(19) United States
(12) Patent Application Publication
(10) Pub. No.: US 2015/0102290 A1
(43) Pub. Date: Apr. 16, 2015

(54) DISUBSTITUTED PYRENE COMPOUNDS WITH AMINO GROUP CONTAINING ORTHO ARYL GROUP

(71) Applicant: Universal Display Corporation, Ewing, NJ (US)

(72) Inventors: Raymond Kwong, Fo Tan (HK); Kit Yee Tsang, Shatin (HK); Sze Kui Lam, Kowloon (HK)

(73) Assignee: Universal Display Corporation, Ewing, NJ (US)

(21) Appl. No.: 14/052,374

(22) Filed: Oct. 11, 2013

(51) Int. Cl. H01L 51/00; H01L 51/50

(52) U.S. Cl. CPC H01L 51/0054; H01L 51/5056; H01L 51/5072; H01L 51/5092; H01L 51/006; H01L 51/0061; H01L 51/0073
USPC 257/40; 564/426; 549/460

(57) ABSTRACT

Compounds according to Formula 1, devices containing the same and formulations containing the same are described. Formula 1 has the following structure:

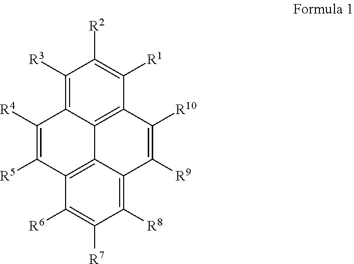

where at least two of R¹-R¹⁰ are not H,
where at least one of R¹-R¹⁰ has the formula T1

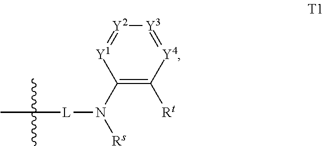

where L is an organic linker,
where Y¹ to Y⁴ are CR or N,
where adjacent R moieties can form fused rings,
where R^{s} and R^{t} are independently aryl or heteroaryl, either of which may independently be further substituted, and
where R^{s} and R^{t} do not form fused rings with any part of the molecule.

### PARTIES TO A JOINT RESEARCH AGREEMENT

The claimed invention was made by, on behalf of, and/or in connection with one or more of the following parties to a joint university corporation research agreement: Regents of the University of Michigan, Princeton University, University of Southern California, and the Universal Display Corporation. The agreement was in effect on and before the date the claimed invention was made, and the claimed invention was made as a result of activities undertaken within the scope of the agreement.

### FIELD OF THE INVENTION

The present invention relates to compounds for use as fluorescent emitters and devices, such as organic light emitting diodes, including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

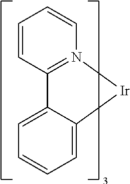

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material, A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY OF THE INVENTION

According to an embodiment, a compound is provided that has the structure of Formula 1 shown below:

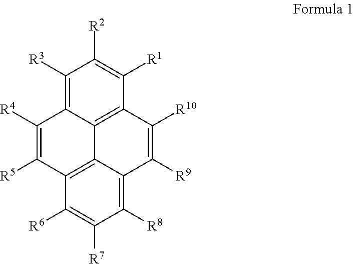

where R¹-R¹⁰ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof,

where at least two of R¹-R¹⁰ are not H,

where at least one of R¹-R¹⁰ has the formula T1

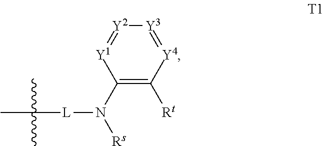

where L is an organic linker,

where Y¹ to Y⁴ are CR or N,

where R is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof,

where adjacent R moieties can form fused rings,

where R^{s} and R^{t} are independently aryl or heteroaryl, either of which may independently be further substituted, and

where R^{s} and R^{t} do not form fused rings with any part of the molecule.

According to another embodiment, a first device comprising a first organic light emitting device is also provided. The first organic light emitting device can include an anode, a cathode, and an organic layer, disposed between the anode and the cathode. The organic layer can include a compound of Formula 1. The first device can be a consumer product, an organic light-emitting device, and/or a lighting panel.

According to another embodiment, a formulation containing the compound according to Formula 1 is provided. The formulation can include one or more components selected from the group consisting of a solvent, a host, a hole injection material, hole transport material, and an electron transport layer material, disclosed herein

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows Formula 1 as disclosed herein.

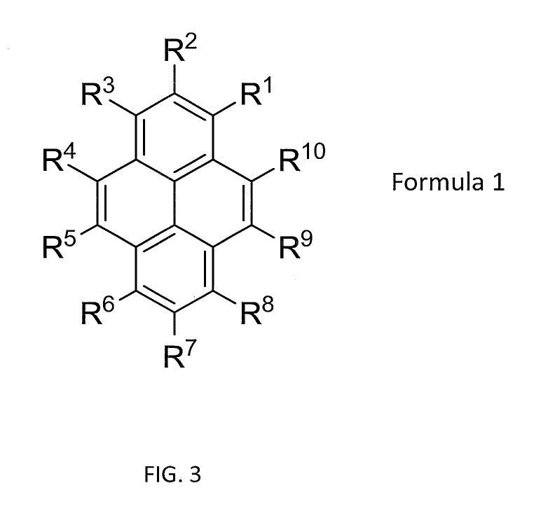

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

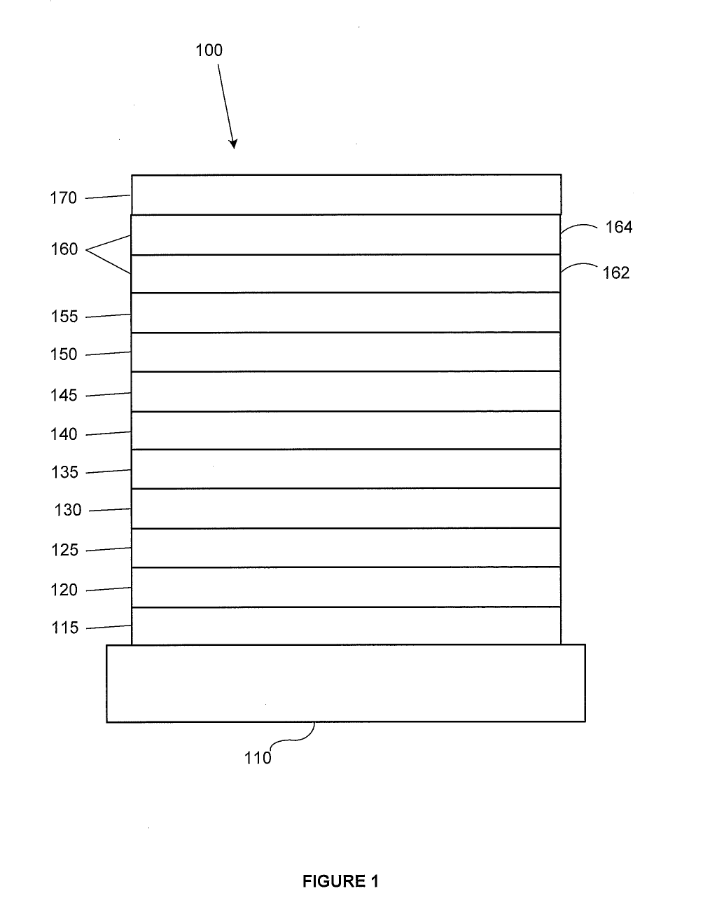

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

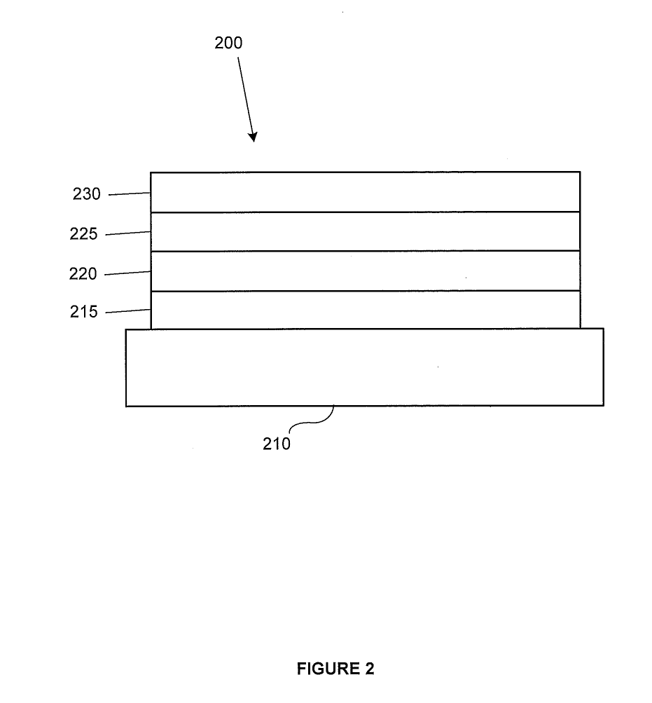

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention may be incorporated into a wide variety of consumer products, including flat panel displays, computer monitors, medical monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, 3-D displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.), but could be used outside this temperature range, for example, from −40 degree C. to +80 degree C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

The terms halo, halogen, alkyl, cycloalkyl, alkenyl, alkynyl, aralkyl, heterocyclic group, aryl, aromatic group, and heteroaryl are known to the art, and are defined in U.S. Pat. No. 7,279,704 at cols. 31-32, which are incorporated herein by reference.

As used herein, “substituted” indicates that a substituent other than H is bonded to the relevant atom. Thus, where R² is monosubstituted, then one R² must be other than H. Similarly, where R³ is disubstituted, then two of R³ must be other than H. Similarly, where R² is unsubstituted R² is hydrogen for all available positions.

Pyrene compounds are a class of luminescent compounds that have been used in OLED devices. However, pyrene molecules have a tendency toward π-stacking, which leads to red-shifting of the emissions. It has been unexpectedly discovered that high efficiency blue emissions can be produced by pyrene compounds with at least two substitutions, including at least one amine group that includes a six-membered aryl ring substituted in the ortho position, where a linker is between the pyrene and the amino group. It is believed that these high efficiency blue emissions result because the linker-amino-ortho-aryl moiety produces steric bulkiness that imposes a heavy twisting on the aryl rings of the pyrene, which forces the pyrene moiety into a non-coplanar arrangement. It is believed that the linker may induce extra aryl-aryl twisting. Surprisingly, the data shows that the combined effect of these unique pyrene-based compounds is reduced π-stacking, increased photoluminescence and electroluminescent efficiency, as well as, decreased evaporation temperature, which makes the pyrene compounds described herein particularly suitable for use as fluorescent blue emitters in OLED devices.

According to one embodiment, a pyrene compound according to Formula 1 is disclosed:

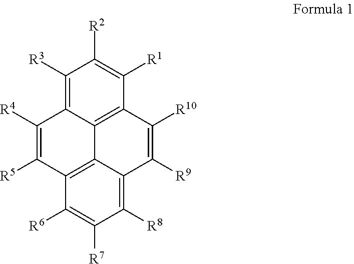

where R¹-R¹⁰ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof,

where at least two of R¹-R¹⁰ are not H,

where at least one of R¹-R¹⁰ has the formula T1

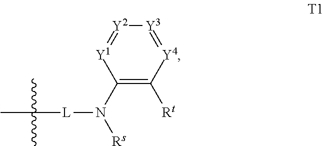

where L is an organic linker,

where Y¹ to Y⁴ are CR or N,

where R is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof,

where adjacent R moieties can form fused rings,

where R^{s} and R^{t} are independently aryl or heteroaryl, either of which may independently be further substituted, and

where R^{s} and R^{t} do not form fused rings with any part of the molecule,

In some embodiments, R^{s} and R^{t} can be further substituted by a moiety selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof,

In some embodiments, Rₛ can include a moiety selected from the group consisting of dibenzothiophene, dibenzofuran, dibenzoselenophene, aza-dibenzothiophene, aza-dibenzofuran, or aza-dibenzoselenophene, phenyl, pyridine, and combinations thereof.

The linker L is not a bond and includes at least one atom. In some embodiments, the linker L is alkyl, aryl or heteroaryl. In some more specific embodiments, the linker L is selected from the group consisting of:

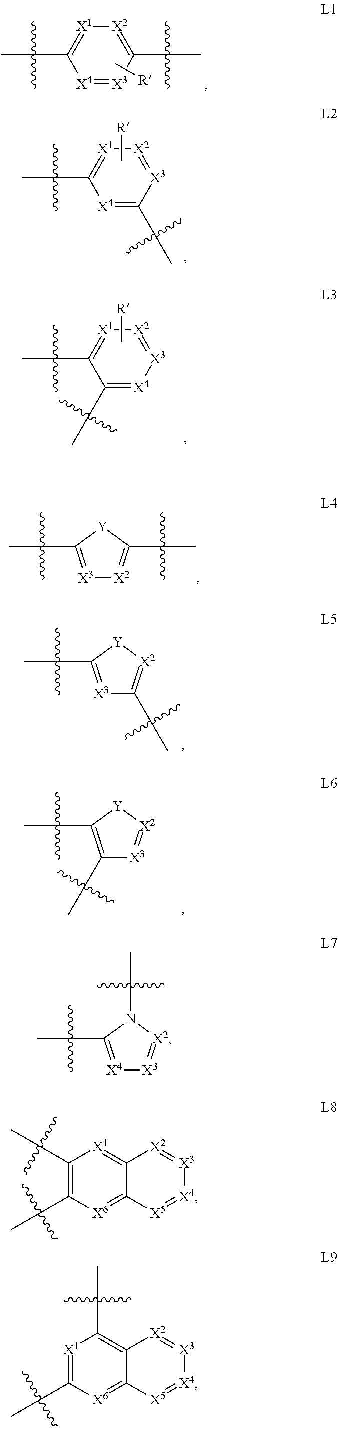

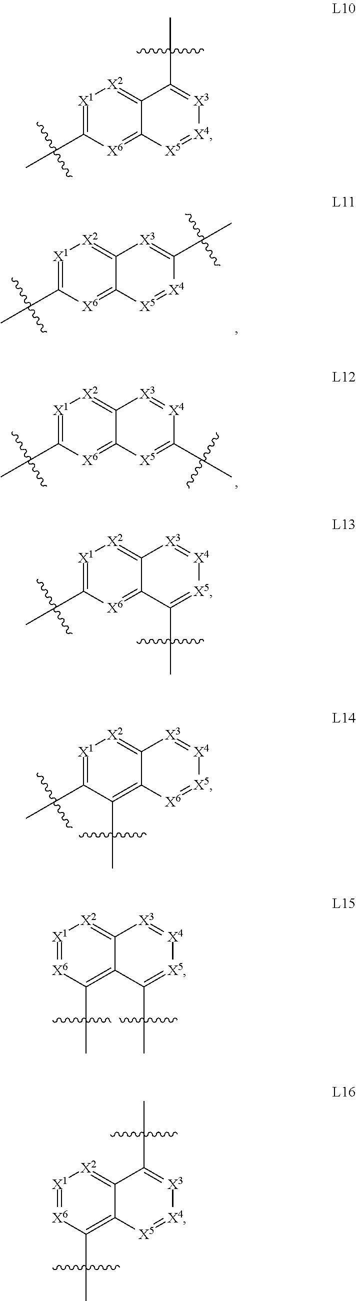

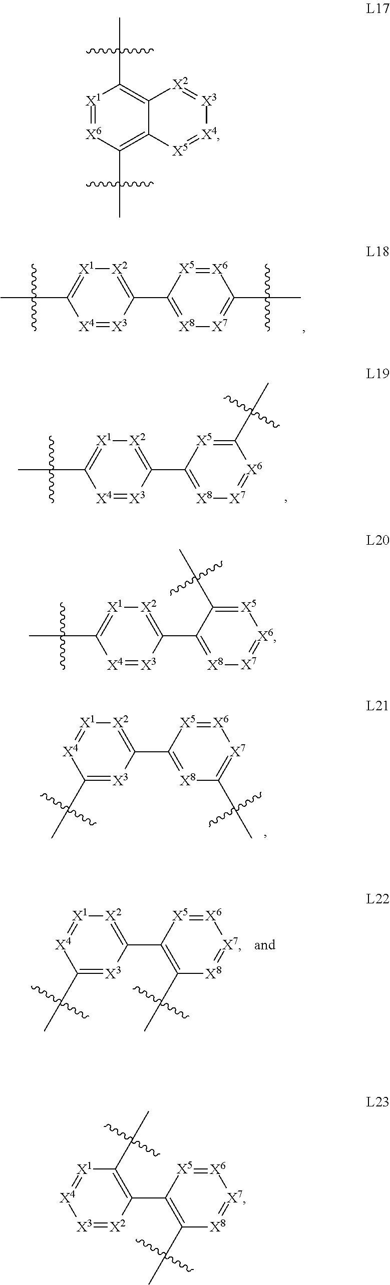

where X¹ to X⁸ are CR′ or N,

where Y is NR″, O or S, and

where R′ and R″ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof.

In some embodiments, R¹ has the formula

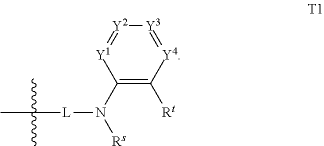

In some embodiments, R¹ has the formula

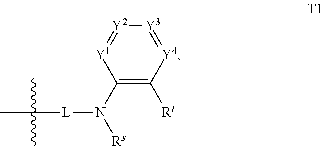

and R⁶ is alkyl, aryl or heteroaryl. In some specific embodiments, such compounds can be selected from the group

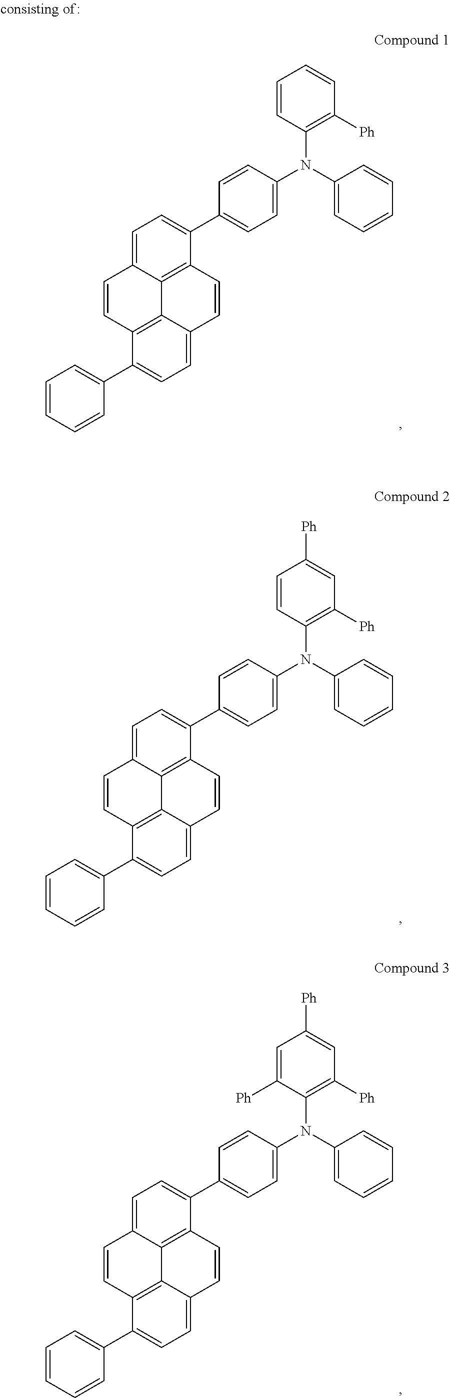 [SMILES: c1ccc(-c2ccccc2N(c2ccccc2)c2ccc(-c3ccc4ccc5c(-c6ccccc6)ccc6ccc3c4c65)cc2)cc1 ; c1ccc(-c2ccc(N(c3ccccc3)c3ccc(-c4ccc5ccc6c(-c7ccccc7)ccc7ccc4c5c76)cc3)c(-c3ccccc3)c2)cc1 ; c1ccc(-c2cc(-c3ccccc3)c(N(c3ccccc3)c3ccc(-c4ccc5ccc6c(-c7ccccc7)ccc7ccc4c5c76)cc3)c(-c3ccccc3)c2)cc1]

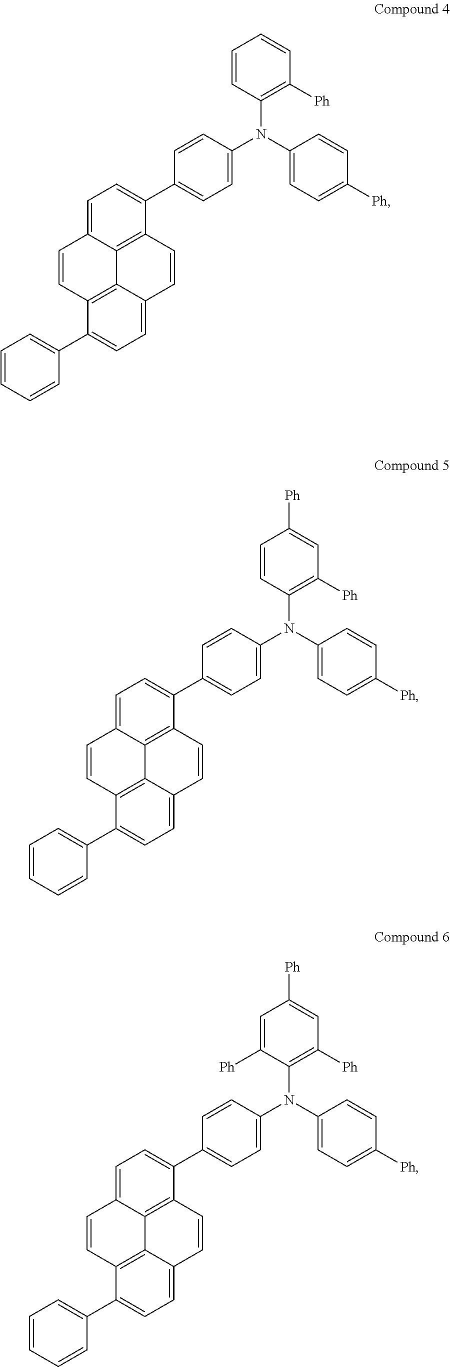 [SMILES: c1ccc(-c2ccc(N(c3ccc(-c4ccc5ccc6c(-c7ccccc7)ccc7ccc4c5c76)cc3)c3ccccc3-c3ccccc3)cc2)cc1 ; c1ccc(-c2ccc(N(c3ccc(-c4ccc5ccc6c(-c7ccccc7)ccc7ccc4c5c76)cc3)c3ccc(-c4ccccc4)cc3-c3ccccc3)cc2)cc1 ; c1ccc(-c2ccc(N(c3ccc(-c4ccc5ccc6c(-c7ccccc7)ccc7ccc4c5c76)cc3)c3c(-c4ccccc4)cc(-c4ccccc4)cc3-c3ccccc3)cc2)cc1]

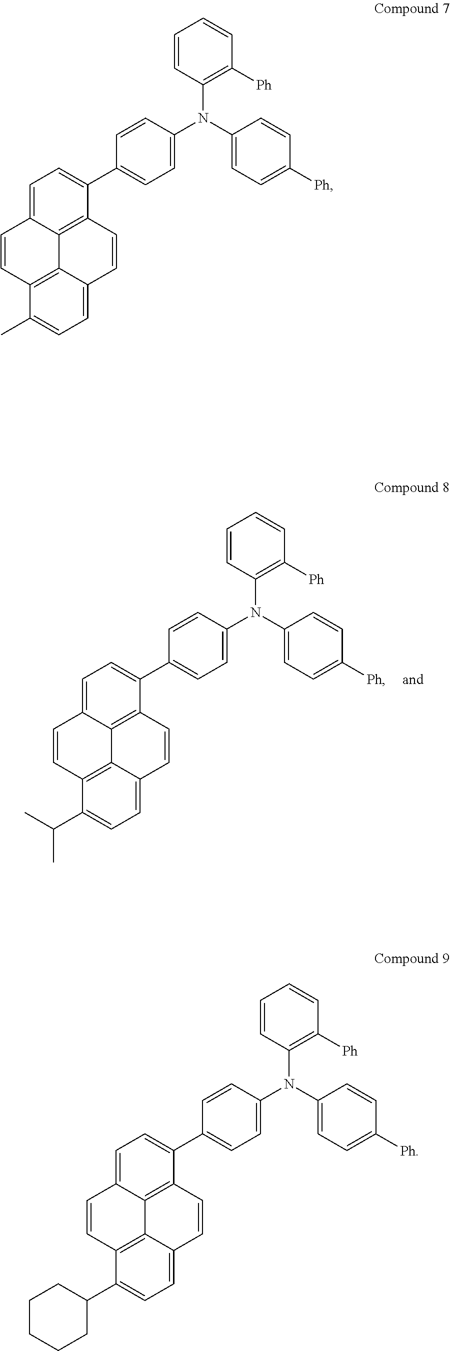 [SMILES: Cc1ccc2ccc3c(-c4ccc(N(c5ccc(-c6ccccc6)cc5)c5ccccc5-c5ccccc5)cc4)ccc4ccc1c2c43 ; CC(C)c1ccc2ccc3c(-c4ccc(N(c5ccc(-c6ccccc6)cc5)c5ccccc5-c5ccccc5)cc4)ccc4ccc1c2c43 ; c1ccc(-c2ccc(N(c3ccc(-c4ccc5ccc6c(C7CCCCC7)ccc7ccc4c5c76)cc3)c3ccccc3-c3ccccc3)cc2)cc1]

In some embodiments, R¹ and R⁶ each have the formula T1

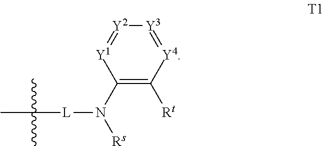

In some specific embodiments, such compounds can be selected from the group consisting of:

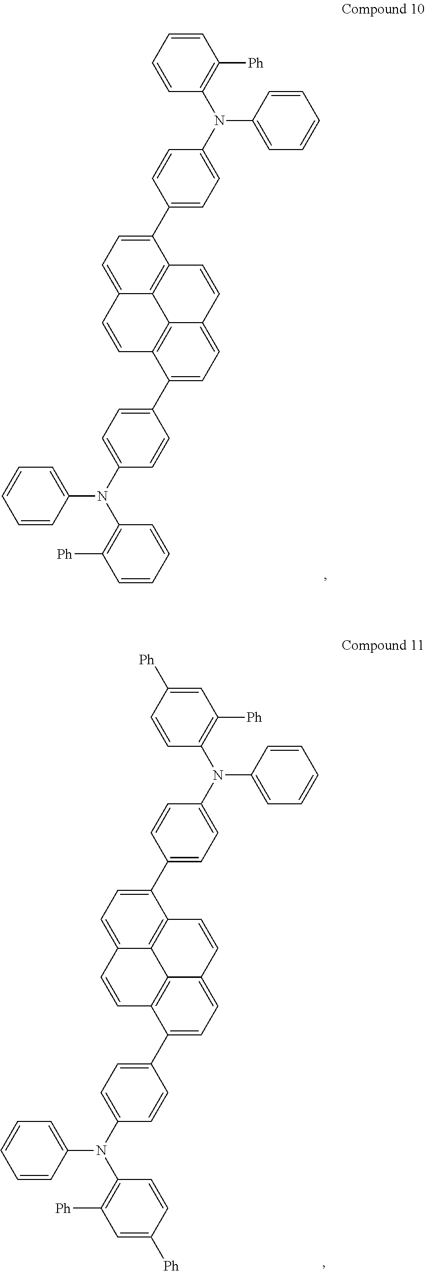 [SMILES: c1ccc(-c2ccccc2N(c2ccccc2)c2ccc(-c3ccc4ccc5c(-c6ccc(N(c7ccccc7)c7ccccc7-c7ccccc7)cc6)ccc6ccc3c4c65)cc2)cc1 ; c1ccc(-c2ccc(N(c3ccccc3)c3ccc(-c4ccc5ccc6c(-c7ccc(N(c8ccccc8)c8ccc(-c9ccccc9)cc8-c8ccccc8)cc7)ccc7ccc4c5c76)cc3)c(-c3ccccc3)c2)cc1]

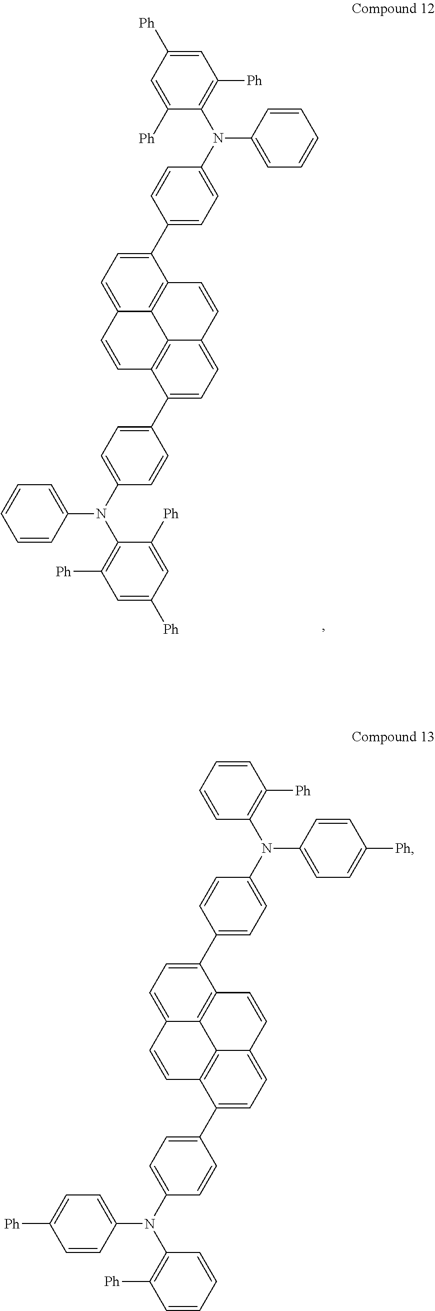 [SMILES: c1ccc(-c2cc(-c3ccccc3)c(N(c3ccccc3)c3ccc(-c4ccc5ccc6c(-c7ccc(N(c8ccccc8)c8c(-c9ccccc9)cc(-c9ccccc9)cc8-c8ccccc8)cc7)ccc7ccc4c5c76)cc3)c(-c3ccccc3)c2)cc1 ; c1ccc(-c2ccc(N(c3ccc(-c4ccc5ccc6c(-c7ccc(N(c8ccc(-c9ccccc9)cc8)c8ccccc8-c8ccccc8)cc7)ccc7ccc4c5c76)cc3)c3ccccc3-c3ccccc3)cc2)cc1]

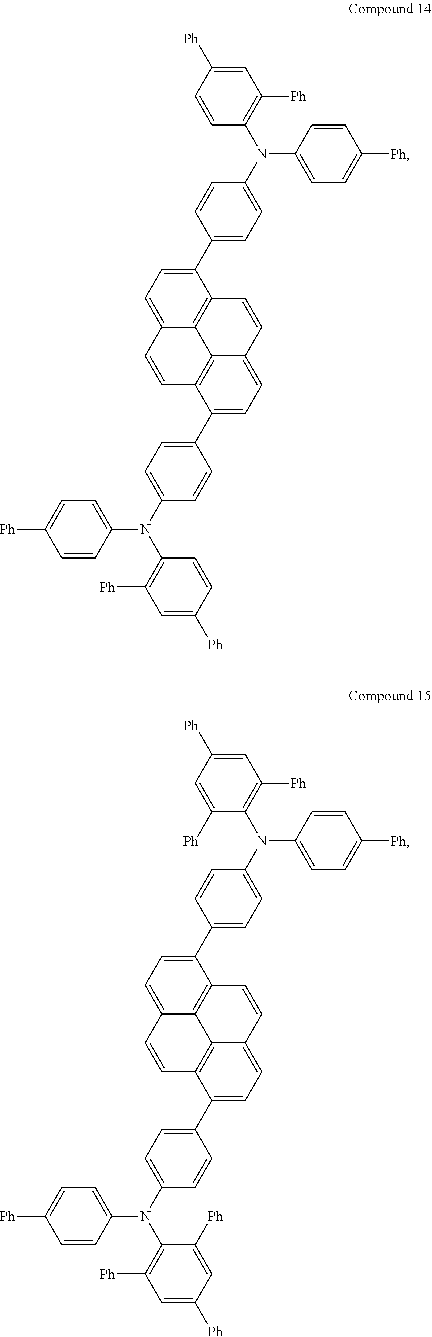 [SMILES: c1ccc(-c2ccc(N(c3ccc(-c4ccc5ccc6c(-c7ccc(N(c8ccc(-c9ccccc9)cc8)c8ccc(-c9ccccc9)cc8-c8ccccc8)cc7)ccc7ccc4c5c76)cc3)c3ccc(-c4ccccc4)cc3-c3ccccc3)cc2)cc1 ; c1ccc(-c2ccc(N(c3ccc(-c4ccc5ccc6c(-c7ccc(N(c8ccc(-c9ccccc9)cc8)c8c(-c9ccccc9)cc(-c9ccccc9)cc8-c8ccccc8)cc7)ccc7ccc4c5c76)cc3)c3c(-c4ccccc4)cc(-c4ccccc4)cc3-c3ccccc3)cc2)cc1]

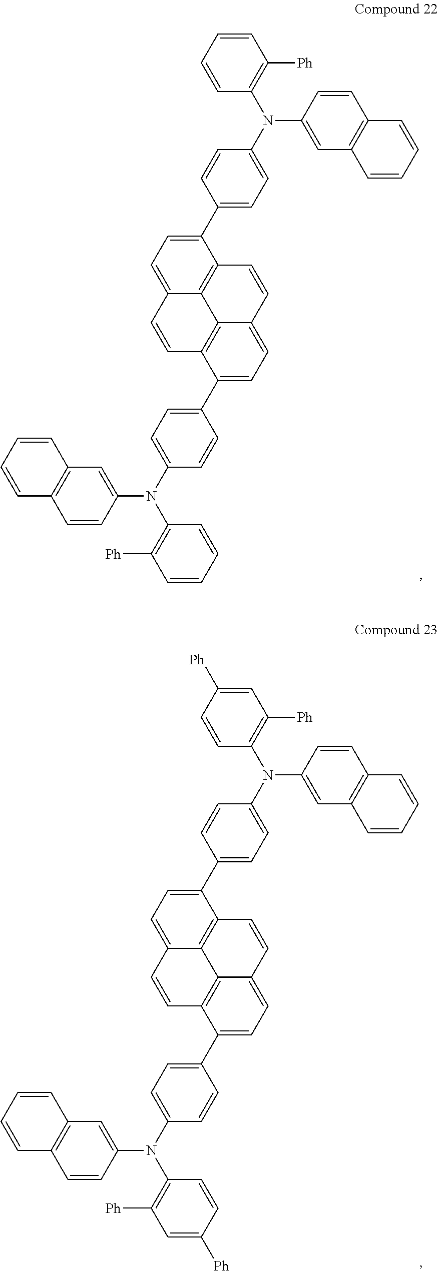 [SMILES: c1ccc(-c2ccccc2N(c2ccc(-c3ccc4ccc5c(-c6ccc(N(c7ccc8ccccc8c7)c7ccccc7-c7ccccc7)cc6)ccc6ccc3c4c65)cc2)c2ccc3ccccc3c2)cc1 ; c1ccc(-c2ccc(N(c3ccc(-c4ccc5ccc6c(-c7ccc(N(c8ccc9ccccc9c8)c8ccc(-c9ccccc9)cc8-c8ccccc8)cc7)ccc7ccc4c5c76)cc3)c3ccc4ccccc4c3)c(-c3ccccc3)c2)cc1]

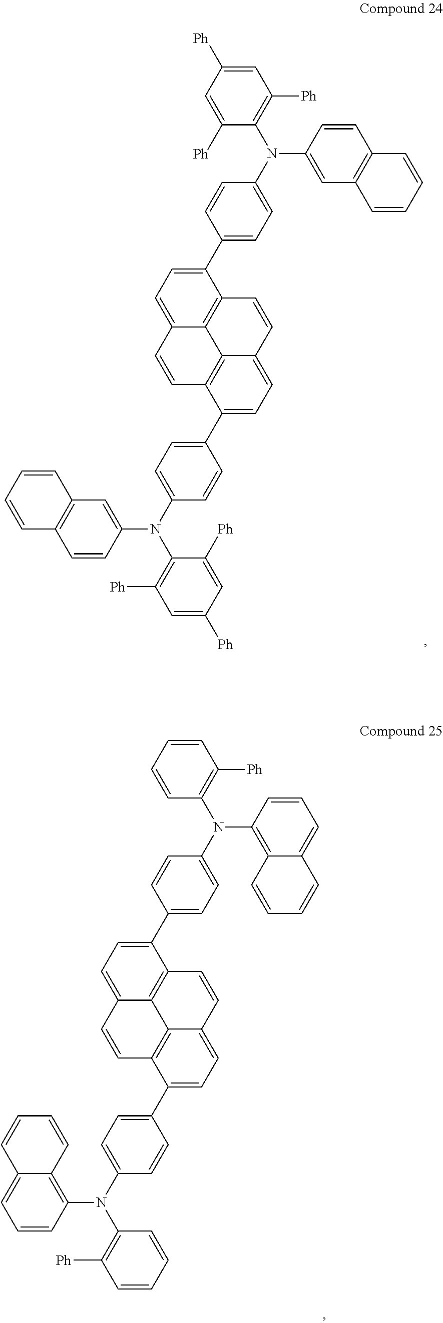 [SMILES: c1ccc(-c2cc(-c3ccccc3)c(N(c3ccc(-c4ccc5ccc6c(-c7ccc(N(c8ccc9ccccc9c8)c8c(-c9ccccc9)cc(-c9ccccc9)cc8-c8ccccc8)cc7)ccc7ccc4c5c76)cc3)c3ccc4ccccc4c3)c(-c3ccccc3)c2)cc1 ; c1ccc(-c2ccccc2N(c2ccc(-c3ccc4ccc5c(-c6ccc(N(c7ccccc7-c7ccccc7)c7cccc8ccccc78)cc6)ccc6ccc3c4c65)cc2)c2cccc3ccccc23)cc1]

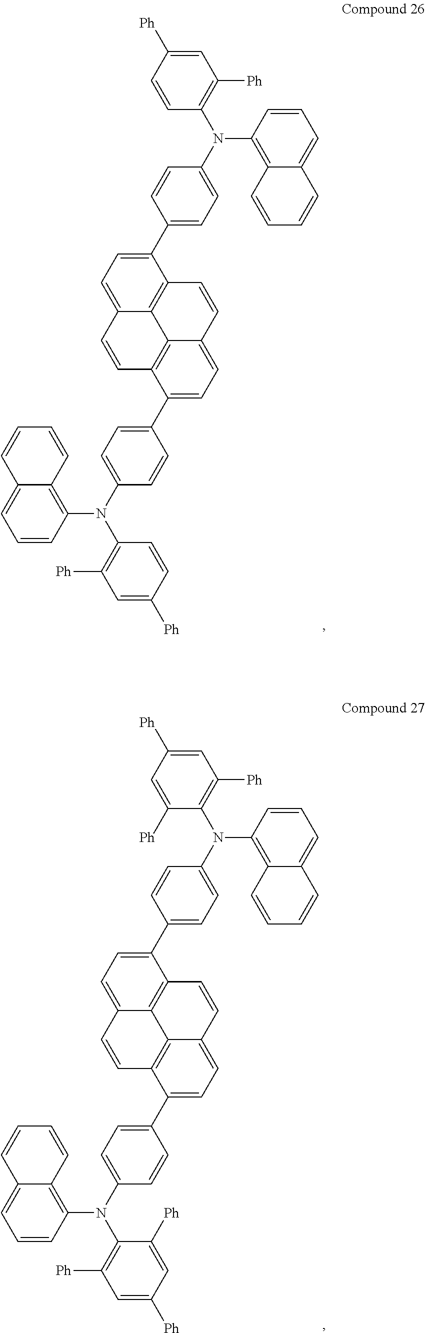 [SMILES: c1ccc(-c2ccc(N(c3ccc(-c4ccc5ccc6c(-c7ccc(N(c8ccc(-c9ccccc9)cc8-c8ccccc8)c8cccc9ccccc89)cc7)ccc7ccc4c5c76)cc3)c3cccc4ccccc34)c(-c3ccccc3)c2)cc1 ; c1ccc(-c2cc(-c3ccccc3)c(N(c3ccc(-c4ccc5ccc6c(-c7ccc(N(c8c(-c9ccccc9)cc(-c9ccccc9)cc8-c8ccccc8)c8cccc9ccccc89)cc7)ccc7ccc4c5c76)cc3)c3cccc4ccccc34)c(-c3ccccc3)c2)cc1]

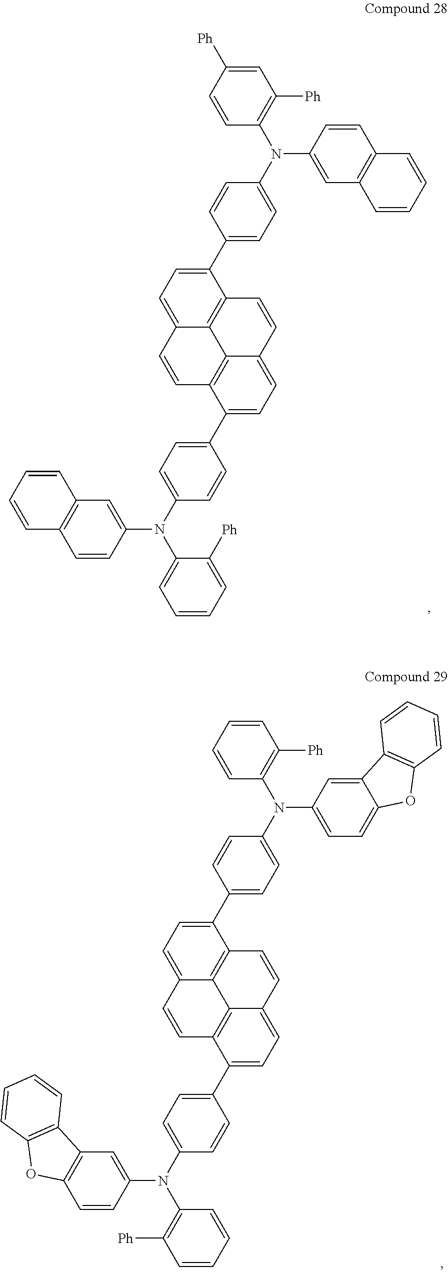 [SMILES: c1ccc(-c2ccc(N(c3ccc(-c4ccc5ccc6c(-c7ccc(N(c8ccc9ccccc9c8)c8ccccc8-c8ccccc8)cc7)ccc7ccc4c5c76)cc3)c3ccc4ccccc4c3)c(-c3ccccc3)c2)cc1 ; c1ccc(-c2ccccc2N(c2ccc(-c3ccc4ccc5c(-c6ccc(N(c7ccc8oc9ccccc9c8c7)c7ccccc7-c7ccccc7)cc6)ccc6ccc3c4c65)cc2)c2ccc3oc4ccccc4c3c2)cc1]

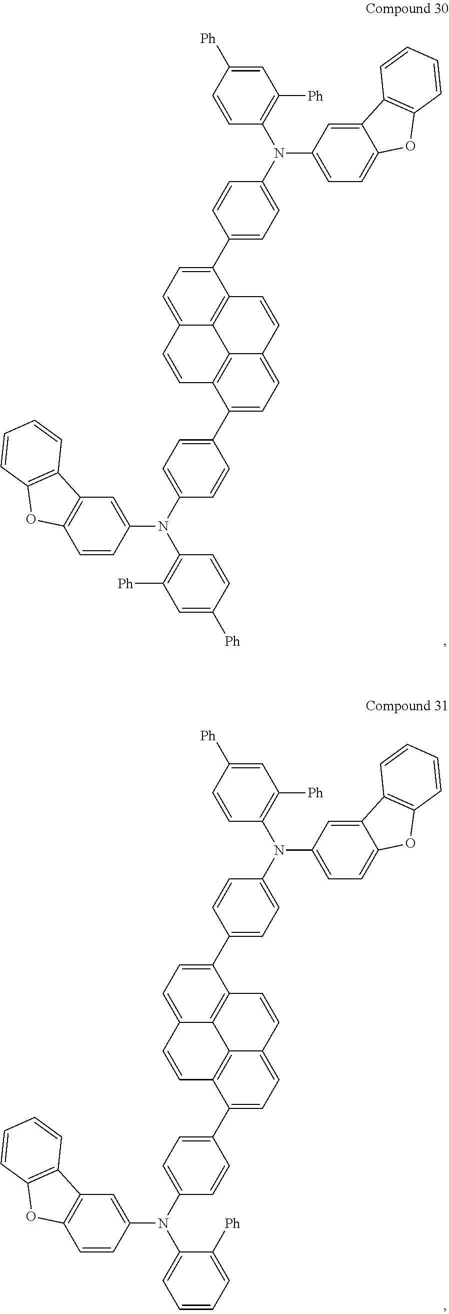 [SMILES: c1ccc(-c2ccc(N(c3ccc(-c4ccc5ccc6c(-c7ccc(N(c8ccc9oc%10ccccc%10c9c8)c8ccc(-c9ccccc9)cc8-c8ccccc8)cc7)ccc7ccc4c5c76)cc3)c3ccc4oc5ccccc5c4c3)c(-c3ccccc3)c2)cc1 ; c1ccc(-c2ccc(N(c3ccc(-c4ccc5ccc6c(-c7ccc(N(c8ccc9oc%10ccccc%10c9c8)c8ccccc8-c8ccccc8)cc7)ccc7ccc4c5c76)cc3)c3ccc4oc5ccccc5c4c3)c(-c3ccccc3)c2)cc1]

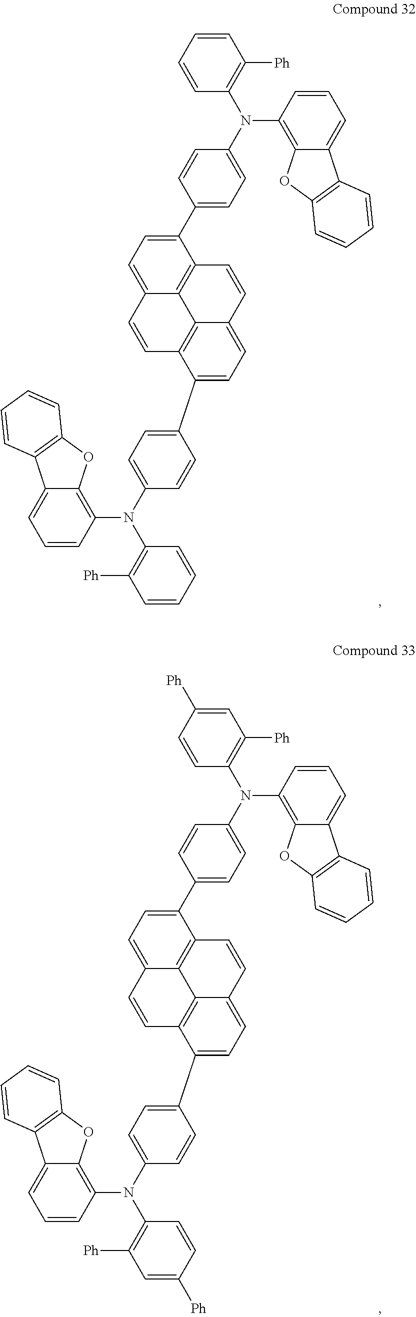 [SMILES: c1ccc(-c2ccccc2N(c2ccc(-c3ccc4ccc5c(-c6ccc(N(c7ccccc7-c7ccccc7)c7cccc8c7oc7ccccc78)cc6)ccc6ccc3c4c65)cc2)c2cccc3c2oc2ccccc23)cc1 ; c1ccc(-c2ccc(N(c3ccc(-c4ccc5ccc6c(-c7ccc(N(c8ccc(-c9ccccc9)cc8-c8ccccc8)c8cccc9c8oc8ccccc89)cc7)ccc7ccc4c5c76)cc3)c3cccc4c3oc3ccccc34)c(-c3ccccc3)c2)cc1]

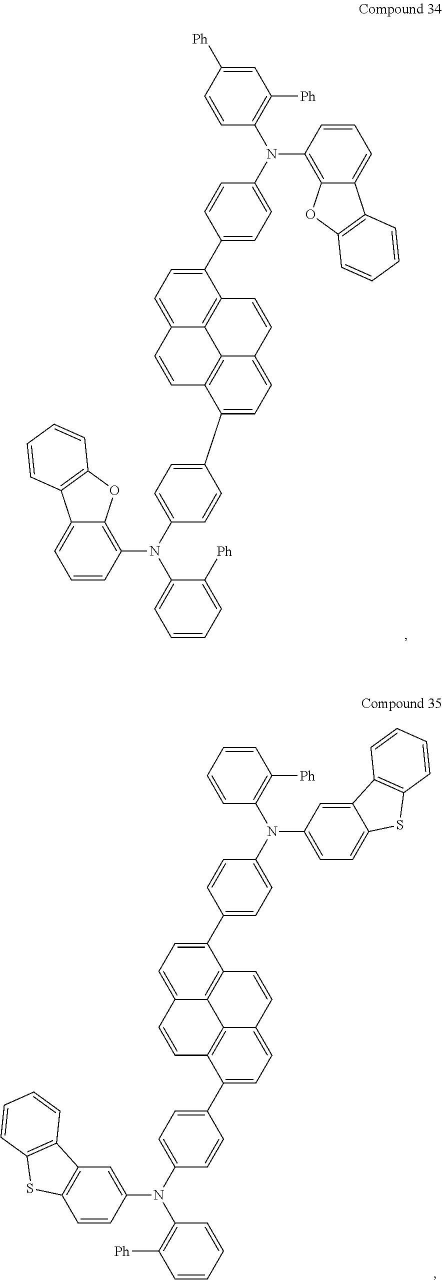 [SMILES: c1ccc(-c2ccc(N(c3ccc(-c4ccc5ccc6c(-c7ccc(N(c8ccccc8-c8ccccc8)c8cccc9c8oc8ccccc89)cc7)ccc7ccc4c5c76)cc3)c3cccc4c3oc3ccccc34)c(-c3ccccc3)c2)cc1 ; c1ccc(-c2ccccc2N(c2ccc(-c3ccc4ccc5c(-c6ccc(N(c7ccc8sc9ccccc9c8c7)c7ccccc7-c7ccccc7)cc6)ccc6ccc3c4c65)cc2)c2ccc3sc4ccccc4c3c2)cc1]

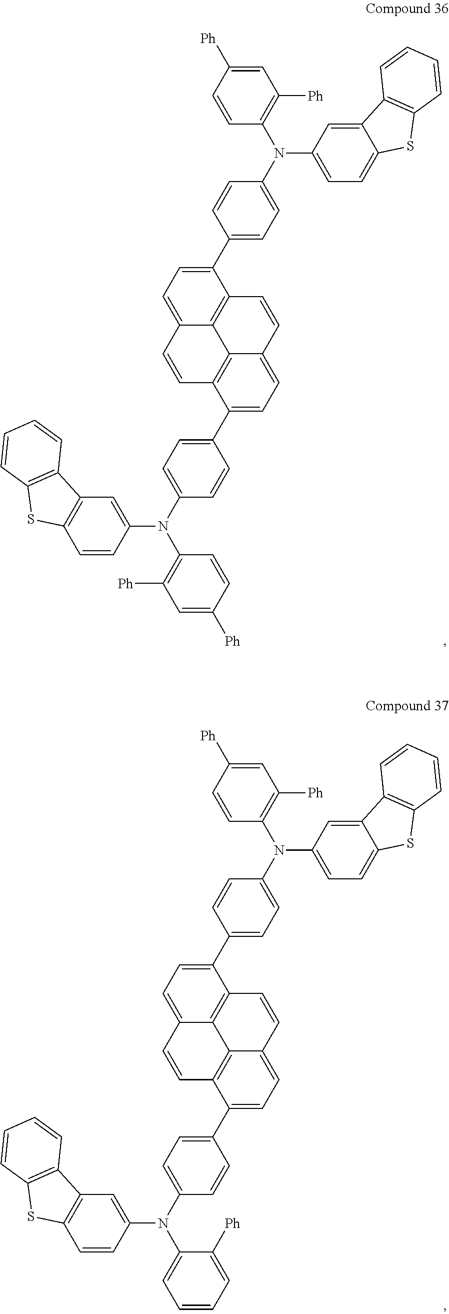 [SMILES: c1ccc(-c2ccc(N(c3ccc(-c4ccc5ccc6c(-c7ccc(N(c8ccc9sc%10ccccc%10c9c8)c8ccc(-c9ccccc9)cc8-c8ccccc8)cc7)ccc7ccc4c5c76)cc3)c3ccc4sc5ccccc5c4c3)c(-c3ccccc3)c2)cc1 ; c1ccc(-c2ccc(N(c3ccc(-c4ccc5ccc6c(-c7ccc(N(c8ccc9sc%10ccccc%10c9c8)c8ccccc8-c8ccccc8)cc7)ccc7ccc4c5c76)cc3)c3ccc4sc5ccccc5c4c3)c(-c3ccccc3)c2)cc1]

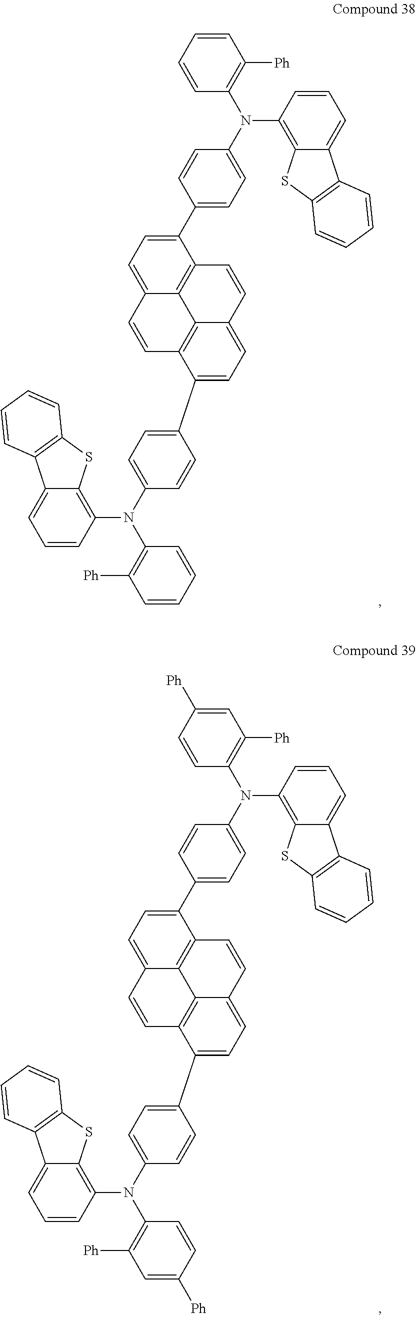 [SMILES: c1ccc(-c2ccccc2N(c2ccc(-c3ccc4ccc5c(-c6ccc(N(c7ccccc7-c7ccccc7)c7cccc8c7sc7ccccc78)cc6)ccc6ccc3c4c65)cc2)c2cccc3c2sc2ccccc23)cc1 ; c1ccc(-c2ccc(N(c3ccc(-c4ccc5ccc6c(-c7ccc(N(c8ccc(-c9ccccc9)cc8-c8ccccc8)c8cccc9c8sc8ccccc89)cc7)ccc7ccc4c5c76)cc3)c3cccc4c3sc3ccccc34)c(-c3ccccc3)c2)cc1]

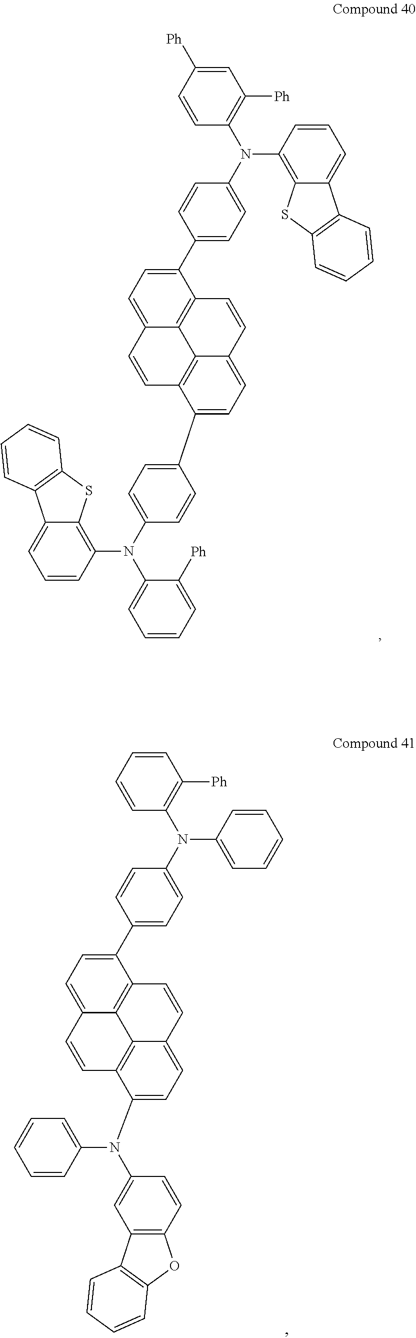 [SMILES: c1ccc(-c2ccc(N(c3ccc(-c4ccc5ccc6c(-c7ccc(N(c8ccccc8-c8ccccc8)c8cccc9c8sc8ccccc89)cc7)ccc7ccc4c5c76)cc3)c3cccc4c3sc3ccccc34)c(-c3ccccc3)c2)cc1 ; c1ccc(-c2ccccc2N(c2ccccc2)c2ccc(-c3ccc4ccc5c(N(c6ccccc6)c6ccc7oc8ccccc8c7c6)ccc6ccc3c4c65)cc2)cc1]

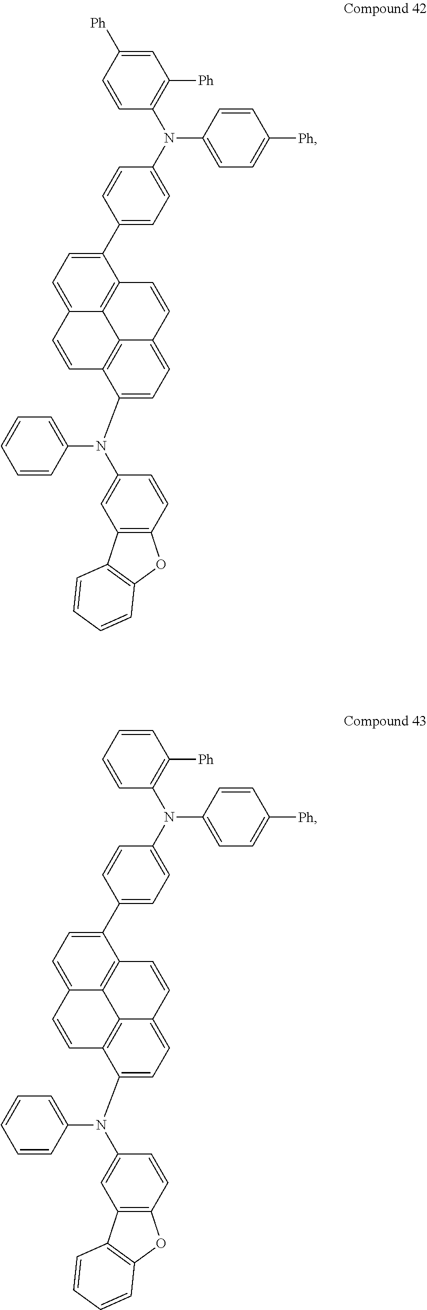 [SMILES: c1ccc(-c2ccc(N(c3ccc(-c4ccc5ccc6c(N(c7ccccc7)c7ccc8oc9ccccc9c8c7)ccc7ccc4c5c76)cc3)c3ccc(-c4ccccc4)cc3-c3ccccc3)cc2)cc1 ; c1ccc(-c2ccc(N(c3ccc(-c4ccc5ccc6c(N(c7ccccc7)c7ccc8oc9ccccc9c8c7)ccc7ccc4c5c76)cc3)c3ccccc3-c3ccccc3)cc2)cc1]

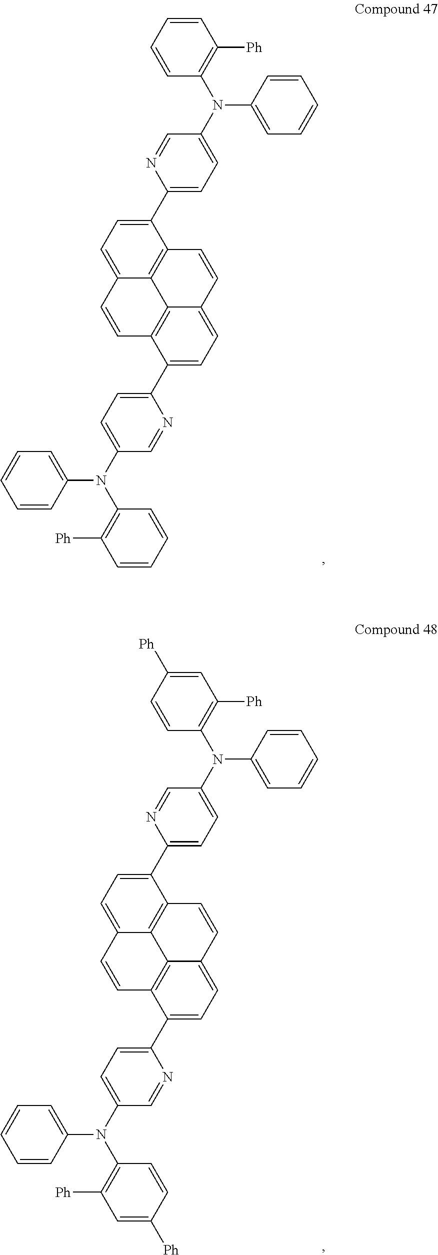 [SMILES: c1ccc(-c2ccccc2N(c2ccccc2)c2ccc(-c3ccc4ccc5c(-c6ccc(N(c7ccccc7)c7ccccc7-c7ccccc7)cn6)ccc6ccc3c4c65)nc2)cc1 ; c1ccc(-c2ccc(N(c3ccccc3)c3ccc(-c4ccc5ccc6c(-c7ccc(N(c8ccccc8)c8ccc(-c9ccccc9)cc8-c8ccccc8)cn7)ccc7ccc4c5c76)nc3)c(-c3ccccc3)c2)cc1]

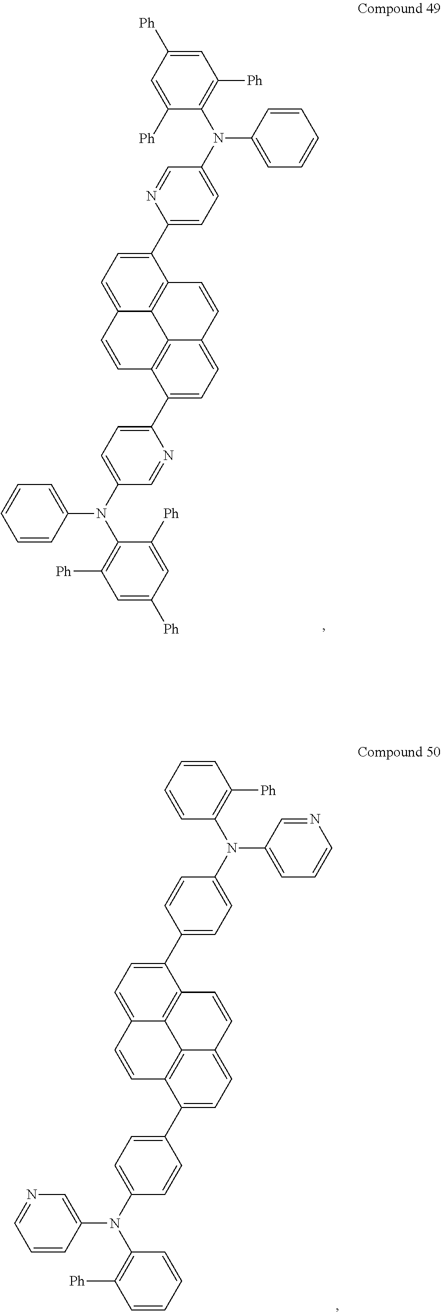 [SMILES: c1ccc(-c2cc(-c3ccccc3)c(N(c3ccccc3)c3ccc(-c4ccc5ccc6c(-c7ccc(N(c8ccccc8)c8c(-c9ccccc9)cc(-c9ccccc9)cc8-c8ccccc8)cn7)ccc7ccc4c5c76)nc3)c(-c3ccccc3)c2)cc1 ; c1ccc(-c2ccccc2N(c2ccc(-c3ccc4ccc5c(-c6ccc(N(c7cccnc7)c7ccccc7-c7ccccc7)cc6)ccc6ccc3c4c65)cc2)c2cccnc2)cc1]

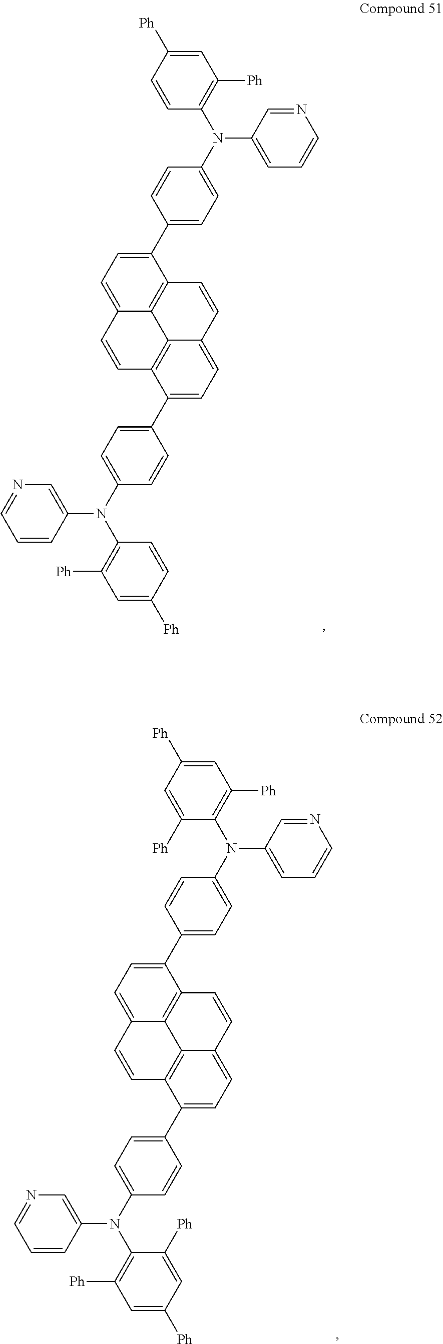 [SMILES: c1ccc(-c2ccc(N(c3ccc(-c4ccc5ccc6c(-c7ccc(N(c8cccnc8)c8ccc(-c9ccccc9)cc8-c8ccccc8)cc7)ccc7ccc4c5c76)cc3)c3cccnc3)c(-c3ccccc3)c2)cc1 ; c1ccc(-c2cc(-c3ccccc3)c(N(c3ccc(-c4ccc5ccc6c(-c7ccc(N(c8cccnc8)c8c(-c9ccccc9)cc(-c9ccccc9)cc8-c8ccccc8)cc7)ccc7ccc4c5c76)cc3)c3cccnc3)c(-c3ccccc3)c2)cc1]

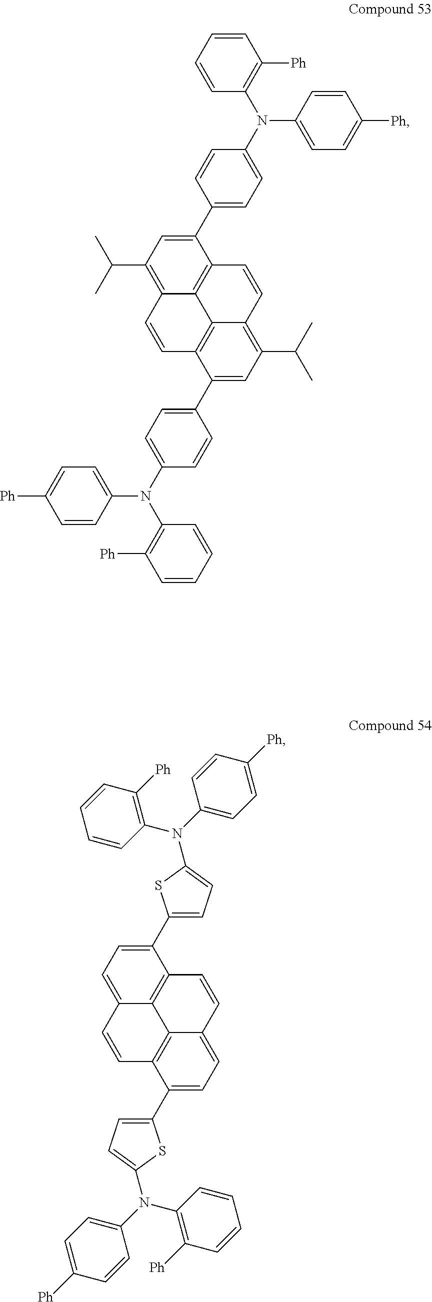 [SMILES: CC(C)c1cc(-c2ccc(N(c3ccc(-c4ccccc4)cc3)c3ccccc3-c3ccccc3)cc2)c2ccc3c(C(C)C)cc(-c4ccc(N(c5ccc(-c6ccccc6)cc5)c5ccccc5-c5ccccc5)cc4)c4ccc1c2c43 ; c1ccc(-c2ccc(N(c3ccc(-c4ccc5ccc6c(-c7ccc(N(c8ccc(-c9ccccc9)cc8)c8ccccc8-c8ccccc8)s7)ccc7ccc4c5c76)s3)c3ccccc3-c3ccccc3)cc2)cc1]

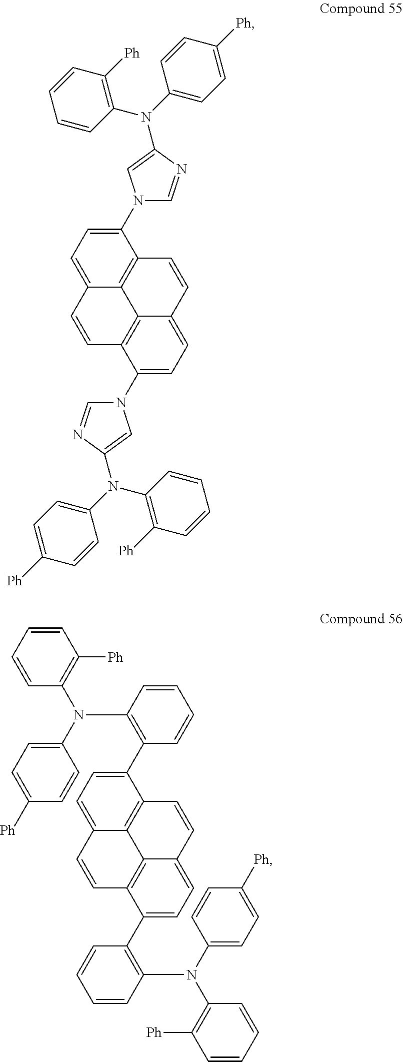 [SMILES: c1ccc(-c2ccc(N(c3cn(-c4ccc5ccc6c(-n7cnc(N(c8ccc(-c9ccccc9)cc8)c8ccccc8-c8ccccc8)c7)ccc7ccc4c5c76)cn3)c3ccccc3-c3ccccc3)cc2)cc1 ; c1ccc(-c2ccc(N(c3ccccc3-c3ccccc3)c3ccccc3-c3ccc4ccc5c(-c6ccccc6N(c6ccc(-c7ccccc7)cc6)c6ccccc6-c6ccccc6)ccc6ccc3c4c65)cc2)cc1]

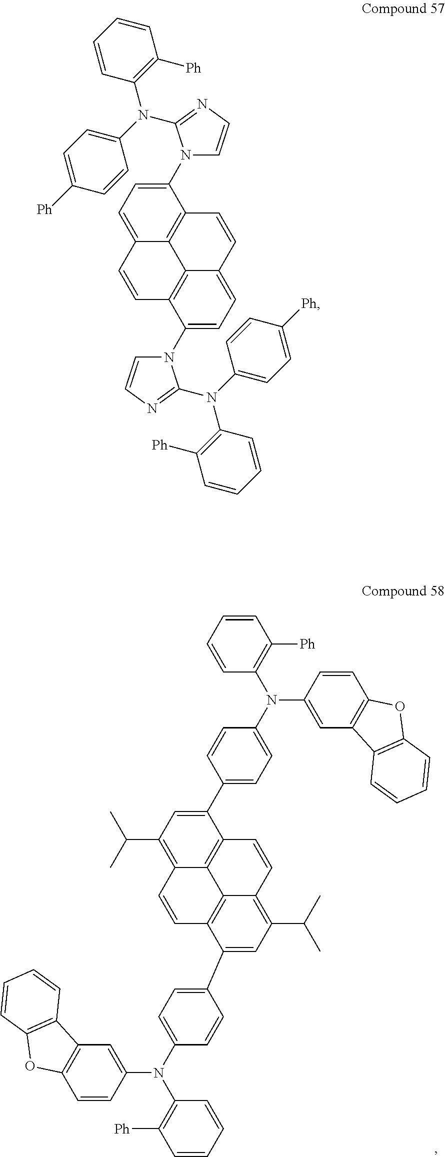 [SMILES: c1ccc(-c2ccc(N(c3ccccc3-c3ccccc3)c3nccn3-c3ccc4ccc5c(-n6ccnc6N(c6ccc(-c7ccccc7)cc6)c6ccccc6-c6ccccc6)ccc6ccc3c4c65)cc2)cc1 ; CC(C)c1cc(-c2ccc(N(c3ccc4oc5ccccc5c4c3)c3ccccc3-c3ccccc3)cc2)c2ccc3c(C(C)C)cc(-c4ccc(N(c5ccc6oc7ccccc7c6c5)c5ccccc5-c5ccccc5)cc4)c4ccc1c2c43]

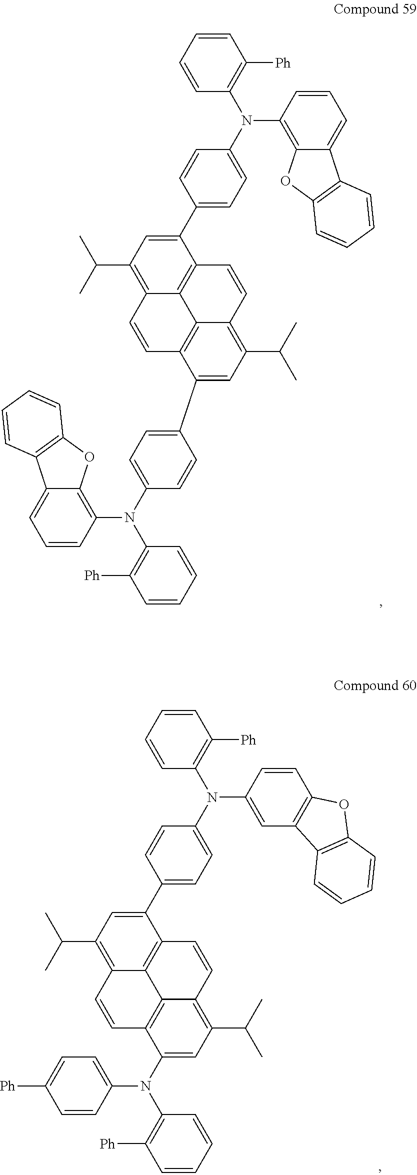 [SMILES: CC(C)c1cc(-c2ccc(N(c3ccccc3-c3ccccc3)c3cccc4c3oc3ccccc34)cc2)c2ccc3c(C(C)C)cc(-c4ccc(N(c5ccccc5-c5ccccc5)c5cccc6c5oc5ccccc56)cc4)c4ccc1c2c43 ; CC(C)c1cc(-c2ccc(N(c3ccc4oc5ccccc5c4c3)c3ccccc3-c3ccccc3)cc2)c2ccc3c(C(C)C)cc(N(c4ccc(-c5ccccc5)cc4)c4ccccc4-c4ccccc4)c4ccc1c2c34]

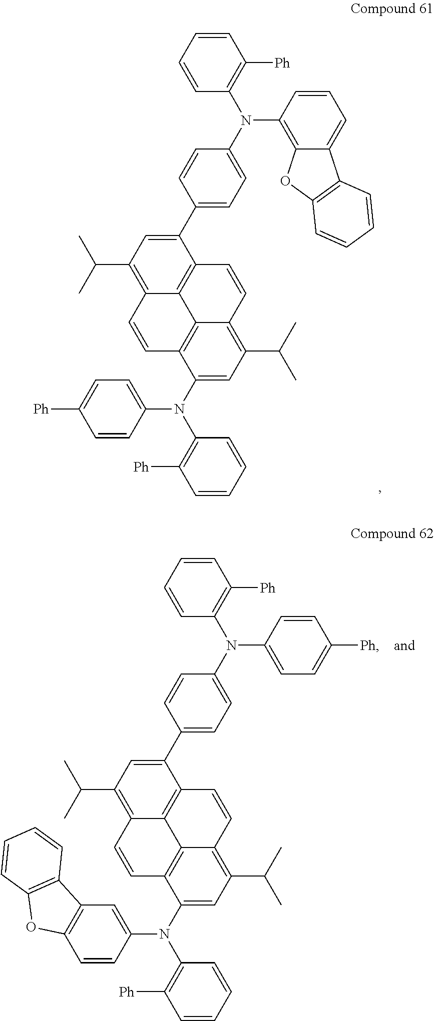 [SMILES: CC(C)c1cc(-c2ccc(N(c3ccccc3-c3ccccc3)c3cccc4c3oc3ccccc34)cc2)c2ccc3c(C(C)C)cc(N(c4ccc(-c5ccccc5)cc4)c4ccccc4-c4ccccc4)c4ccc1c2c34 ; CC(C)c1cc(-c2ccc(N(c3ccc(-c4ccccc4)cc3)c3ccccc3-c3ccccc3)cc2)c2ccc3c(C(C)C)cc(N(c4ccc5oc6ccccc6c5c4)c4ccccc4-c4ccccc4)c4ccc1c2c34]

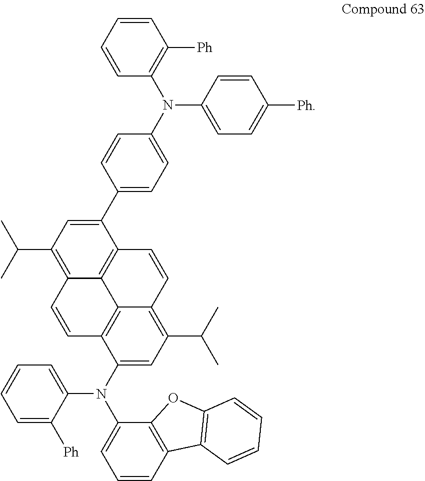 [SMILES: CC(C)c1cc(-c2ccc(N(c3ccc(-c4ccccc4)cc3)c3ccccc3-c3ccccc3)cc2)c2ccc3c(C(C)C)cc(N(c4ccccc4-c4ccccc4)c4cccc5c4oc4ccccc45)c4ccc1c2c34]

In some embodiments, R¹ has the formula

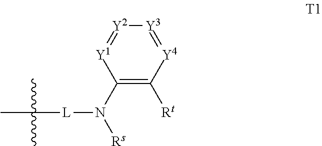

and R⁶ is amino. In some specific embodiments, such compounds can be selected from the group consisting of:

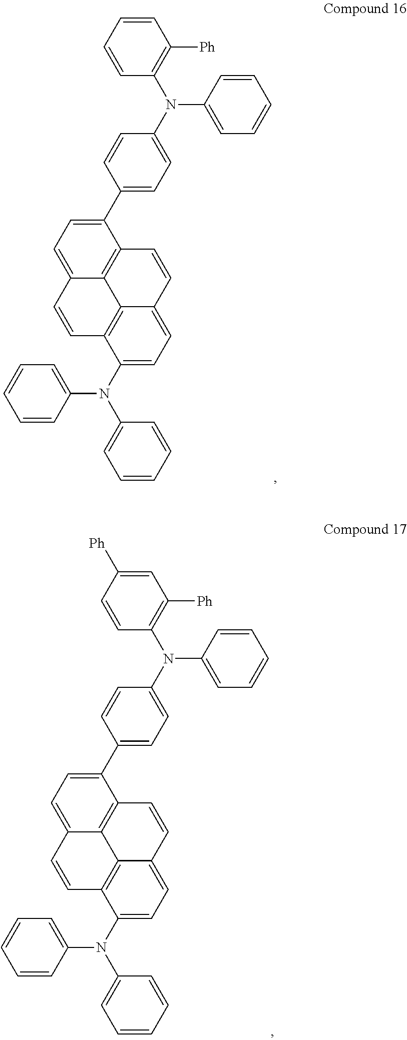 [SMILES: c1ccc(-c2ccccc2N(c2ccccc2)c2ccc(-c3ccc4ccc5c(N(c6ccccc6)c6ccccc6)ccc6ccc3c4c65)cc2)cc1 ; c1ccc(-c2ccc(N(c3ccccc3)c3ccc(-c4ccc5ccc6c(N(c7ccccc7)c7ccccc7)ccc7ccc4c5c76)cc3)c(-c3ccccc3)c2)cc1]

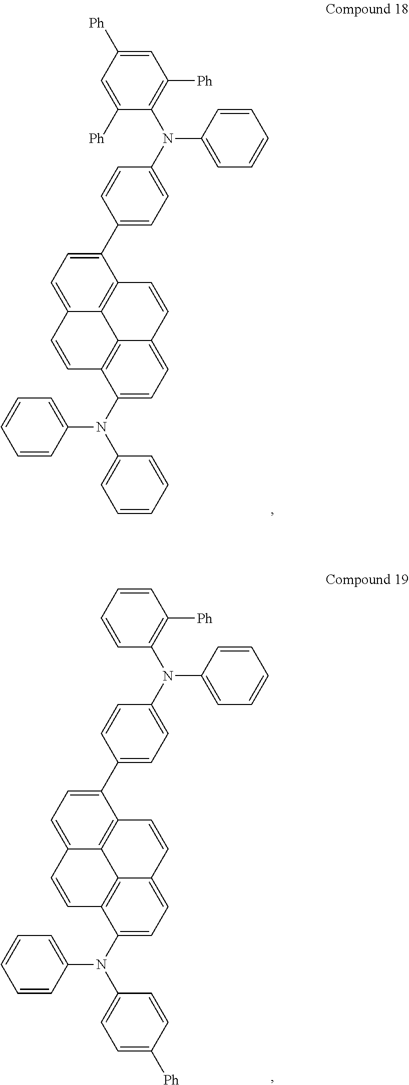 [SMILES: c1ccc(-c2cc(-c3ccccc3)c(N(c3ccccc3)c3ccc(-c4ccc5ccc6c(N(c7ccccc7)c7ccccc7)ccc7ccc4c5c76)cc3)c(-c3ccccc3)c2)cc1 ; c1ccc(-c2ccc(N(c3ccccc3)c3ccc4ccc5c(-c6ccc(N(c7ccccc7)c7ccccc7-c7ccccc7)cc6)ccc6ccc3c4c65)cc2)cc1]

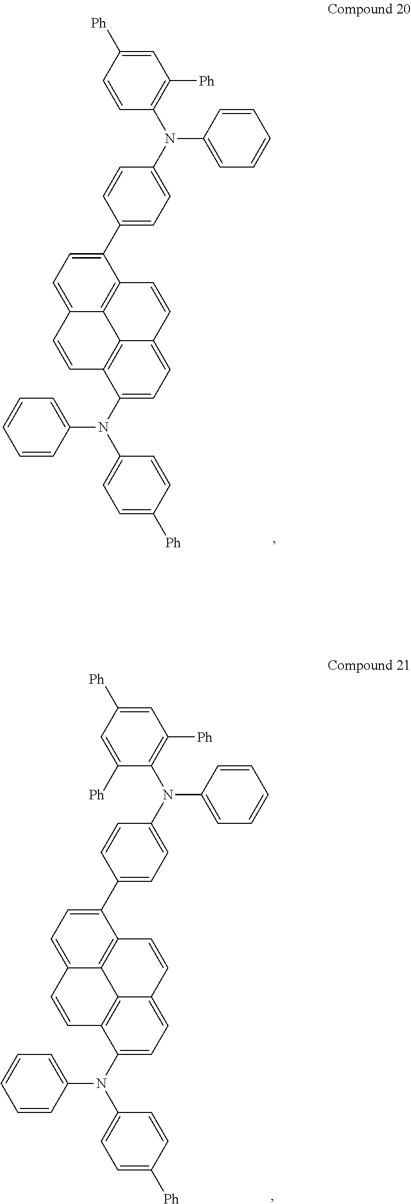 [SMILES: c1ccc(-c2ccc(N(c3ccccc3)c3ccc4ccc5c(-c6ccc(N(c7ccccc7)c7ccc(-c8ccccc8)cc7-c7ccccc7)cc6)ccc6ccc3c4c65)cc2)cc1 ; c1ccc(-c2ccc(N(c3ccccc3)c3ccc4ccc5c(-c6ccc(N(c7ccccc7)c7c(-c8ccccc8)cc(-c8ccccc8)cc7-c7ccccc7)cc6)ccc6ccc3c4c65)cc2)cc1]

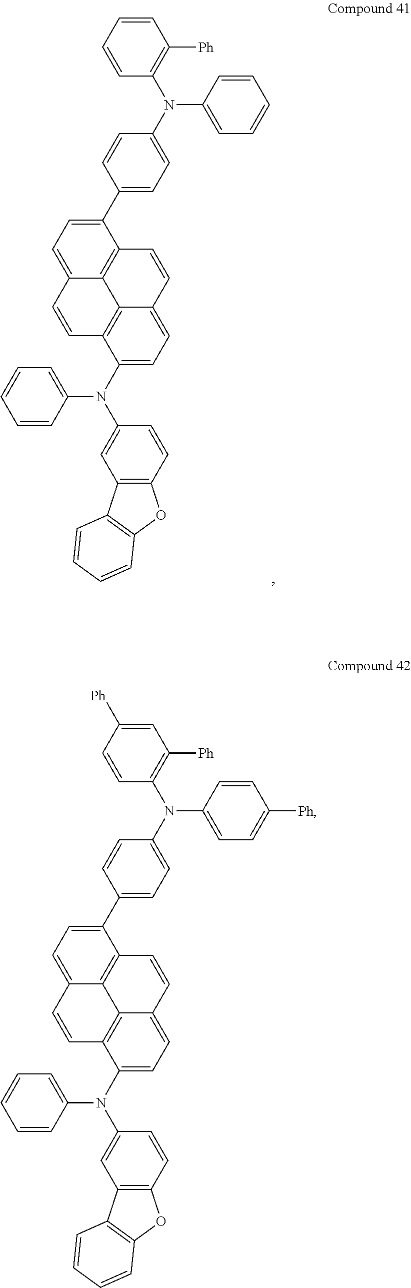 [SMILES: c1ccc(-c2ccccc2N(c2ccccc2)c2ccc(-c3ccc4ccc5c(N(c6ccccc6)c6ccc7oc8ccccc8c7c6)ccc6ccc3c4c65)cc2)cc1 ; c1ccc(-c2ccc(N(c3ccc(-c4ccc5ccc6c(N(c7ccccc7)c7ccc8oc9ccccc9c8c7)ccc7ccc4c5c76)cc3)c3ccc(-c4ccccc4)cc3-c3ccccc3)cc2)cc1]

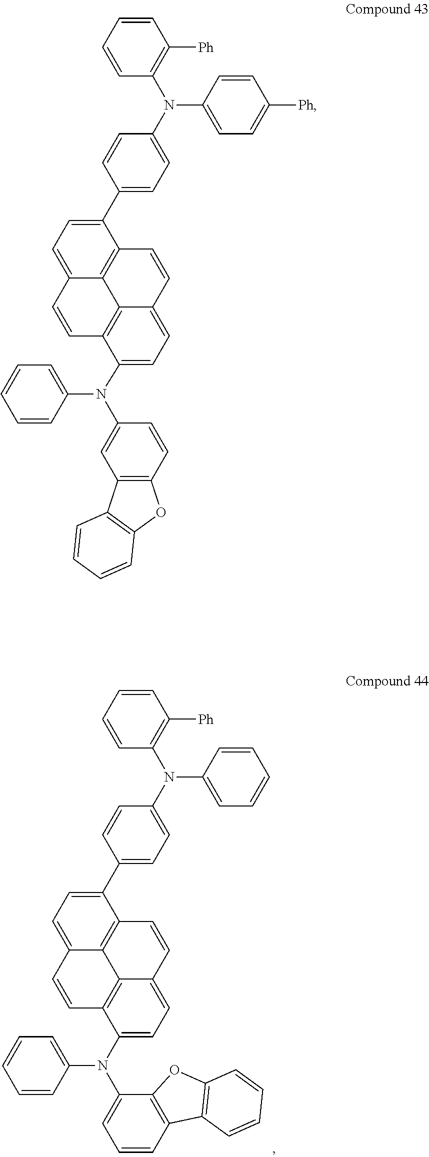 [SMILES: c1ccc(-c2ccc(N(c3ccc(-c4ccc5ccc6c(N(c7ccccc7)c7ccc8oc9ccccc9c8c7)ccc7ccc4c5c76)cc3)c3ccccc3-c3ccccc3)cc2)cc1 ; c1ccc(-c2ccccc2N(c2ccccc2)c2ccc(-c3ccc4ccc5c(N(c6ccccc6)c6cccc7c6oc6ccccc67)ccc6ccc3c4c65)cc2)cc1]

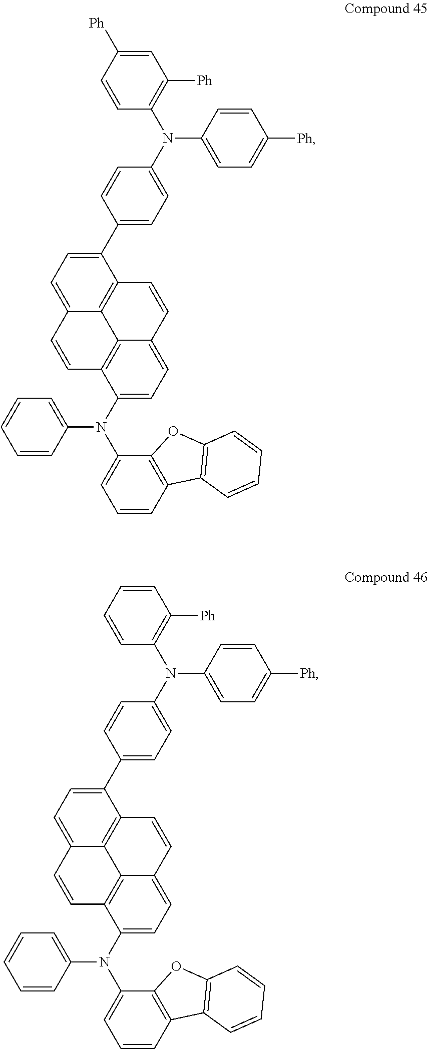 [SMILES: c1ccc(-c2ccc(N(c3ccc(-c4ccc5ccc6c(N(c7ccccc7)c7cccc8c7oc7ccccc78)ccc7ccc4c5c76)cc3)c3ccc(-c4ccccc4)cc3-c3ccccc3)cc2)cc1 ; c1ccc(-c2ccc(N(c3ccc(-c4ccc5ccc6c(N(c7ccccc7)c7cccc8c7oc7ccccc78)ccc7ccc4c5c76)cc3)c3ccccc3-c3ccccc3)cc2)cc1]

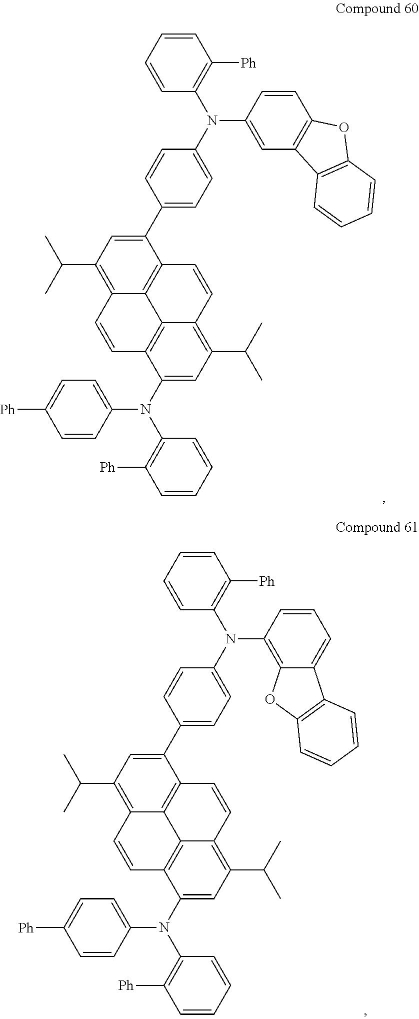 [SMILES: CC(C)c1cc(-c2ccc(N(c3ccc4oc5ccccc5c4c3)c3ccccc3-c3ccccc3)cc2)c2ccc3c(C(C)C)cc(N(c4ccc(-c5ccccc5)cc4)c4ccccc4-c4ccccc4)c4ccc1c2c34 ; CC(C)c1cc(-c2ccc(N(c3ccccc3-c3ccccc3)c3cccc4c3oc3ccccc34)cc2)c2ccc3c(C(C)C)cc(N(c4ccc(-c5ccccc5)cc4)c4ccccc4-c4ccccc4)c4ccc1c2c34]

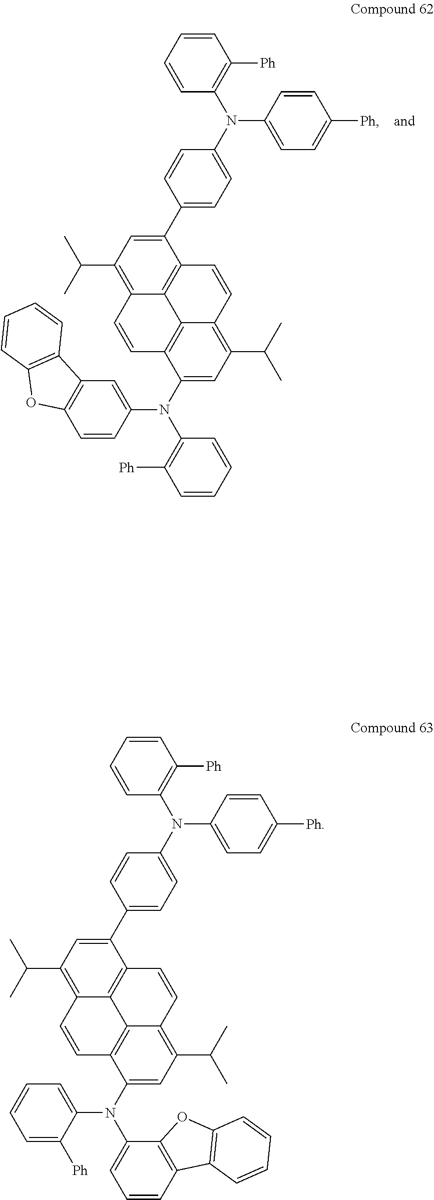 [SMILES: CC(C)c1cc(-c2ccc(N(c3ccc(-c4ccccc4)cc3)c3ccccc3-c3ccccc3)cc2)c2ccc3c(C(C)C)cc(N(c4ccc5oc6ccccc6c5c4)c4ccccc4-c4ccccc4)c4ccc1c2c34 ; CC(C)c1cc(-c2ccc(N(c3ccc(-c4ccccc4)cc3)c3ccccc3-c3ccccc3)cc2)c2ccc3c(C(C)C)cc(N(c4ccccc4-c4ccccc4)c4cccc5c4oc4ccccc45)c4ccc1c2c34]

According to another aspect of the present disclosure, a first device is also provided. The first device includes a first organic light emitting device, that includes an anode, a cathode, and an organic layer disposed between the anode and the cathode. The organic layer can include a host and a phosphorescent dopant. The organic layer can include a compound according to Formula I, and its variations as described herein. In some embodiments, the organic layer can also include a host material. In some embodiments, the host material can contain aromatic groups selected from the group consisting of naphthalene, triphenylene, anthracene, chrysene, triazene, carbazole, dibenzofuran, dibenzothiophene, and dibenzoselenophene.

The first device can be one or more of a consumer product, an organic light-emitting device and a lighting panel. The organic layer can be an emissive layer and the compound can be an emissive dopant in some embodiments, while the compound can be a non-emissive dopant in other embodiments.

In yet another aspect of the present disclosure, a formulation that comprises a compound according to Formula I is described. The formulation can include one or more components selected from the group consisting of a solvent, a host, a hole injection material, hole transport material, and an electron transport layer material, disclosed herein.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### HIL/HTL:

A hole injecting/transporting material to be used in the present invention is not particularly limited, and any compound may be used as long as the compound is typically used as a hole injecting/transporting material. Examples of the material include, but not limit to: a phthalocyanine or porphryin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

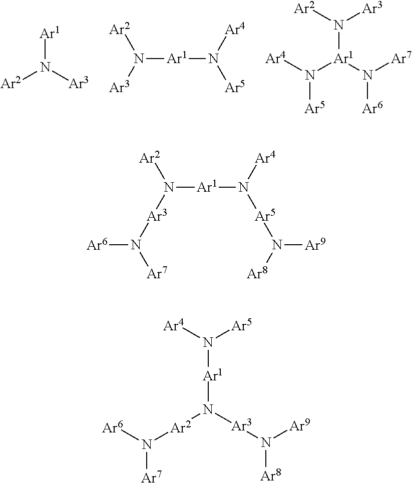

Each of Ar¹ to Ar⁹ is selected from the group consisting aromatic hydrocarbon cyclic compounds such as benzene, biphenyl, triphenyl, triphenylene, naphthalene, anthracene, phenalene, phenanthrene, fluorene, pyrene, chrysene, perylene, azulene; group consisting aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and group consisting 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Wherein each Ar is further substituted by a substituent selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof.

In one aspect, Ar¹ to Ar⁹ is independently selected from the group consisting of:

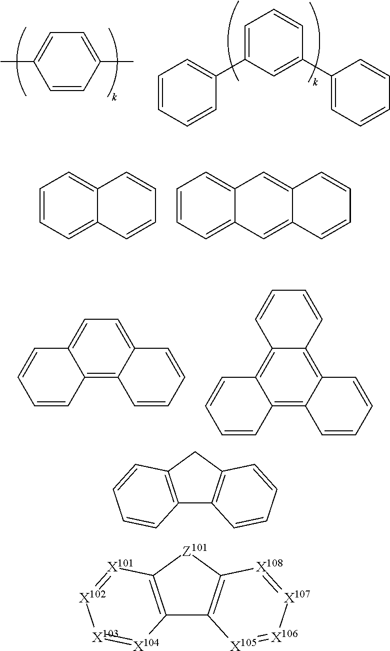

wherein k is an integer from 1 to 20; X¹⁰¹ to X¹⁰⁸ is C (including CH) or N; Z¹⁰¹ is NAr¹, O, or S; Ar¹ has the same group defined above.

Examples of metal complexes used in HIL or HTL include, but not limit to the following general formula:

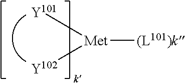

wherein Met is a metal, which can have an atomic weight greater than 40; (Y¹⁰¹-Y¹⁰²) is a bidentate ligand, Y¹⁰¹ and Y¹⁰² are independently selected from C, N, O, P, and S; L¹⁰¹ is an ancillary ligand; k′ is an integer value from 1 to the maximum number of ligands that may be attached to the metal; and k′+k″ is the maximum number of ligands that may be attached to the metal.

In one aspect, (Y¹⁰¹-Y¹⁰²) is a 2-phenylpyridine derivative. In another aspect, (Y¹⁰¹-Y¹⁰²) is a carbene ligand. In another aspect, Met is selected from Ir, Pt, Os, and Zn. In a further aspect, the metal complex has a smallest oxidation potential in solution vs. Fc⁺/Fc couple less than about 0.6 V.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. While the Table below categorizes host materials as preferred for devices that emit various colors, any host material may be used with any dopant so long as the triplet criteria is satisfied.

Examples of metal complexes used as host are preferred to have the following general formula:

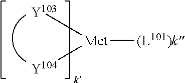

wherein Met is a metal; (Y¹⁰³-Y¹⁰⁴) is a bidentate ligand, Y¹⁰³ and Y¹⁰⁴ are independently selected from C, N, O, P, and S; L¹⁰¹ is an another ligand; k′ is an integer value from 1 to the maximum number of ligands that may be attached to the metal; and k′+k″ is the maximum number of ligands that may be attached to the metal,

In one aspect, the metal complexes are:

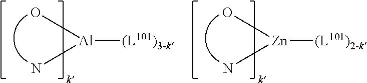

wherein (O—N) is a bidentate ligand, having metal coordinated to atoms O and N.

In another aspect, Met is selected from Ir and Pt. In a further aspect, (Y¹⁰³-Y¹⁰⁴) is a carbene ligand.

Examples of organic compounds used as host are selected from the group consisting aromatic hydrocarbon cyclic compounds such as benzene, biphenyl, triphenyl, triphenylene, naphthalene, anthracene, phenalene, phenanthrene, fluorene, pyrene, chrysene, perylene, azulene; group consisting aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and group consisting 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Wherein each group is further substituted by a substituent selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof

In one aspect, host compound contains at least one of the following groups in the molecule:

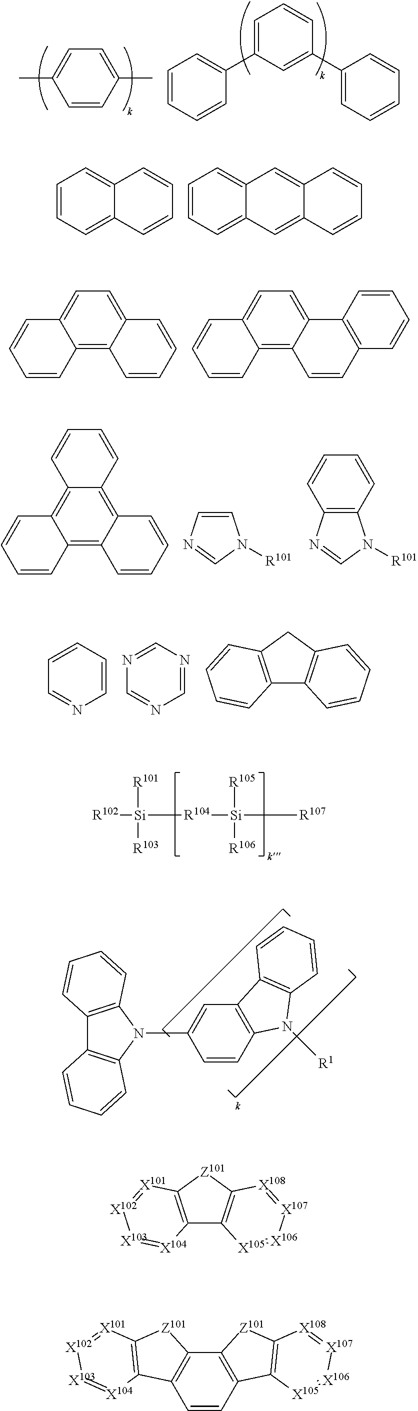

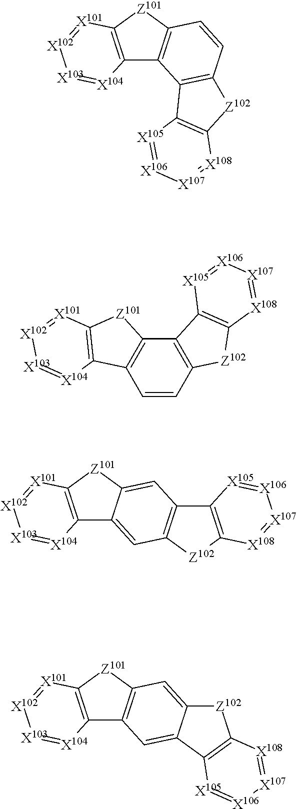

wherein R¹⁰¹ to R¹⁰⁷ is independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, when it is aryl or heteroaryl, it has the similar definition as Ar's mentioned above. k is an integer from 0 to 20 or 1 to 20; k′″ is an integer from 0 to 20. X¹⁰¹ to X¹⁰⁸ is selected from C (including CH) or N. Z¹⁰¹ and Z¹⁰² is selected from NR¹⁰¹, O, or S.

### HBL:

A hole blocking layer (HBL) may be used to reduce the number of holes and/or excitons that leave the emissive layer. The presence of such a blocking layer in a device may result in substantially higher efficiencies as compared to a similar device lacking a blocking layer. Also, a blocking layer may be used to confine emission to a desired region of an OLED.

In one aspect, compound used in HBL contains the same molecule or the same functional groups used as host described above.

In another aspect, compound used in HBL contains at least one of the following groups in the molecule:

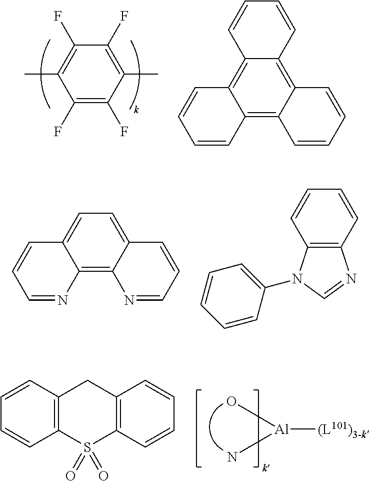

wherein k is an integer from 1 to 20; L¹⁰¹ is an another ligand, k′ is an integer from 1 to 3.

### ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

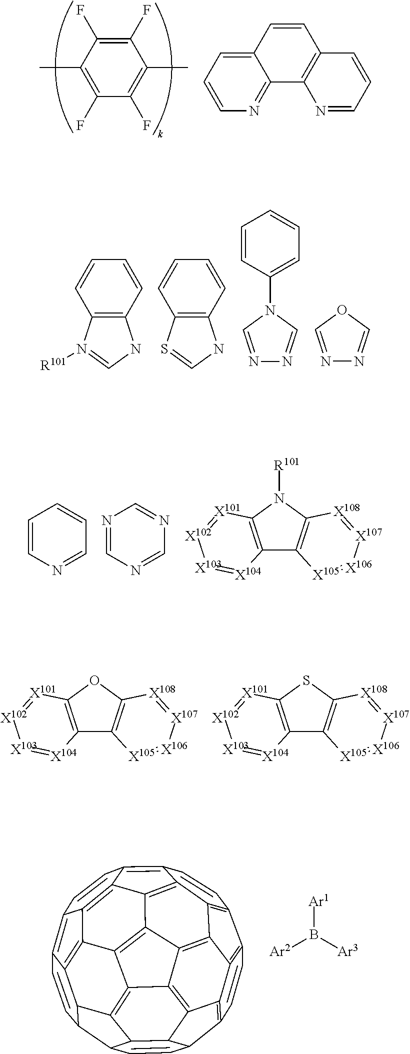

wherein R¹⁰¹ is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, when it is aryl or heteroaryl, it has the similar definition as Ar's mentioned above. Ar¹ to Ar³ has the similar definition as Ar's mentioned above. k is an integer from 1 to 20. X¹⁰¹ to X¹⁰⁸ is selected from C (including CH) or N.

In another aspect, the metal complexes used in ETL contains, but not limit to the following general formula:

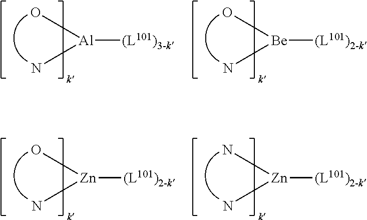

wherein (O—N) or (N—N) is a bidentate ligand, having metal coordinated to atoms O, N or N, N; L¹⁰¹ is another ligand; k′ is an integer value from 1 to the maximum number of ligands that may be attached to the metal.

In any above-mentioned compounds used in each layer of the OLED device, the hydrogen atoms can be partially or fully deuterated. Thus, any specifically listed substituent, such as, without limitation, methyl, phenyl, pyridyl, etc. encompasses undeuterated, partially deuterated, and fully deuterated versions thereof. Similarly, classes of substituents such as, without limitation, alkyl, aryl, cycloalkyl, heteroaryl, etc. also encompass undeuterated, partially deuterated, and fully deuterated versions thereof.

In addition to and/or in combination with the materials disclosed herein, many hole injection materials, hole transporting materials, host materials, dopant materials, exiton/hole blocking layer materials, electron transporting and electron injecting materials may be used in an OLED. Non-limiting examples of the materials that may be used in an OLED in combination with materials disclosed herein are listed in Table 1 below. Table 1 lists non-limiting classes of materials, non-limiting examples of compounds for each class, and references that disclose the materials.

TABLE 1

| | | |
|---|---|---|
| MATERIAL | EXAMPLES OF MATERIAL | PUBLICATIONS |

Hole injection materials

| | | |
|---|---|---|
| Phthalocyanine and porphryin compounds | 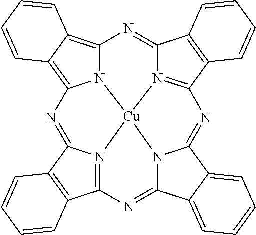 | Appl. Phys. Lett. 69, 2160 (1996) |
| Starburst triarylamines | 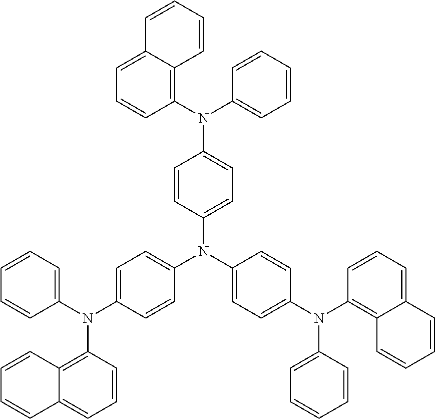 [SMILES: c1ccc(N(c2ccc(N(c3ccc(N(c4ccccc4)c4cccc5ccccc45)cc3)c3ccc(N(c4ccccc4)c4cccc5ccccc45)cc3)cc2)c2cccc3ccccc23)cc1] | J. Lumin. 72-.74, 985 (1997) |
| CFₓ Fluorohydrocarbon polymer | 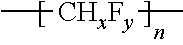 | Appl. Phys. Lett. 78, 673 (2001) |
| Conducting polymers (e.g., PEDOT:PSS, polyaniline, polypthiophene) | 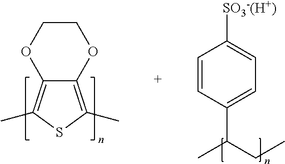 | Synth. Met. 87, 171 (1997) WO2007002683 |
| Phosphonic acid and sliane SAMs | 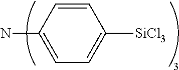 | US20030162053 |
| Triarylamine or polythiophene polymers with conductivity dopants | 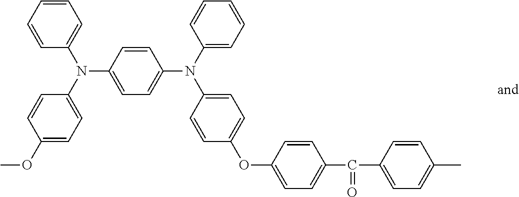 | EP1725079A1 |
| | 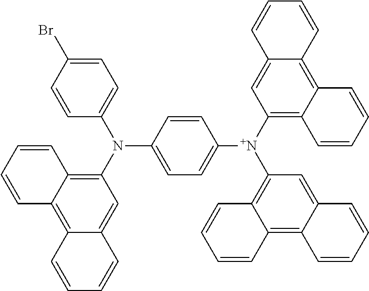 [SMILES: Brc1ccc(N(c2ccc([NH+](c3cc4ccccc4c4ccccc34)c3cc4ccccc4c4ccccc34)cc2)c2cc3ccccc3c3ccccc23)cc1] | |
| | 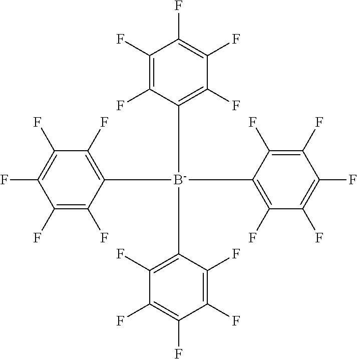 [SMILES: Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F] | |
| Organic compounds with conductive inorganic compounds, such as molybdenum and tungsten oxides | 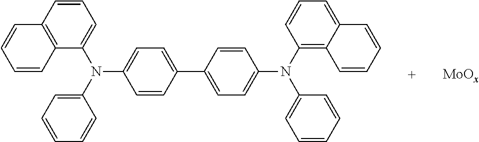 [SMILES: c1ccc(N(c2ccc(-c3ccc(N(c4ccccc4)c4cccc5ccccc45)cc3)cc2)c2cccc3ccccc23)cc1] | US20050123751 SID Symposium Digest, 37, 923 (2006) WO2009018009 |
| n-type semiconducting organic complexes | 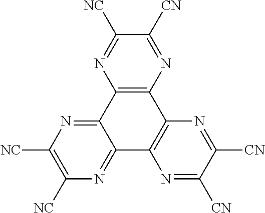 [SMILES: N#Cc1nc2c3nc(C#N)c(C#N)nc3c3nc(C#N)c(C#N)nc3c2nc1C#N] | US20020158242 |
| Metal organometallic complexes | 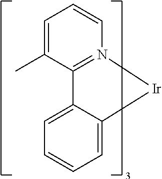 | US20060240279 |
| Cross-linkable compounds | 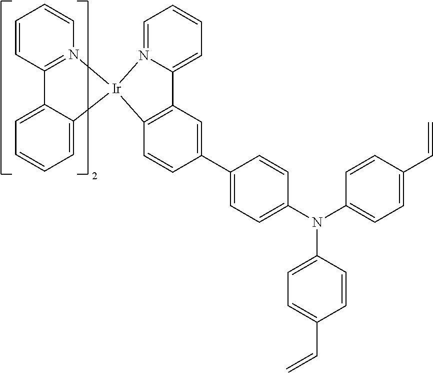 | US20080220265 |
| Polythiophene based polymers and copolymers | 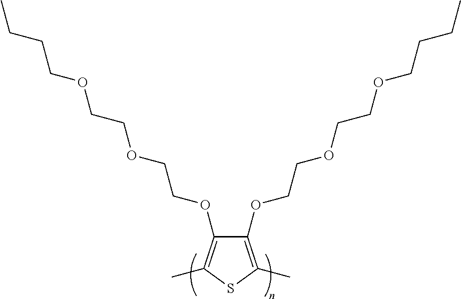 | WO 2011075644 EP2350216 |

Hole transporting materials

| Triarylamines (e.g., TPD, α-NPD) | 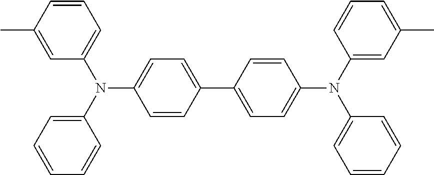 | Appl. Phys. Lett. 51, 913 (1987) |
|---|---|---|
| | 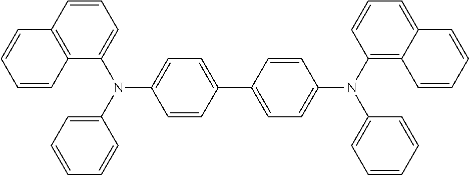 [SMILES: c1ccc(N(c2ccc(-c3ccc(N(c4ccccc4)c4cccc5ccccc45)cc3)cc2)c2cccc3ccccc23)cc1] | US5061569 |
| | 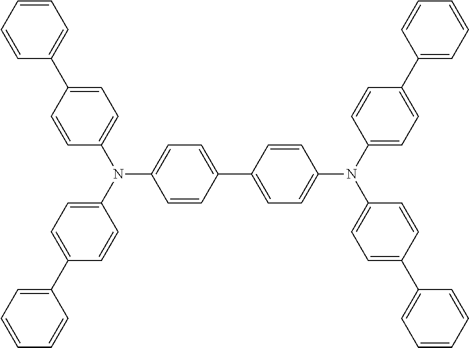 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1] | EP650955 |
| | 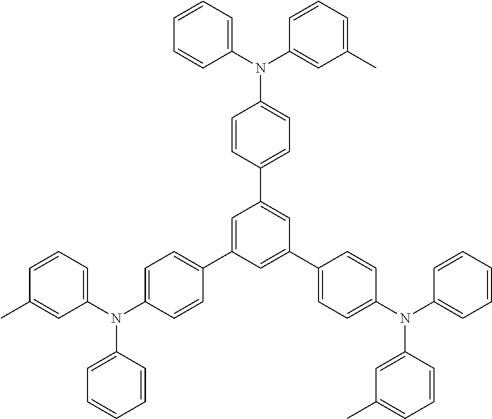 [SMILES: Cc1cccc(N(c2ccccc2)c2ccc(-c3cc(-c4ccc(N(c5ccccc5)c5cccc(C)c5)cc4)cc(-c4ccc(N(c5ccccc5)c5cccc(C)c5)cc4)c3)cc2)c1] | J. Mater. Chem. 3, 319 (1993) |
| | 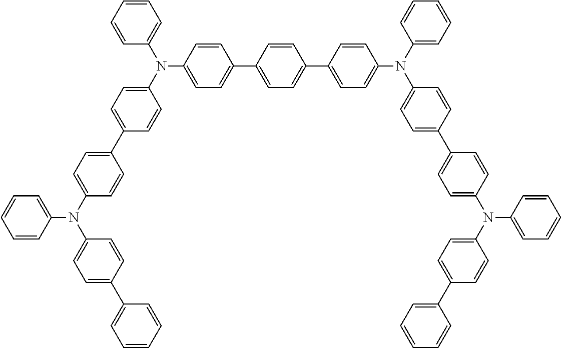 [SMILES: c1ccc(-c2ccc(N(c3ccccc3)c3ccc(-c4ccc(N(c5ccccc5)c5ccc(-c6ccc(-c7ccc(N(c8ccccc8)c8ccc(-c9ccc(N(c%10ccccc%10)c%10ccc(-c%11ccccc%11)cc%10)cc9)cc8)cc7)cc6)cc5)cc4)cc3)cc2)cc1] | Appl. Phys. Lett. 90, 183503 (2007) |
| | 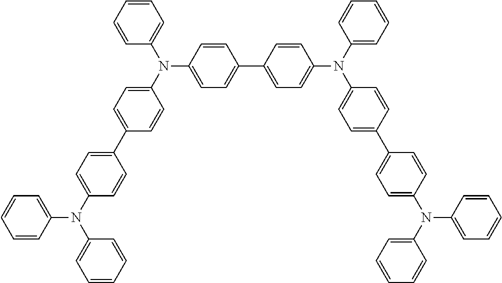 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1] | Appl. Phys. Lett. 90, 183503 (2007) |
| Triaylamine on spirofluorene core | 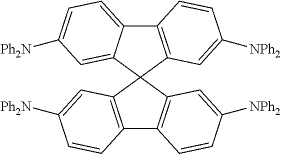 | Synth. Met. 91, 209 (1997) |
| Arylamine carbazole compounds | 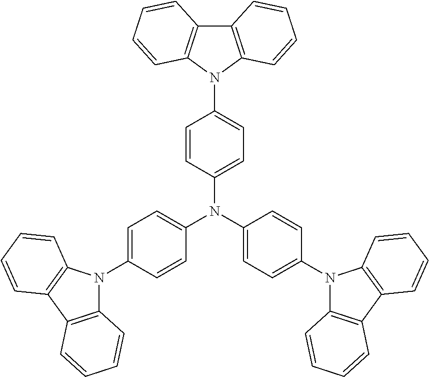 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1] | Adv. Mater. 6, 677 (1994), US20080124572 |
| Triarylamine with (di)benzothiophene/ (di)benzofuran | 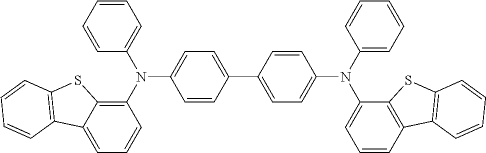 [SMILES: c1ccc(N(c2ccc(-c3ccc(N(c4ccccc4)c4cccc5c4sc4ccccc45)cc3)cc2)c2cccc3c2sc2ccccc23)cc1] | US20070278938, US20080106190 US20110163302 |
| Indolocarbazoles | 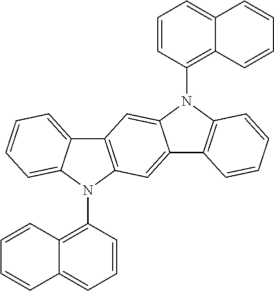 [SMILES: c1ccc2c(-n3c4ccccc4c4cc5c(cc43)c3ccccc3n5-c3cccc4ccccc34)cccc2c1] | Synth. Met. 111, 421 (2000) |
| Isoindole compounds | 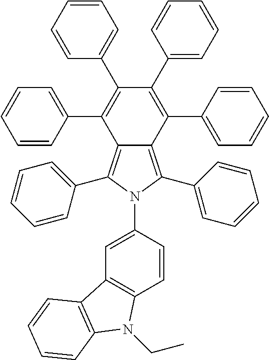 [SMILES: CCn1c2ccccc2c2cc(-n3c(-c4ccccc4)c4c(-c5ccccc5)c(-c5ccccc5)c(-c5ccccc5)c(-c5ccccc5)c4c3-c3ccccc3)ccc21] | Chem. Mater. 15, 3148 (2003) |
| Metal carbene complexes | 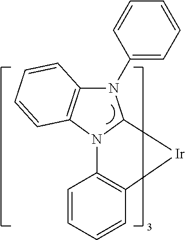 | US20080018221 |
| Phosphorescent OLED host materials | | |
| Red hosts | | |
| Arylcarbazoles | 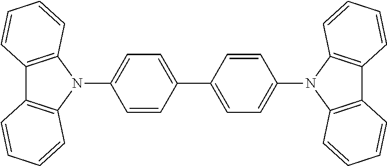 [SMILES: c1ccc2c(c1)c1ccccc1n2-c1ccc(-c2ccc(-n3c4ccccc4c4ccccc43)cc2)cc1] | Appl. Phys. Lett. 78, 1622 (2001) |
| Metal 8-hydroxyquinolates (e.g., Alq₃, BAlq) | 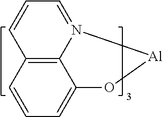 | Nature 395, 151 (1998) |
| | 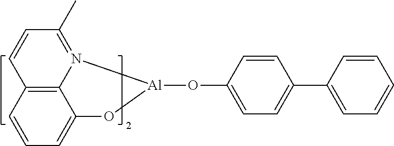 | US20060202194 |
| | 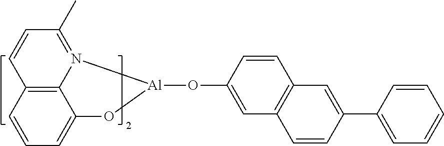 | WO2005014551 |
| | 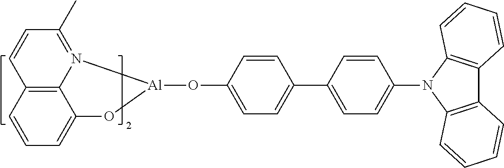 | WO2006072002 |
| Metal phenoxybenzothiazole compounds | 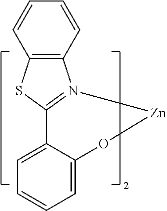 | Appl. Phys. Lett. 90, 123509 (2007) |
| Conjugated oligomers and polymers (e.g., polyfluorene) | 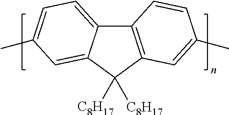 | Org. Electron. 1, 15 (2000) |
| Aromatic fused rings | 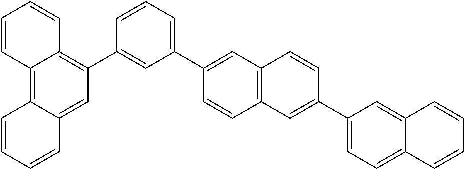 [SMILES: c1cc(-c2ccc3cc(-c4ccc5ccccc5c4)ccc3c2)cc(-c2cc3ccccc3c3ccccc23)c1] | WO2009066779, WO2009066778, WO2009063833, US20090045731, US20090045730, WO2009008311, US20090008605, US20090009065 |
| Zinc complexes | 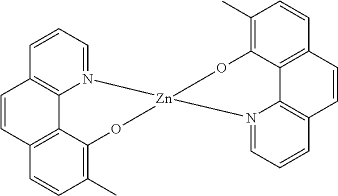 | WO2010056066 |
| Chrysene based compounds | 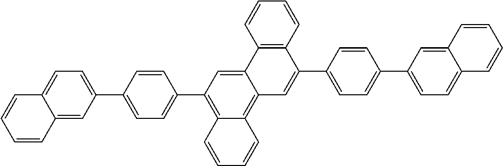 [SMILES: c1ccc2cc(-c3ccc(-c4cc5c6ccccc6c(-c6ccc(-c7ccc8ccccc8c7)cc6)cc5c5ccccc45)cc3)ccc2c1] | WO2011086863 |

Green hosts

| | | |
|---|---|---|
| Arylcarbazoles | 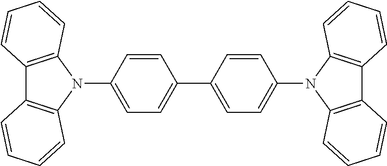 [SMILES: c1ccc2c(c1)c1ccccc1n2-c1ccc(-c2ccc(-n3c4ccccc4c4ccccc43)cc2)cc1] | Appl. Phys. Lett. 78, 1622 (2001) |
| | 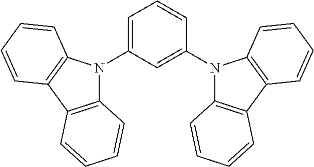 [SMILES: c1cc(-n2c3ccccc3c3ccccc32)cc(-n2c3ccccc3c3ccccc32)c1] | US20030175553 |
| | 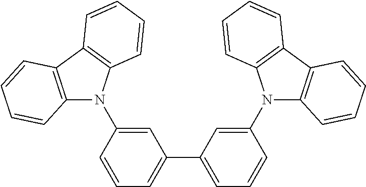 [SMILES: c1cc(-c2cccc(-n3c4ccccc4c4ccccc43)c2)cc(-n2c3ccccc3c3ccccc32)c1] | WO2001039234 |
| Aryltriphenylene compounds | 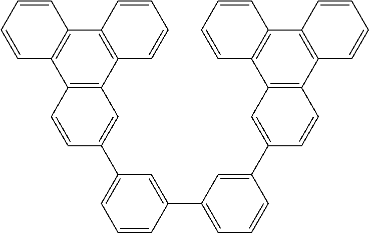 [SMILES: c1cc(-c2cccc(-c3ccc4c5ccccc5c5ccccc5c4c3)c2)cc(-c2ccc3c4ccccc4c4ccccc4c3c2)c1] | US20060280965 |
| | 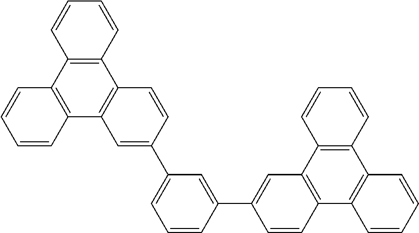 [SMILES: c1cc(-c2ccc3c4ccccc4c4ccccc4c3c2)cc(-c2ccc3c4ccccc4c4ccccc4c3c2)c1] | US20060280965 |
| | 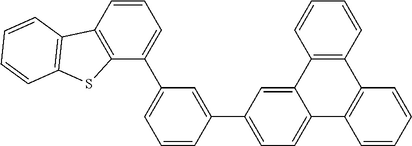 [SMILES: c1cc(-c2ccc3c4ccccc4c4ccccc4c3c2)cc(-c2cccc3c2sc2ccccc23)c1] | WO2009021126 |
| Poly-fused heteroaryl compounds | 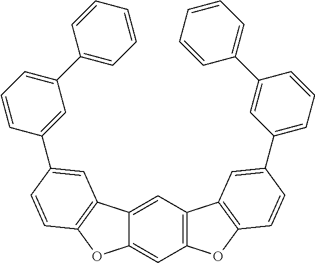 [SMILES: c1ccc(-c2cccc(-c3ccc4oc5cc6oc7ccc(-c8cccc(-c9ccccc9)c8)cc7c6cc5c4c3)c2)cc1] | US20090309488 US20090302743 US20100012931 |
| Donor acceptor type molecules | 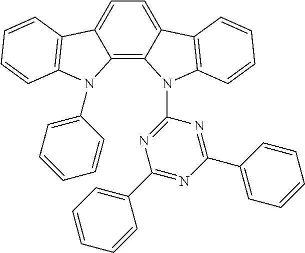 [SMILES: c1ccc(-c2nc(-c3ccccc3)nc(-n3c4ccccc4c4ccc5c6ccccc6n(-c6ccccc6)c5c43)n2)cc1] | WO2008056746 |
| | 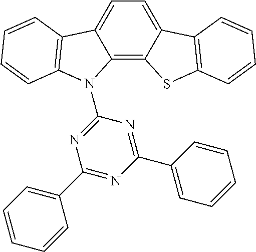 [SMILES: c1ccc(-c2nc(-c3ccccc3)nc(-n3c4ccccc4c4ccc5c6ccccc6sc5c43)n2)cc1] | WO2010107244 |
| Aza-carbazole/ DBT/DBF | 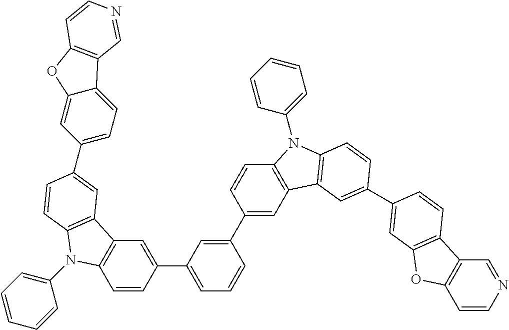 [SMILES: c1ccc(-n2c3ccc(-c4cccc(-c5ccc6c(c5)c5cc(-c7ccc8c(c7)oc7ccncc78)ccc5n6-c5ccccc5)c4)cc3c3cc(-c4ccc5c(c4)oc4ccncc45)ccc32)cc1] | JP2008074939 |
| | 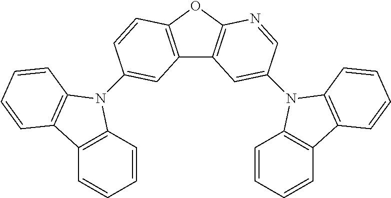 [SMILES: c1ccc2c(c1)c1ccccc1n2-c1ccc2oc3ncc(-n4c5ccccc5c5ccccc54)cc3c2c1] | US20100187984 |
| Polymers (e.g., PVK) | 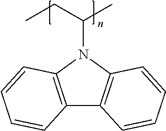 | Appl. Phys. Lett. 77, 2280 (2000) |
| Spirofluorene compounds | 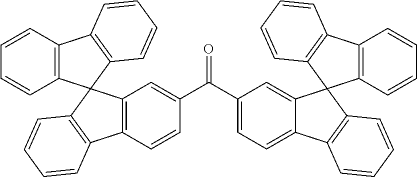 [SMILES: O=C(c1ccc2c(c1)C1(c3ccccc3-c3ccccc31)c1ccccc1-2)c1ccc2c(c1)C1(c3ccccc3-c3ccccc31)c1ccccc1-2] | WO2004093207 |
| Metal phenoxybenzooxazole compounds | 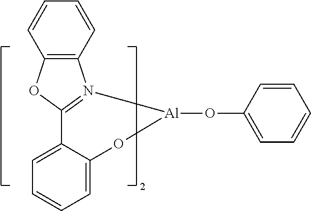 | WO2005089025 |
| | 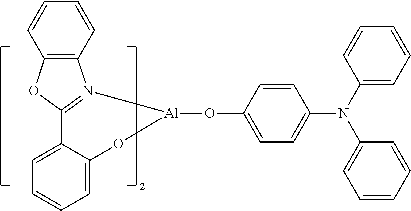 | WO2006132173 |
| | 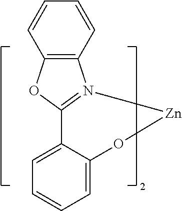 | JP200511610 |
| Spirofluorene- carbazole compounds | 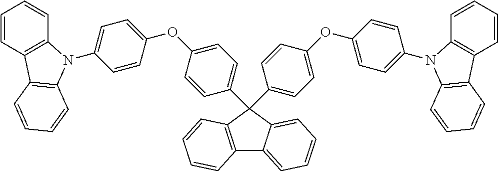 [SMILES: c1ccc2c(c1)-c1ccccc1C2(c1ccc(Oc2ccc(-n3c4ccccc4c4ccccc43)cc2)cc1)c1ccc(Oc2ccc(-n3c4ccccc4c4ccccc43)cc2)cc1] | JP2007254297 |
| | 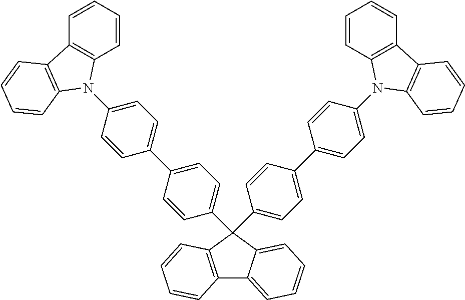 [SMILES: c1ccc2c(c1)-c1ccccc1C2(c1ccc(-c2ccc(-n3c4ccccc4c4ccccc43)cc2)cc1)c1ccc(-c2ccc(-n3c4ccccc4c4ccccc43)cc2)cc1] | JP2007254297 |
| Indolocabazoles | 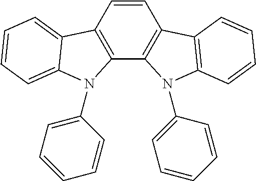 [SMILES: c1ccc(-n2c3ccccc3c3ccc4c5ccccc5n(-c5ccccc5)c4c32)cc1] | WO2007063796 |
| | 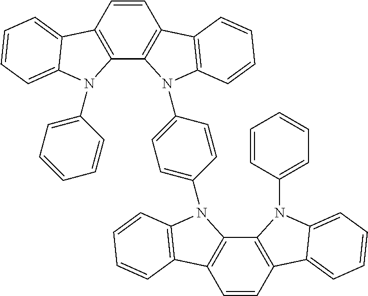 [SMILES: c1ccc(-n2c3ccccc3c3ccc4c5ccccc5n(-c5ccc(-n6c7ccccc7c7ccc8c9ccccc9n(-c9ccccc9)c8c76)cc5)c4c32)cc1] | WO2007063754 |
| 5-member ring electron deficient heterocycles (e.g., triazole, oxadiazole) | 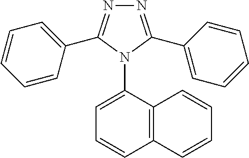 [SMILES: c1ccc(-c2nnc(-c3ccccc3)n2-c2cccc3ccccc23)cc1] | J. Appl. Phys. 90, 5048 (2001) |
| | 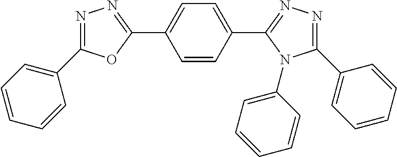 [SMILES: c1ccc(-c2nnc(-c3ccc(-c4nnc(-c5ccccc5)n4-c4ccccc4)cc3)o2)cc1] | WO2004107822 |
| Tetraphenylene complexes | 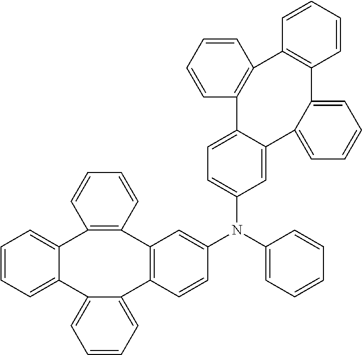 [SMILES: c1ccc(N(c2ccc3c(c2)-c2ccccc2-c2ccccc2-c2ccccc2-3)c2ccc3c(c2)-c2ccccc2-c2ccccc2-c2ccccc2-3)cc1] | US20050112407 |
| Metal phenoxypyridine compounds | 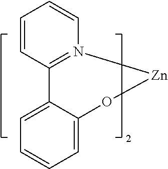 | WO2005030900 |
| Metal coordination complexes (e.g., Zn, Al with N\hat{ }N ligands) | 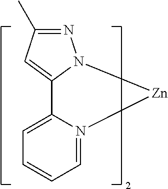 | US20040137268, US20040137267 |

Blue hosts

| Arylcarbazoles | 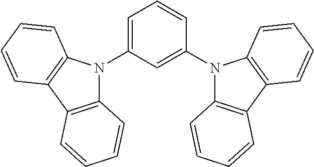 [SMILES: c1cc(-n2c3ccccc3c3ccccc32)cc(-n2c3ccccc3c3ccccc32)c1] | Appl. Phys. Lett, 82, 2422 (2003) |
|---|---|---|
| | 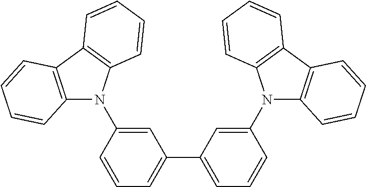 [SMILES: c1cc(-c2cccc(-n3c4ccccc4c4ccccc43)c2)cc(-n2c3ccccc3c3ccccc32)c1] | US20070190359 |
| Dibenzothiophene/ Dibenzofuran- carbazole compounds | 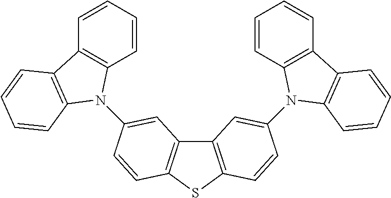 [SMILES: c1ccc2c(c1)c1ccccc1n2-c1ccc2sc3ccc(-n4c5ccccc5c5ccccc54)cc3c2c1] | WO2006114966, US20090167162 |
| | 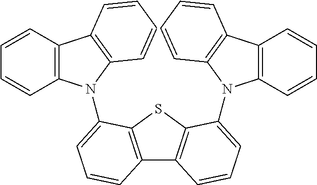 [SMILES: c1cc(-n2c3ccccc3c3ccccc32)c2sc3c(-n4c5ccccc5c5ccccc54)cccc3c2c1] | US20090167162 |
| | 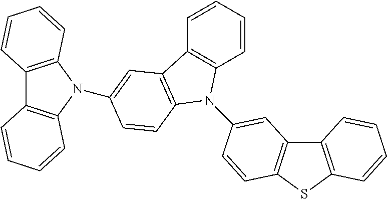 [SMILES: c1ccc2c(c1)sc1ccc(-n3c4ccccc4c4cc(-n5c6ccccc6c6ccccc65)ccc43)cc12] | WO2009086028 |
| | 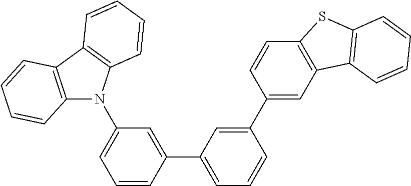 [SMILES: c1cc(-c2cccc(-n3c4ccccc4c4ccccc43)c2)cc(-c2ccc3sc4ccccc4c3c2)c1] | US20090030202, US20090017330 |
| | 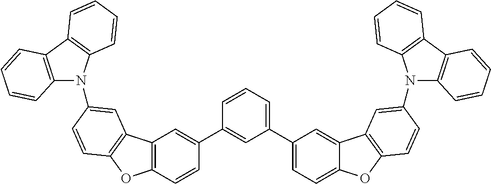 [SMILES: c1cc(-c2ccc3oc4ccc(-n5c6ccccc6c6ccccc65)cc4c3c2)cc(-c2ccc3oc4ccc(-n5c6ccccc6c6ccccc65)cc4c3c2)c1] | US20100084966 |
| Silicon aryl compounds | 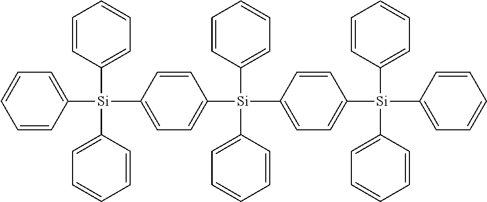 [SMILES: c1ccc([Si](c2ccccc2)(c2ccccc2)c2ccc([Si](c3ccccc3)(c3ccccc3)c3ccc([Si](c4ccccc4)(c4ccccc4)c4ccccc4)cc3)cc2)cc1] | US20050238919 |
| | 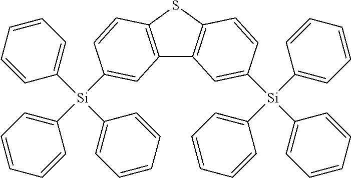 [SMILES: c1ccc([Si](c2ccccc2)(c2ccccc2)c2ccc3sc4ccc([Si](c5ccccc5)(c5ccccc5)c5ccccc5)cc4c3c2)cc1] | WO2009003898 |
| Silicon/Germanium aryl compounds | 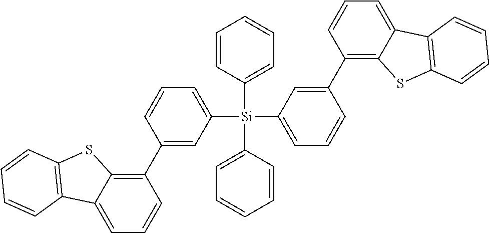 [SMILES: c1ccc([Si](c2ccccc2)(c2cccc(-c3cccc4c3sc3ccccc34)c2)c2cccc(-c3cccc4c3sc3ccccc34)c2)cc1] | EP2034538A |
| Aryl benzoyl ester | 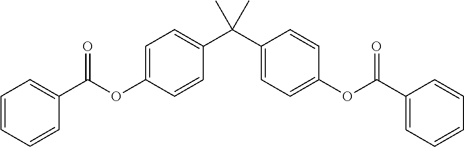 [SMILES: CC(C)(c1ccc(OC(=O)c2ccccc2)cc1)c1ccc(OC(=O)c2ccccc2)cc1] | WO2006100298 |
| Carbazole linked by non-conjugated groups | 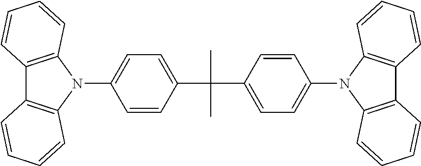 [SMILES: CC(C)(c1ccc(-n2c3ccccc3c3ccccc32)cc1)c1ccc(-n2c3ccccc3c3ccccc32)cc1] | US20040115476 |
| Aza-carbazoles | 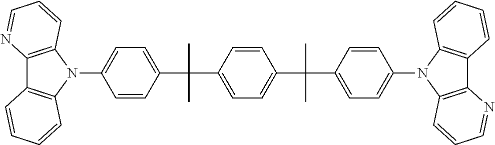 [SMILES: CC(C)(c1ccc(-n2c3ccccc3c3ncccc32)cc1)c1ccc(C(C)(C)c2ccc(-n3c4ccccc4c4ncccc43)cc2)cc1] | US20060121308 |
| High triplet metal organometallic complex | 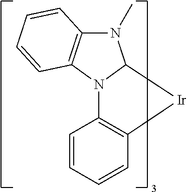 | US7154114 |
| Phosphorescent dopants | | |
| Red dopants | | |
| Heavy metal porphyrins (e.g., PtOEP) | 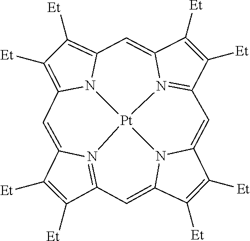 | Nature 395, 151 (1998) |
| Iridium (III) organometallic complexes | 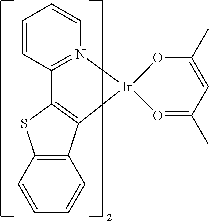 | Appl. Phys. Lett. 78, 1622 (2001) |
| | 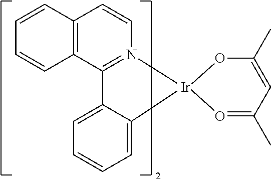 | US2006835469 |
| | 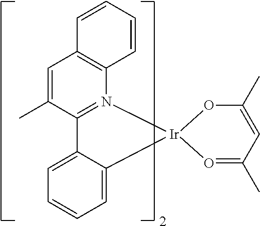 | US2006835469 |
| | 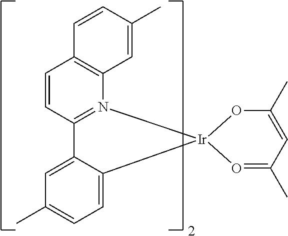 | US20060202194 |
| | 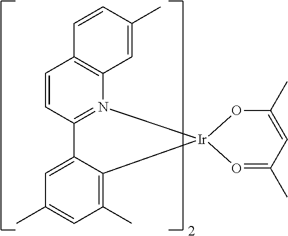 | US20060202194 |
| | 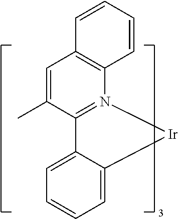 | US20070087321 |
| | 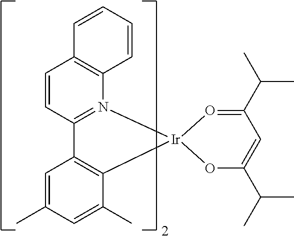 | US20080261076 US20100090591 |
| | 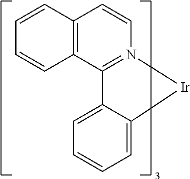 | US20070087321 |
| | 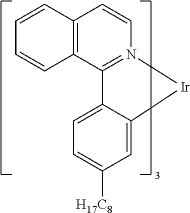 | Adv. Mater. 19, 739 (2007) |
| | 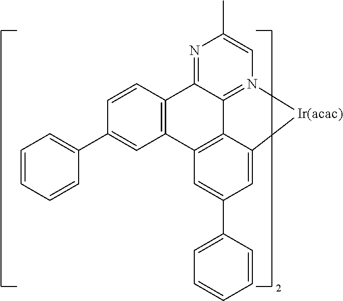 | WO2009100991 |
| | 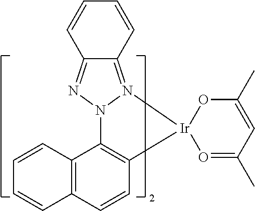 | WO2008101842 |
| | 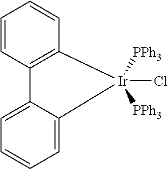 | US7232618 |
| Platinum (II) organometallic complexes | 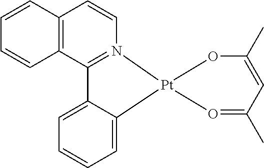 | WO2003040257 |
| | 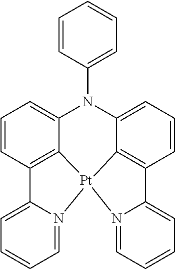 | US20070103060 |
| Osminum (III) complexes | 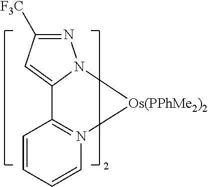 | Chem. Mater. 17, 3532 (2005) |
| Ruthenium (II) complexes | 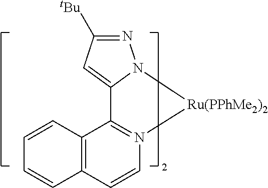 | Adv. Mater. 17, 1059 (2005) |
| Rhenium (I), (II), and (III) complexes | 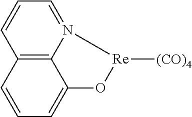 | US20050244673 |

Green dopants

| | | |
|---|---|---|
| Iridium (III) organometallic complexes | 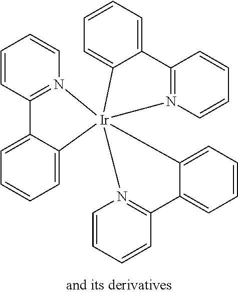 | Inorg. Chem. 40, 1704 (2001) |
| | 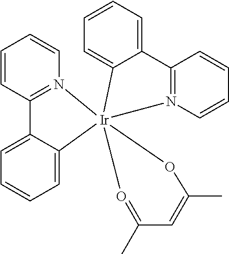 | US20020034656 |
| | 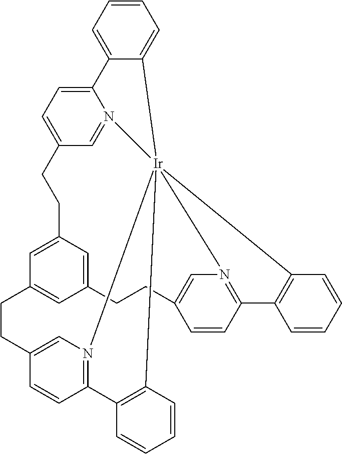 | US7332232 |
| | 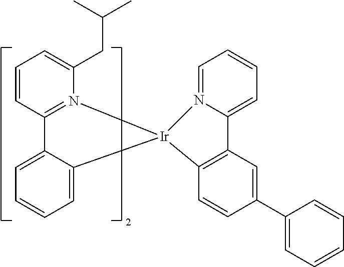 | US20090108737 |
| | 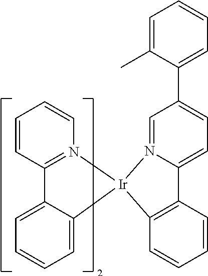 | WO2010028151 |
| | 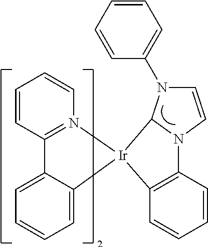 | EP1841834B |
| | 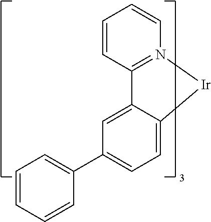 | US20060127696 |
| | 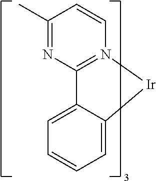 | US20090039776 |
| | 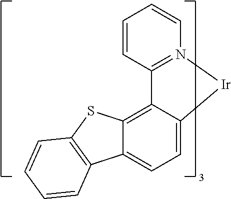 | US6921915 |
| | 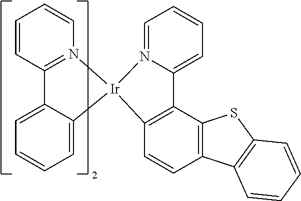 | US20100244004 |
| | 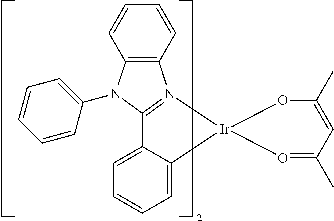 | US6687266 |
| | 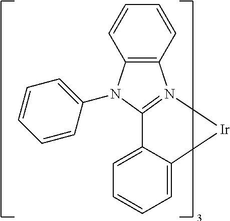 | Chem. Mater. 16, 2480 (2004) |
| | 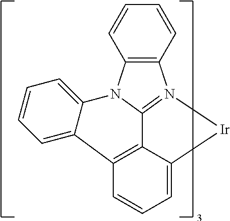 | US20070190359 |
| | 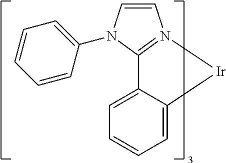 | US 20060008670 JP2007123392 |
| | 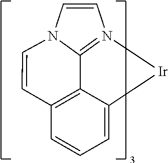 | WO2010086089, WO2011044988 |
| | 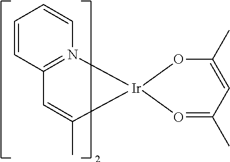 | Adv. Mater. 16, 2003 (2004) |
| | 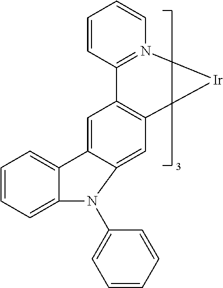 | Angew. Chem. Int. Ed. 2006, 45, 7800 |
| | 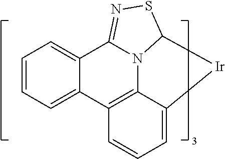 | WO2009050290 |
| | 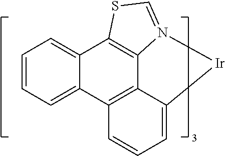 | US20090165846 |
| | 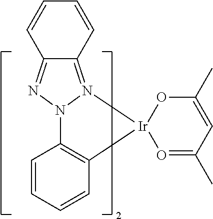 | US20080015355 |
| | 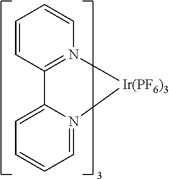 | US20010015432 |
| | 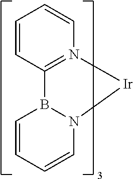 | US20100295032 |
| Monomer for polymeric metal organometallic compounds | 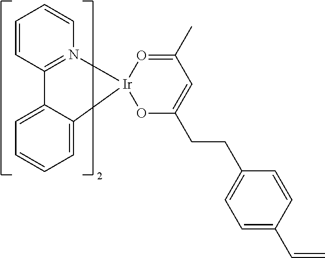 | US7250226, US7396598 |
| Pt(II) organometallic complexes, including polydentated ligands | 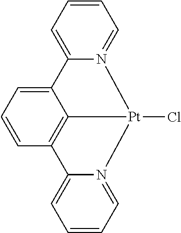 | Appl. Phys. Lett. 86, 153505 (2005) |
| | 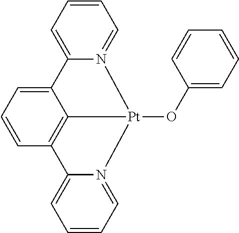 | Appl. Phys. Lett. 86, 153505 (2005) |
| | 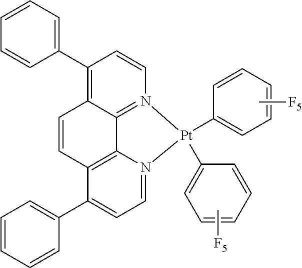 | Chem. Lett. 34, 592 (2005) |
| | 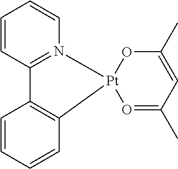 | WO2002015645 |
| | 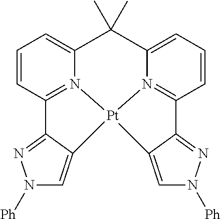 | US20060263635 |
| | 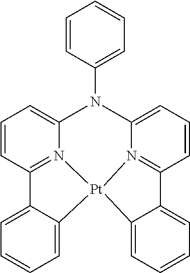 | US20060182992 US20070103060 |
| Cu complexes | 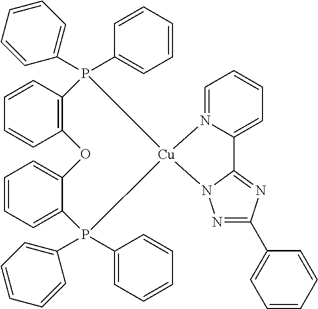 | WO2009000673 |
| | 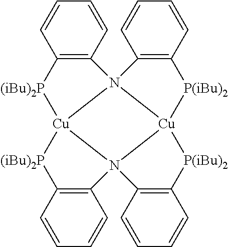 | US20070111026 |
| Gold complexes | 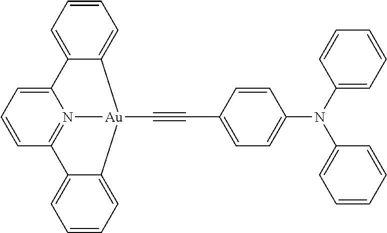 | Chem. Commun. 2906 (2005) |
| Rhenium (III) complexes | 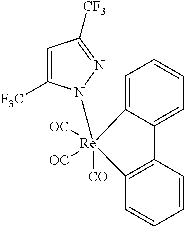 | Inorg. Chem. 42, 1248 (2003) |
| Osmium (II) complexes | 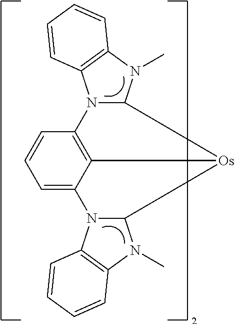 | US7279704 |
| Deuterated organometallic complexes | 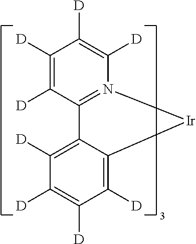 | US20030138657 |
| Organometallic complexes with two or more metal centers | 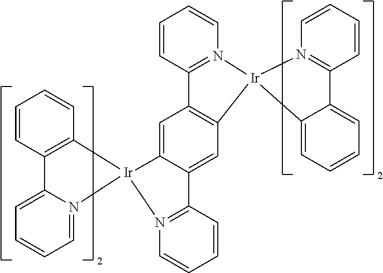 | US20030152802 |
| | 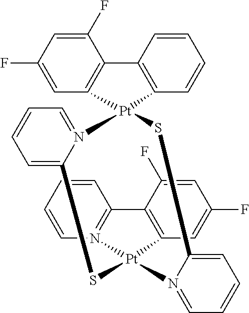 | US7090928 |

Blue dopants

| | | |
|---|---|---|
| Iridium (III) organometallic complexes | 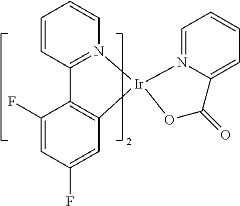 | WO2002002714 |
| | 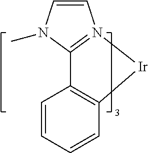 | WO2006009024 |
| | 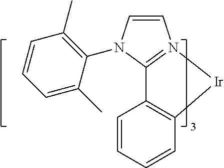 | US20060251923 US20110057559 US20110204333 |
| | 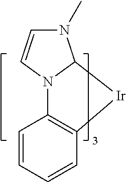 | US7393599, WO2006056418, US20050260441, WO2005019373 |
| | 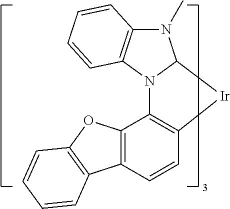 | US7534505 |
| | 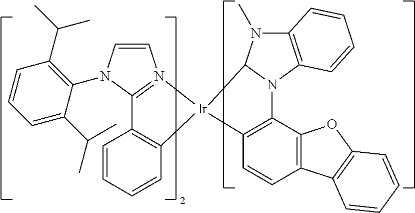 | WO2011051404 |
| | 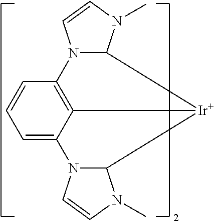 | US7445855 |
| | 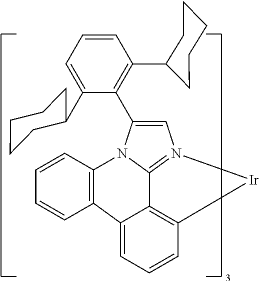 | US20070190359, US20080297033 US20100148663 |
| | 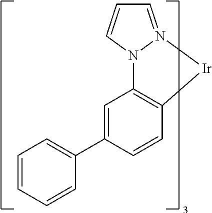 | US7338722 |
| | 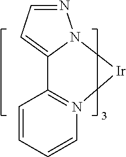 | US20020134984 |
| | 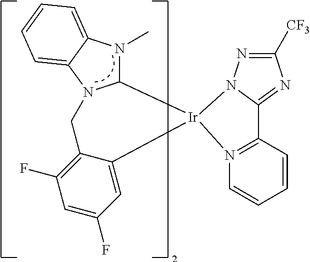 | Angew. Chem. Int. Ed. 47, 4542 (2008) |
| | 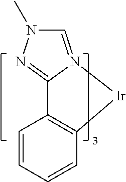 | Chem. Mater. 18, 5119 (2006) |
| | 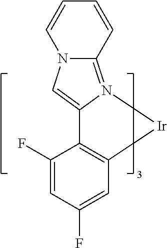 | Inorg. Chem. 46, 4308 (2007) |
| | 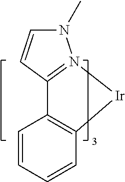 | WO2005123873 |
| | 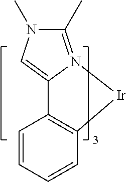 | WO2005123873 |
| | 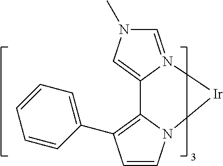 | WO2007004380 |
| | 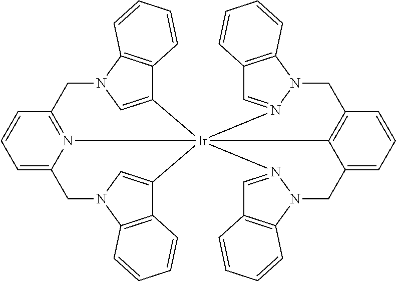 | WO2006082742 |
| Osmium (II) complexes | 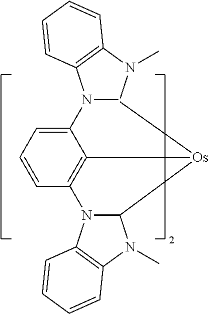 | US7279704 |
| | 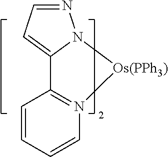 | Organometallics 23, 3745 (2004) |
| Gold complexes | 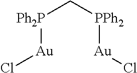 | Appl. Phys. Lett.74, 1361 (1999) |
| Platinum (II) complexes | 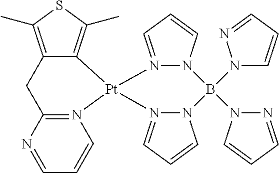 | WO2006098120, WO2006103874 |
| Pt tetradentate complexes with at least one metal- carbene bond | 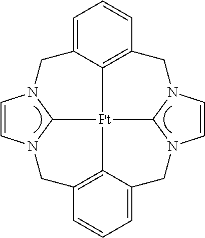 | US7655323 |

Exciton/hole blocking layer materials

| | | |
|---|---|---|
| Bathocuprine compounds (e.g., BCP, BPhen) | 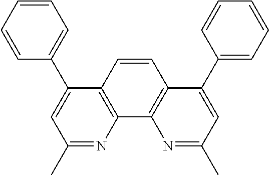 [SMILES: Cc1cc(-c2ccccc2)c2ccc3c(-c4ccccc4)cc(C)nc3c2n1] | Appl. Phys. Lett. 75, 4 (1999) |
| | 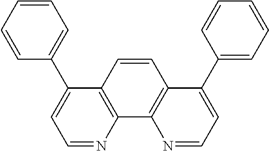 [SMILES: c1ccc(-c2ccnc3c2ccc2c(-c4ccccc4)ccnc23)cc1] | Appl. Phys. Lett. 79, 449 (2001) |
| Metal 8- hydroxyquinolates (e.g., BAlq) | 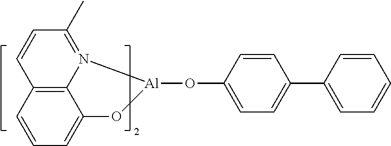 | Appl, Phys. Lett. 81, 162 (2002) |
| 5-member ring electron deficient heterocycles such as triazole, oxadiazole, imidazole, benzoimidazole | 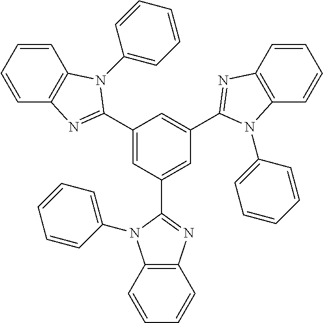 [SMILES: c1ccc(-n2c(-c3cc(-c4nc5ccccc5n4-c4ccccc4)cc(-c4nc5ccccc5n4-c4ccccc4)c3)nc3ccccc32)cc1] | Appl. Phys. Lett. 81, 162 (2002) |
| Triphenylene compounds | 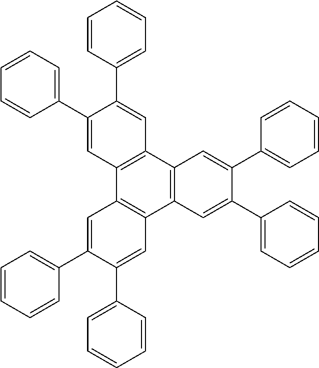 [SMILES: c1ccc(-c2cc3c4cc(-c5ccccc5)c(-c5ccccc5)cc4c4cc(-c5ccccc5)c(-c5ccccc5)cc4c3cc2-c2ccccc2)cc1] | US20050025993 |
| Fluorinated aromatic compounds | 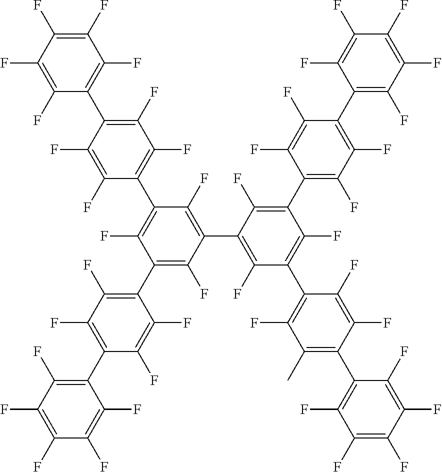 [SMILES: Cc1c(F)c(-c2c(F)c(-c3c(F)c(F)c(-c4c(F)c(F)c(F)c(F)c4F)c(F)c3F)c(F)c(-c3c(F)c(-c4c(F)c(F)c(-c5c(F)c(F)c(F)c(F)c5F)c(F)c4F)c(F)c(-c4c(F)c(F)c(-c5c(F)c(F)c(F)c(F)c5F)c(F)c4F)c3F)c2F)c(F)c(F)c1-c1c(F)c(F)c(F)c(F)c1F] | Appl. Phys. Lett. 79, 156 (2001) |
| Phenothiazine- S-oxide | 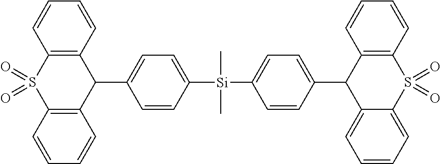 [SMILES: C[Si](C)(c1ccc(C2c3ccccc3S(=O)(=O)c3ccccc32)cc1)c1ccc(C2c3ccccc3S(=O)(=O)c3ccccc32)cc1] | WO2008132085 |
| Silylated five- membered nitrogen, oxygen, sulfur or phosphorus dibenzoheterocycles | 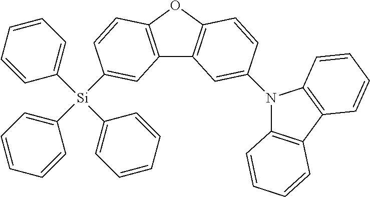 [SMILES: c1ccc([Si](c2ccccc2)(c2ccccc2)c2ccc3oc4ccc(-n5c6ccccc6c6ccccc65)cc4c3c2)cc1] | WO2010079051 |
| Aza-carbazoles | 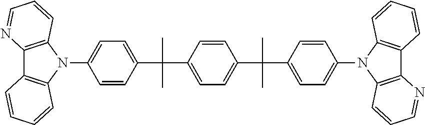 [SMILES: CC(C)(c1ccc(-n2c3ccccc3c3ncccc32)cc1)c1ccc(C(C)(C)c2ccc(-n3c4ccccc4c4ncccc43)cc2)cc1] | US20060121308 |

Electron transporting materials

| | | |
|---|---|---|
| Anthracene- benzoimidazole compounds | 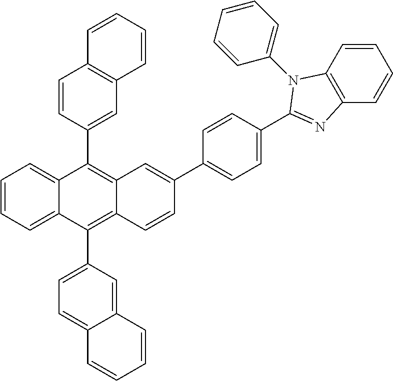 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1] | WO2003060956 |
| | 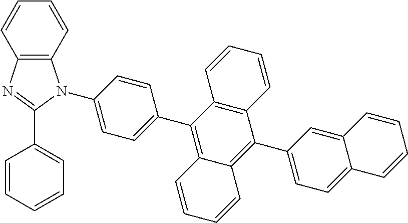 [SMILES: c1ccc(-c2nc3ccccc3n2-c2ccc(-c3c4ccccc4c(-c4ccc5ccccc5c4)c4ccccc34)cc2)cc1] | US20090179554 |
| Aza triphenylene derivatives | 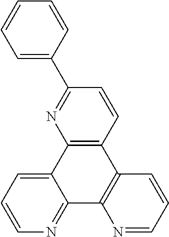 [SMILES: c1ccc(-c2ccc3c4cccnc4c4ncccc4c3n2)cc1] | US20090115316 |
| Anthracene- benzothiazole compounds | 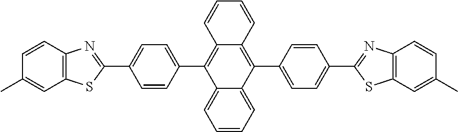 | Appl. Phys. Lett. 89, 063504 (2006) |
| Metal 8-hydroxyquinolates (e.g., Alq₃, Zrq₄) | 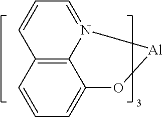 | Appl. Phys. Lett. 51, 913 (1987) US7230107 |
| Metal hydroxybenoquinolates | 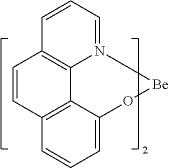 | Chem. Lett. 5, 905 (1993) |
| Bathocuprine compounds such as BCP, BPhen, etc | 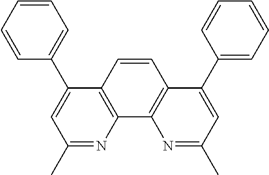 [SMILES: Cc1cc(-c2ccccc2)c2ccc3c(-c4ccccc4)cc(C)nc3c2n1] | Appl. Phys. Lett. 91, 263503 (2007) |
| | 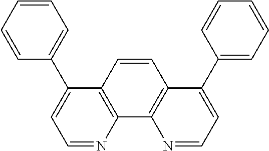 [SMILES: c1ccc(-c2ccnc3c2ccc2c(-c4ccccc4)ccnc23)cc1] | Appl. Phys. Lett. 79, 449 (2001) |
| 5-member ring electron deficient heterocycles (e.g., triazole, oxadiazole, imidazole, benzoimidazole) | 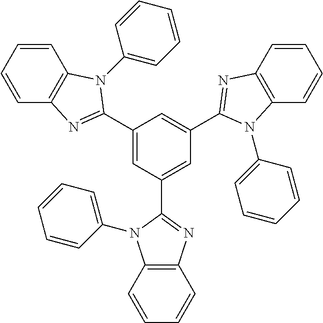 [SMILES: c1ccc(-n2c(-c3cc(-c4nc5ccccc5n4-c4ccccc4)cc(-c4nc5ccccc5n4-c4ccccc4)c3)nc3ccccc32)cc1] | Appl. Phys. Lett. 74, 865 (1999) |
| | 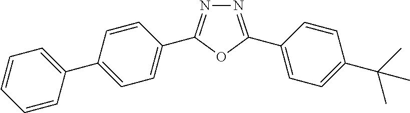 [SMILES: CC(C)(C)c1ccc(-c2nnc(-c3ccc(-c4ccccc4)cc3)o2)cc1] | Appl. Phys. Lett. 55, 1489 (1989) |
| | 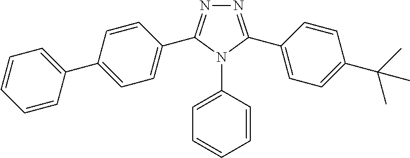 [SMILES: CC(C)(C)c1ccc(-c2nnc(-c3ccc(-c4ccccc4)cc3)n2-c2ccccc2)cc1] | Jpn. J. Apply. Phys. 32, L917 (1993) |
| Silole compounds | 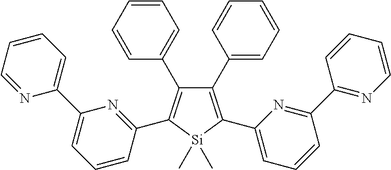 [SMILES: C[Si]1(C)C(c2cccc(-c3ccccn3)n2)=C(c2ccccc2)C(c2ccccc2)=C1c1cccc(-c2ccccn2)n1] | Org. Electron. 4, 113 (2003) |
| Arylborane compounds | 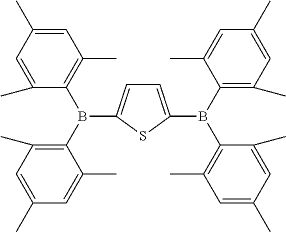 | J. Am. Chem. Soc. 120, 9714 (1998) |
| Fluorinated aromatic compounds | 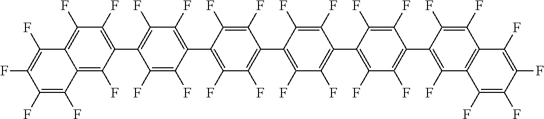 [SMILES: Fc1c(F)c(-c2c(F)c(F)c(-c3c(F)c(F)c4c(F)c(F)c(F)c(F)c4c3F)c(F)c2F)c(F)c(F)c1-c1c(F)c(F)c(-c2c(F)c(F)c(-c3c(F)c(F)c4c(F)c(F)c(F)c(F)c4c3F)c(F)c2F)c(F)c1F] | J. Am. Chem. Soc. 122, 1832 (2000) |
| Fullerene (e.g., C60) | 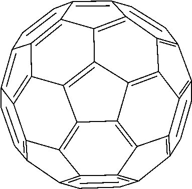 [SMILES: c1cc2c3ccc4c5ccc6c7ccc8c9ccc%10c1c1c2c2c3c4c3c5c6c4c7c8c5c9c%10c1c1c2c3c4c51] | US20090101870 |
| Triazine complexes | 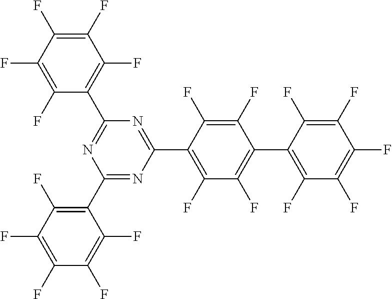 [SMILES: Fc1c(F)c(F)c(-c2nc(-c3c(F)c(F)c(F)c(F)c3F)nc(-c3c(F)c(F)c(-c4c(F)c(F)c(F)c(F)c4F)c(F)c3F)n2)c(F)c1F] | US20040036077 |
| Zn (N\hat{ }N) complexes | 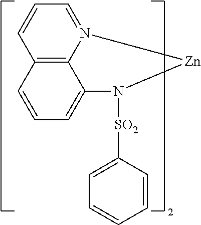 | U56528187 |

### EXPERIMENTAL

### Synthesis of Compound 10

Compound 10 was synthesized as follows:

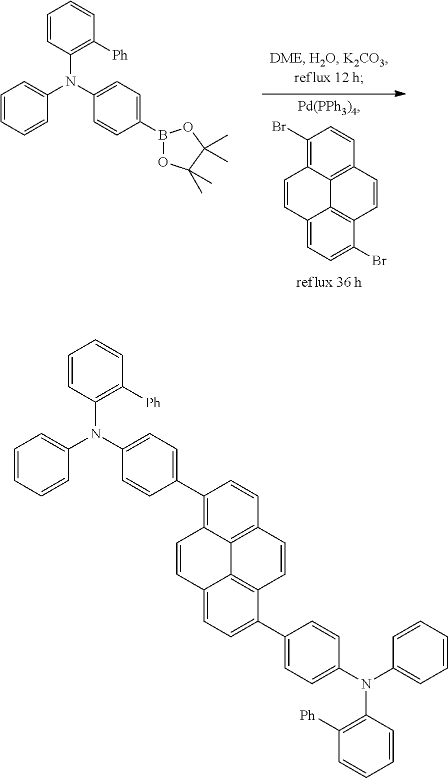 [SMILES: CC1(C)OB(c2ccc(N(c3ccccc3)c3ccccc3-c3ccccc3)cc2)OC1(C)C ; Brc1ccc2ccc3c(Br)ccc4ccc1c2c43 ; c1ccc(-c2ccccc2N(c2ccccc2)c2ccc(-c3ccc4ccc5c(-c6ccc(N(c7ccccc7)c7ccccc7-c7ccccc7)cc6)ccc6ccc3c4c65)cc2)cc1]

A solution of N-phenyl-N-(4-(4,4,5,5-tetramethyl-1,3,2-dioxaborolan-2-yl)phenyl)-[1,1′-biphenyl]-2-amine (4.5 g, 10.0 mmol) and K₂CO₃ (1.4 g, 10.0 mmol) in DME (30 mL) and water (30 mL) was bubbled with nitrogen for 30 min. The mixture was refluxed for 12 h. After cooling, Pd(PPh₃)₄ (0.35 g, 0.30 mmol) and 1,6-dibromopyrene (0.9 g, 2.5 mmol) were added. The mixture was bubbled with nitrogen for 15 min. The mixture was refluxed for 36 h. After cooling, the reaction mixture was diluted by hexane. The precipitate was filtered and washed by excess hexane and water. The dried precipitate was purified by flash chromatography using DCM (containing 0.5% triethylamine) to afford Compound 10 (1.7 g, 81% yield) as a yellow solid.

### Synthesis of Compound 13

Compound 13 was synthesized as follows:

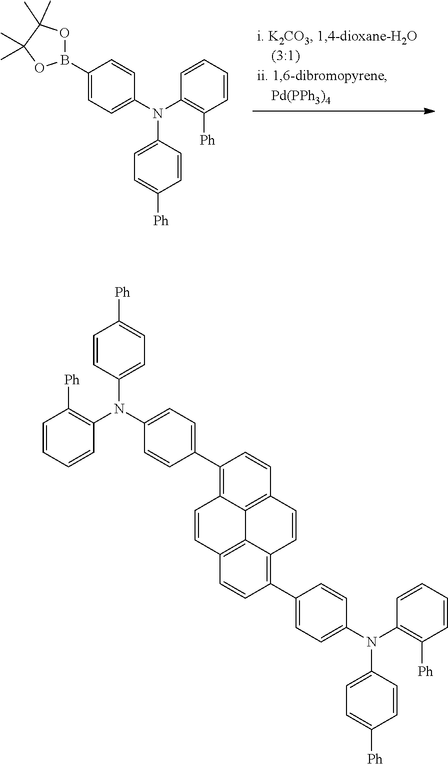 [SMILES: CC1(C)OB(c2ccc(N(c3ccc(-c4ccccc4)cc3)c3ccccc3-c3ccccc3)cc2)OC1(C)C ; c1ccc(-c2ccc(N(c3ccc(-c4ccc5ccc6c(-c7ccc(N(c8ccc(-c9ccccc9)cc8)c8ccccc8-c8ccccc8)cc7)ccc7ccc4c5c76)cc3)c3ccccc3-c3ccccc3)cc2)cc1]

To a solution of N-([1,1′-biphenyl]-4-yl)-N-(4-(4,4,5,5-tetramethyl-1,3,2-dioxaborolan-2-yl)phenyl)-[1,1′-biphenyl]-2-amine (4.35 g, 8.31 mmol), K₂CO₃ (3.63 g, 26.27 mmol) in 1,4-dioxane (60 mL) and water (20 mL) was heated to reflux for 12 h. After cooling to room temperature, Pd(PPh₃)₄ (0.11 g, 0.09 mmol) and 1,6-dibromopyrene (0.79 g, 2.19 mmol) were added. The mixture was bubbled with nitrogen for 15 min. The resultant mixture was heated to reflux for 13 h. The precipitate was filtered and sublimed to give about 1 g of the product. The product was recrystallized twice with toluene to give about 0.7 g of the yellow solid, which was sublimed to give Compound 13 (0.53 g, 24%) as a yellow solid.

### Synthesis of Compound 43

Compound 43 was synthesized as follows:

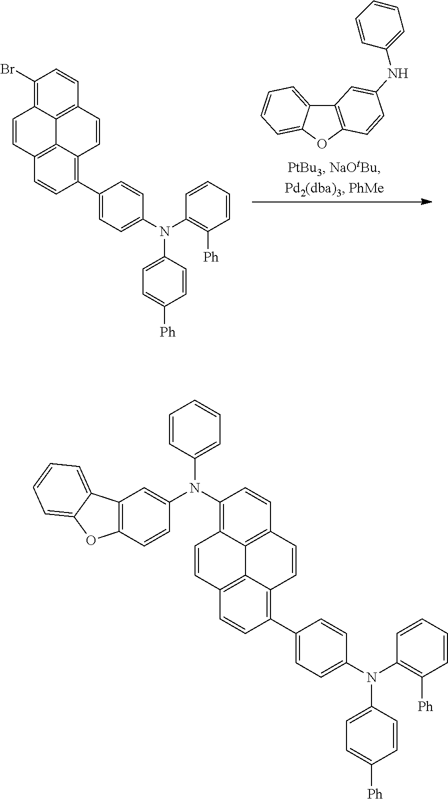 [SMILES: Brc1ccc2ccc3c(-c4ccc(N(c5ccc(-c6ccccc6)cc5)c5ccccc5-c5ccccc5)cc4)ccc4ccc1c2c43 ; c1ccc(Nc2ccc3oc4ccccc4c3c2)cc1 ; c1ccc(-c2ccc(N(c3ccc(-c4ccc5ccc6c(N(c7ccccc7)c7ccc8oc9ccccc9c8c7)ccc7ccc4c5c76)cc3)c3ccccc3-c3ccccc3)cc2)cc1]

To a mixture of N-phenyldibenzo[b,d]furan-2-amine (133 mg, 0.51 mmol), N-([1,1′-biphenyl]-4-yl)-N-(4-(6-bromopyren-1-yl)phenyl)-[1,1′-biphenyl]-2-amine (225 mg, 0.33 mmol), sodium tert-butoxide (173 mg, 1.80 mmol), tri-tert-butylphosphine (10 wt % in hexane) (0.03 mL, 0.12 mmol) in toluene (60 mL) was bubbled with nitrogen for 30 min before Pd₂(dba)₃ (11 mg, 0.01 mmol) was added. The mixture was bubbled with nitrogen for 15 min. The resultant mixture was heated to reflux for 3 h. The reaction mixture was filtered through Celite pad and washed with toluene (containing 0.5% triethylamine). The solvent was removed in vacuo and the residue was purified by flash column chromatography using 10% dichloromethane in hexane (containing 0.5% triethylamine) to give Compound 43 (265 mg, 93% yield) as a yellow solid.

### Synthesis of Compound 29

Compound 29 was synthesized as follows:

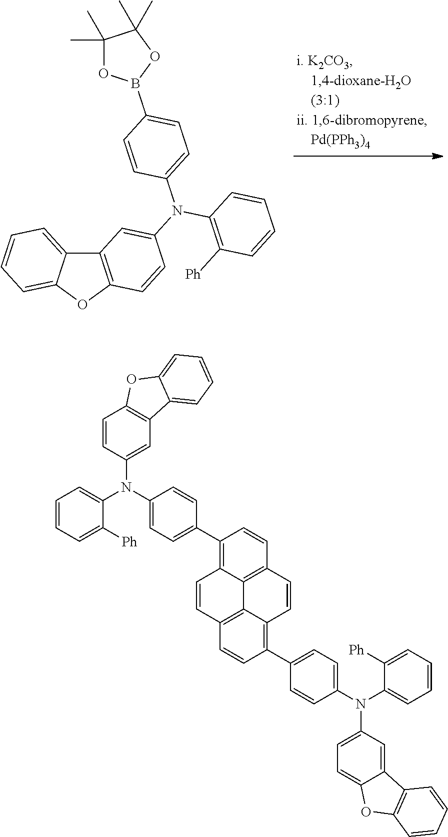 [SMILES: CC1(C)OB(c2ccc(N(c3ccc4oc5ccccc5c4c3)c3ccccc3-c3ccccc3)cc2)OC1(C)C ; c1ccc(-c2ccccc2N(c2ccc(-c3ccc4ccc5c(-c6ccc(N(c7ccc8oc9ccccc9c8c7)c7ccccc7-c7ccccc7)cc6)ccc6ccc3c4c65)cc2)c2ccc3oc4ccccc4c3c2)cc1]

A solution of N-([1,1′-biphenyl]-2-yl)-N-(4-(4,4,5,5-tetramethyl-1,3,2-dioxaborolan-2-yl)phenyl)dibenzo[b,d]furan-2-amine (4.21 g, 7.83 mmol), K₂CO₃ (3.60 g, 26.09 mmol) in 1,4-dioxane (60 mL) and water (20 mL) was refluxed for 12 h. After cooling to room temperature, Pd(PPh₃)₄ (0.12 g, 0.10 mmol) and 1,6-dibromopyrene (0.77 g, 2.14 mmol) were added. The mixture was bubbled with nitrogen for 15 min and heated to reflux for 12 h. The solid was filtered and recrystallized with toluene to give Compound 29 (0.37 g, 54%) as a yellow solid.

### PLQY Evaluations

Photoluminescence and photoluminescence quantum yield (PLQY) experiments were carried out and summarized in Table 2. Poly(methyl methacrylate) (PMMA) doped film (95:5 by weight of PMMA:emitter) were fabricated by solution drop casting on quartz substrates.

TABLE 2

| Compound | PLQY | Emₘₐₓ (nm) |
|---|---|---|
| Cmpd 10 | 90% | 455 |
| Cmpd 13 | 90% | 461 |
| Cmpd 29 | 88% | 456 |
| Cmpd 43 | 94% | 481 |
| Comparative Cmpd 1 | 81% | 456 |
| Comparative Cmpd 2 | 81% | 482 |
| Comparative Cmpd 3 | 87% | 463 |

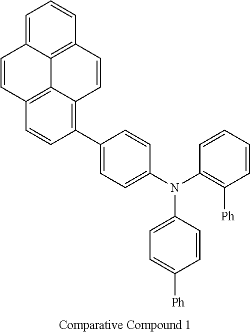 [SMILES: c1ccc(-c2ccc(N(c3ccc(-c4ccc5ccc6cccc7ccc4c5c67)cc3)c3ccccc3-c3ccccc3)cc2)cc1]

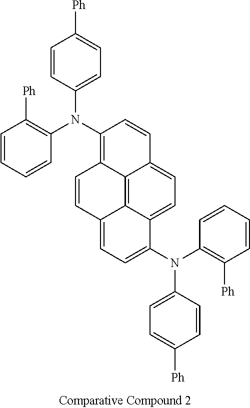 [SMILES: c1ccc(-c2ccc(N(c3ccccc3-c3ccccc3)c3ccc4ccc5c(N(c6ccc(-c7ccccc7)cc6)c6ccccc6-c6ccccc6)ccc6ccc3c4c65)cc2)cc1]

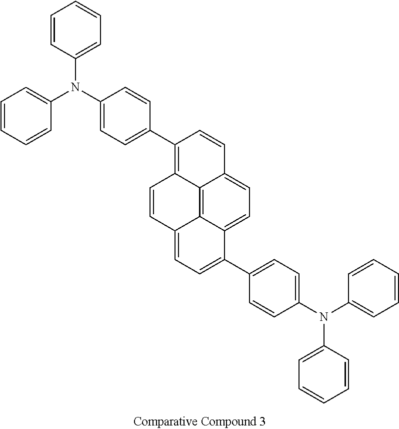 [SMILES: c1ccc(N(c2ccccc2)c2ccc(-c3ccc4ccc5c(-c6ccc(N(c7ccccc7)c7ccccc7)cc6)ccc6ccc3c4c65)cc2)cc1]

As shown by the PLQY data, disubstituted pyenes of Compound 10 and Compound 13 have a significantly higher PLQY than the mono-substituted pyrene of Comparative Compound 1. The unexpected improvement in PLQY is believed to be due to reduced π-stacking when 2 substitutents are present compared to 1. In addition, if the amino N is directly connected to the pyrene ring without any spacer/linker group, the emission is significantly red shifted and the PLQY is lower as demonstrated by comparing Comparative Compound 2 (PLQY=81%, Emₘₐₓ=482 nm) with Compound 13 (PLQY=90%, Emₘₐₓ=461 nm). Furthermore, if there is no ortho aryl group R^{t}, the emission is red shifted and the PLQY is lower as demonstrated by comparing Comparative Compound 3 (PLQY=87%, Emₘₐₓ=463 nm) with Compound 10 (PLQY=90%, Emₘₐₓ=455 nm) and Compound 13 (PLQY=90%, Emₘₐₓ=461 nm). It is expected that the PLQY will further decrease and emission will further redshift for emitters without the ortho aryl group R^{t} when doped in aromatic host matrices due to increased n-stacking between the emitter and the host molecules. It is therefore highly beneficial to a spacer/linker group between the amino N and the pyrene ring and the ortho aryl group R^{t} simultaneously.

As an intrinsic property, a high PLQY value indicates a compound may be particularly useful as an emissive compound in an OLED device. Having a high PLQY is particularly important because maximum efficiencies in OLED devices are generally 5-8% of the PLQY value for fluorescent OLED. Thus, while the device can be optimized to increase quantum efficiency, the maximum quantum efficiency that can be achieved by a given compound is dictated by the intrinsic property of photoluminescent quantum yield. In view of this situation, if the PLQY value of a compound is low to start with, it is unlikely the compound would be useful as an emitter in an OLED device.

### Device Examples

Compounds 10 and 13 were evaluated as possible fluorescent emitters in OLED devices. The organic stack of Device Example 1 consisted of sequentially, from the ITO surface, 100 Å of LG101 (LG Chem, Korea) as the hole injection layer (HIL), 300 Å of α-NPB as the hole transporting layer (HTL), 300 Å of CBP doped with 20% of Compound 10 as the emissive layer (EML), 100 Å of BAlq as the ETL2 and 400 Å of LG-201 (LG Chem, Korea) as the ETL1. The external quantum efficiency was 4.2% at 1000 cd/m² and the CIE was 0.144, 0.201. These results are summarized in Table 3.

Device Example 2 consisted of 100 Å of LG101 (LG Chem, Korea) as the hole injection layer (HIL), 300 Å of α-NPB as the hole transporting layer (HTL), 300 Å of CBP doped with 10% of Compound 13 as the emissive layer (EML), 400 Å of LG-201 (LG Chem, Korea) as the ETL. The external quantum efficiency was 4.8% at 1000 cd/m², and the CIE was 0.141, 0.193. These results are summarized in Table 3.

Device Example 3 consisted of 100 Å of LG101 (LG Chem, Korea) as the hole injection layer (HIL), 300 Å of α-NPB as the hole transporting layer (HTL), 300 Å of Compound A doped with 10% of Compound 13 as the emissive layer (EML), 400 Å of LG-201 (LG Chem, Korea) as the ETL. The external quantum efficiency was 4.8% at 1000 cd/m², and the CIE was 0.141, 0.193. These results are summarized in Table 3.

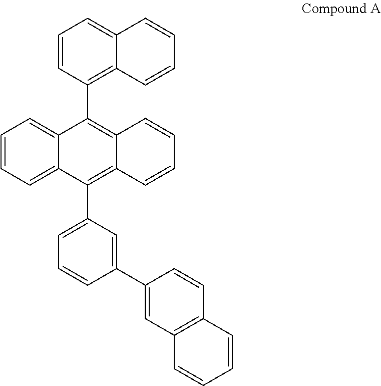 [SMILES: c1cc(-c2ccc3ccccc3c2)cc(-c2c3ccccc3c(-c3cccc4ccccc34)c3ccccc23)c1]

TABLE 3

| | EQE | | |
|---|---|---|---|
| | (at 1000 cd/m2) | CIEx | CIEy |
| Device 1 | 4.2% | 0.144 | 0.201 |
| Device 2 | 4.8% | 0.141 | 0.193 |
| Device 3 | 4.8% | 0.140 | 0.219 |

The device data shows that pyrene compounds, which contain amino group with an ortho aryl arrangement such that the steric bulkiness imposes a heavy twisting of the aryl rings, can be used as emitters in OLEDs to give high efficiency.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

We claim:

1. A compound having Formula 1: 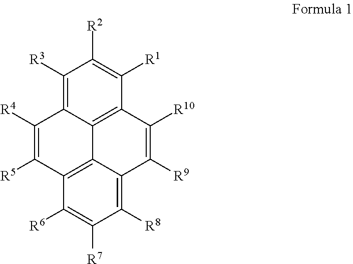
wherein R¹-R¹⁰ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof,
wherein at least two of R¹-R¹⁰ are not H,
wherein at least one of R¹-R¹⁰ has the formula T1 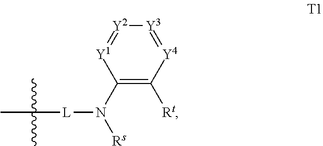
wherein L is an organic linker,
wherein Y¹ to Y⁴ are CR or N,
wherein R is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof,
wherein adjacent R moieties can form fused rings,
wherein R^{s} and R^{t} are independently aryl or heteroaryl, either of which may independently be further substituted, and
wherein R^{s} and R^{t} do not form fused rings with any part of the molecule.

2. The compound of claim 1, wherein linker L is alkyl, aryl or heteroaryl.

3. The compound of claim 1, wherein Rₛ can comprise a moiety selected from the group consisting of dibenzothiophene, dibenzofuran, dibenzoselenophene, aza-dibenzothiophene, aza-dibenzofuran, or aza-dibenzoselenophene, phenyl, pyridine, and combinations thereof.

4. The compound of claim 1, wherein linker L is selected from the group consisting of: 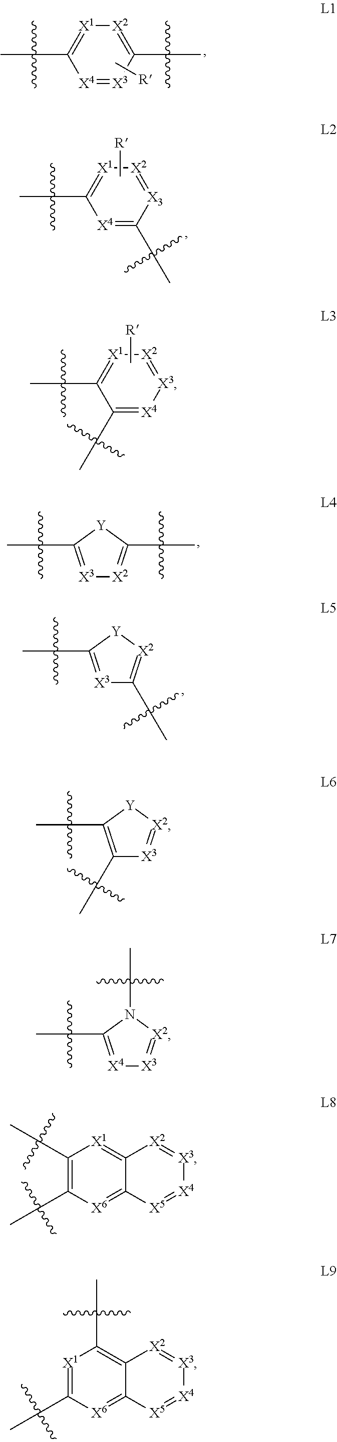 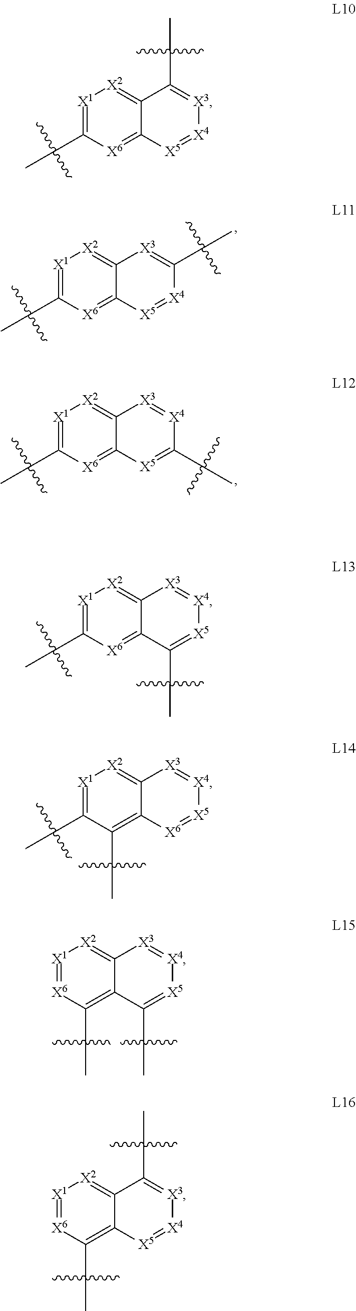 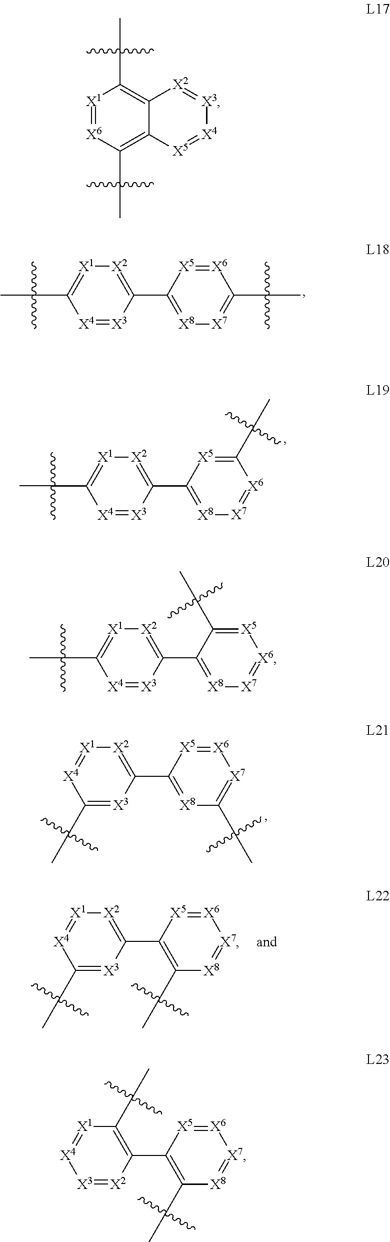
wherein X¹ to X⁸ are CR′ or N,
wherein Y is NR″, O or S, and
wherein R′ and R″ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof.

5. The compound of claim 1, wherein R¹ has the formula

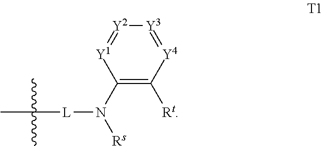

6. The compound of claim 1, wherein R¹ has the formula 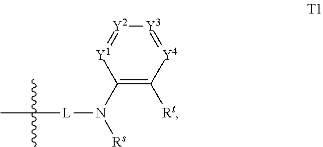
and R⁶ is alkyl, aryl or heteroaryl.

7. The compound of claim 6, wherein the compound is selected from the group

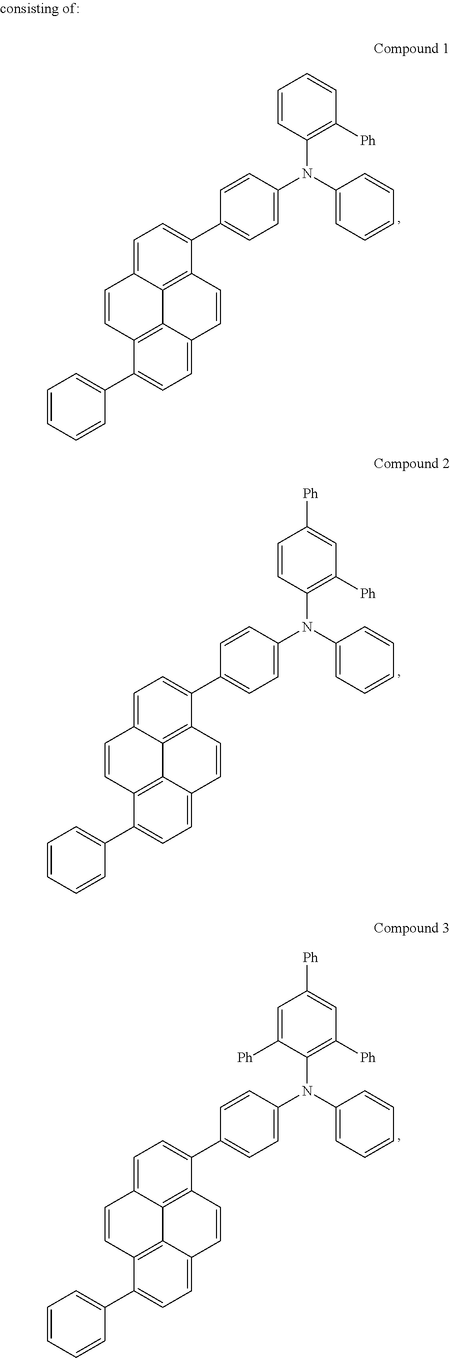 [SMILES: c1ccc(-c2ccccc2N(c2ccccc2)c2ccc(-c3ccc4ccc5c(-c6ccccc6)ccc6ccc3c4c65)cc2)cc1 ; c1ccc(-c2ccc(N(c3ccccc3)c3ccc(-c4ccc5ccc6c(-c7ccccc7)ccc7ccc4c5c76)cc3)c(-c3ccccc3)c2)cc1 ; c1ccc(-c2cc(-c3ccccc3)c(N(c3ccccc3)c3ccc(-c4ccc5ccc6c(-c7ccccc7)ccc7ccc4c5c76)cc3)c(-c3ccccc3)c2)cc1]

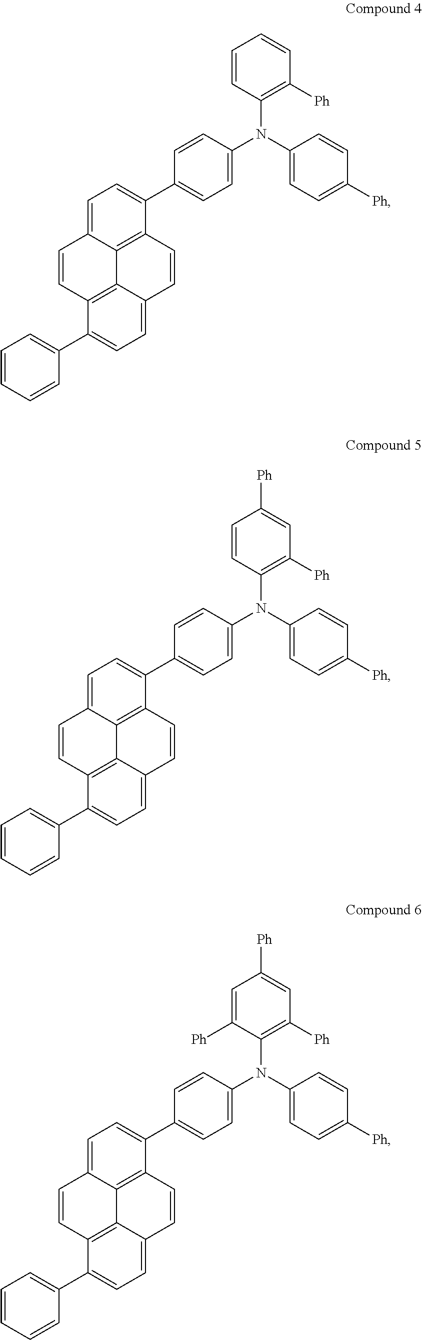 [SMILES: c1ccc(-c2ccc(N(c3ccc(-c4ccc5ccc6c(-c7ccccc7)ccc7ccc4c5c76)cc3)c3ccccc3-c3ccccc3)cc2)cc1 ; c1ccc(-c2ccc(N(c3ccc(-c4ccc5ccc6c(-c7ccccc7)ccc7ccc4c5c76)cc3)c3ccc(-c4ccccc4)cc3-c3ccccc3)cc2)cc1 ; c1ccc(-c2ccc(N(c3ccc(-c4ccc5ccc6c(-c7ccccc7)ccc7ccc4c5c76)cc3)c3c(-c4ccccc4)cc(-c4ccccc4)cc3-c3ccccc3)cc2)cc1]

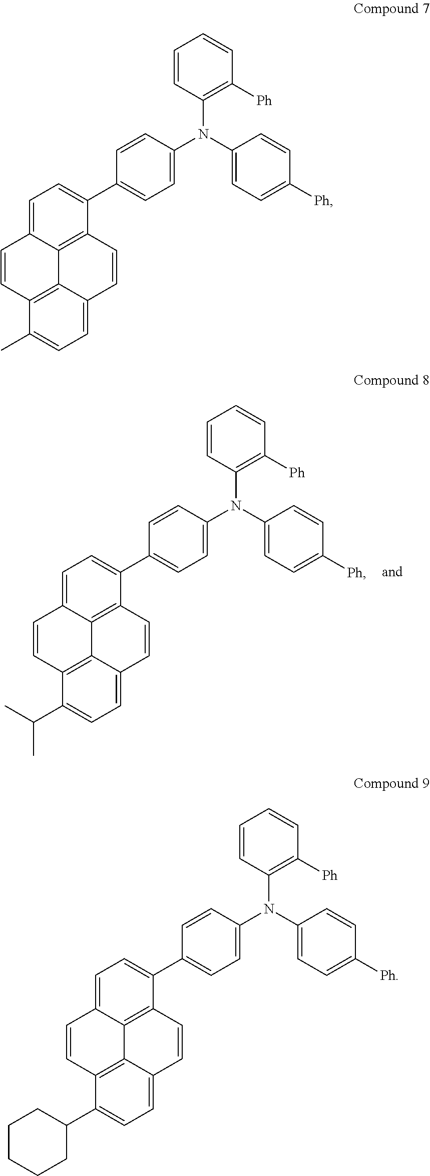 [SMILES: Cc1ccc2ccc3c(-c4ccc(N(c5ccc(-c6ccccc6)cc5)c5ccccc5-c5ccccc5)cc4)ccc4ccc1c2c43 ; CC(C)c1ccc2ccc3c(-c4ccc(N(c5ccc(-c6ccccc6)cc5)c5ccccc5-c5ccccc5)cc4)ccc4ccc1c2c43 ; c1ccc(-c2ccc(N(c3ccc(-c4ccc5ccc6c(C7CCCCC7)ccc7ccc4c5c76)cc3)c3ccccc3-c3ccccc3)cc2)cc1]

8. The compound of claim 1, wherein R¹ and R⁶ each have the formula T1

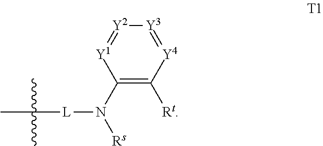

9. The compound of claim 8, wherein the compound is selected from the group

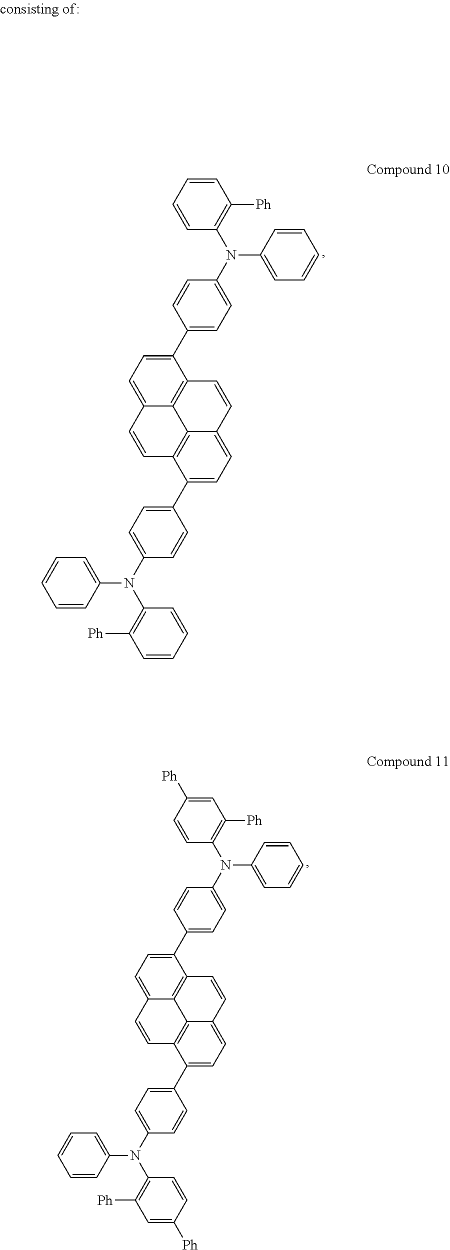 [SMILES: c1ccc(-c2ccccc2N(c2ccccc2)c2ccc(-c3ccc4ccc5c(-c6ccc(N(c7ccccc7)c7ccccc7-c7ccccc7)cc6)ccc6ccc3c4c65)cc2)cc1 ; c1ccc(-c2ccc(N(c3ccccc3)c3ccc(-c4ccc5ccc6c(-c7ccc(N(c8ccccc8)c8ccc(-c9ccccc9)cc8-c8ccccc8)cc7)ccc7ccc4c5c76)cc3)c(-c3ccccc3)c2)cc1]

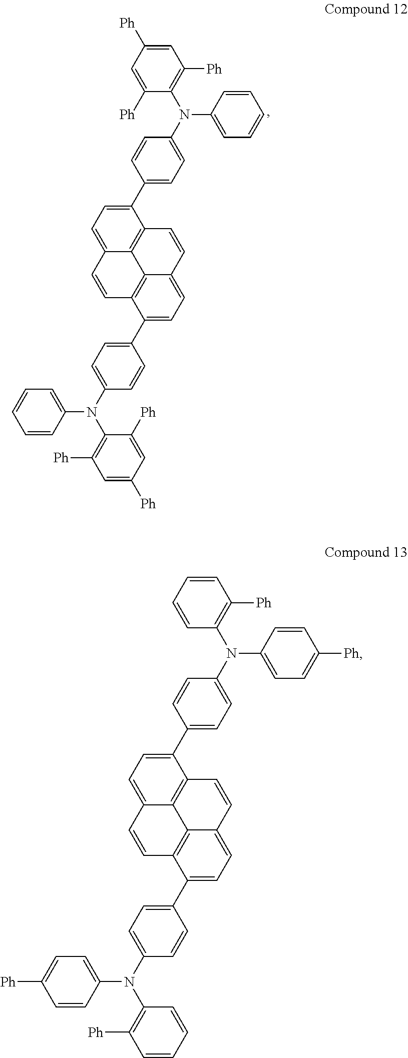 [SMILES: c1ccc(-c2cc(-c3ccccc3)c(N(c3ccccc3)c3ccc(-c4ccc5ccc6c(-c7ccc(N(c8ccccc8)c8c(-c9ccccc9)cc(-c9ccccc9)cc8-c8ccccc8)cc7)ccc7ccc4c5c76)cc3)c(-c3ccccc3)c2)cc1 ; c1ccc(-c2ccc(N(c3ccc(-c4ccc5ccc6c(-c7ccc(N(c8ccc(-c9ccccc9)cc8)c8ccccc8-c8ccccc8)cc7)ccc7ccc4c5c76)cc3)c3ccccc3-c3ccccc3)cc2)cc1]

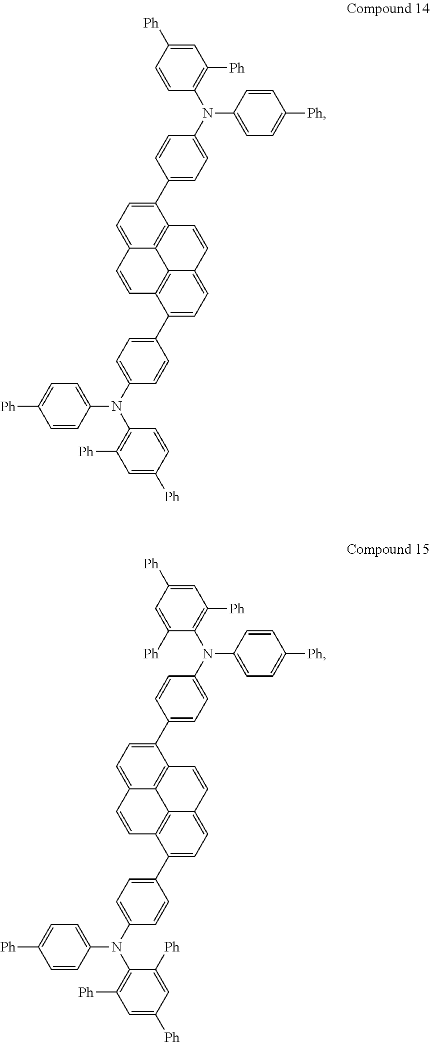 [SMILES: c1ccc(-c2ccc(N(c3ccc(-c4ccc5ccc6c(-c7ccc(N(c8ccc(-c9ccccc9)cc8)c8ccc(-c9ccccc9)cc8-c8ccccc8)cc7)ccc7ccc4c5c76)cc3)c3ccc(-c4ccccc4)cc3-c3ccccc3)cc2)cc1 ; c1ccc(-c2ccc(N(c3ccc(-c4ccc5ccc6c(-c7ccc(N(c8ccc(-c9ccccc9)cc8)c8c(-c9ccccc9)cc(-c9ccccc9)cc8-c8ccccc8)cc7)ccc7ccc4c5c76)cc3)c3c(-c4ccccc4)cc(-c4ccccc4)cc3-c3ccccc3)cc2)cc1]

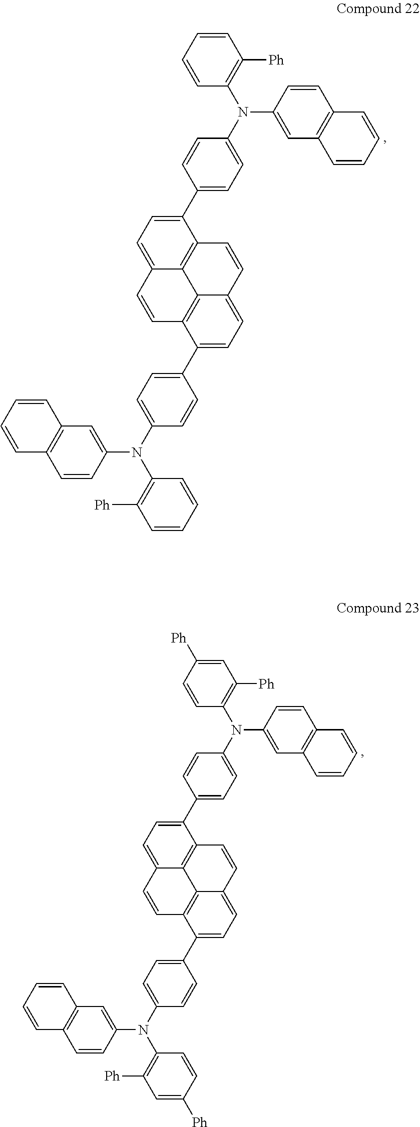 [SMILES: c1ccc(-c2ccccc2N(c2ccc(-c3ccc4ccc5c(-c6ccc(N(c7ccc8ccccc8c7)c7ccccc7-c7ccccc7)cc6)ccc6ccc3c4c65)cc2)c2ccc3ccccc3c2)cc1 ; c1ccc(-c2ccc(N(c3ccc(-c4ccc5ccc6c(-c7ccc(N(c8ccc9ccccc9c8)c8ccc(-c9ccccc9)cc8-c8ccccc8)cc7)ccc7ccc4c5c76)cc3)c3ccc4ccccc4c3)c(-c3ccccc3)c2)cc1]

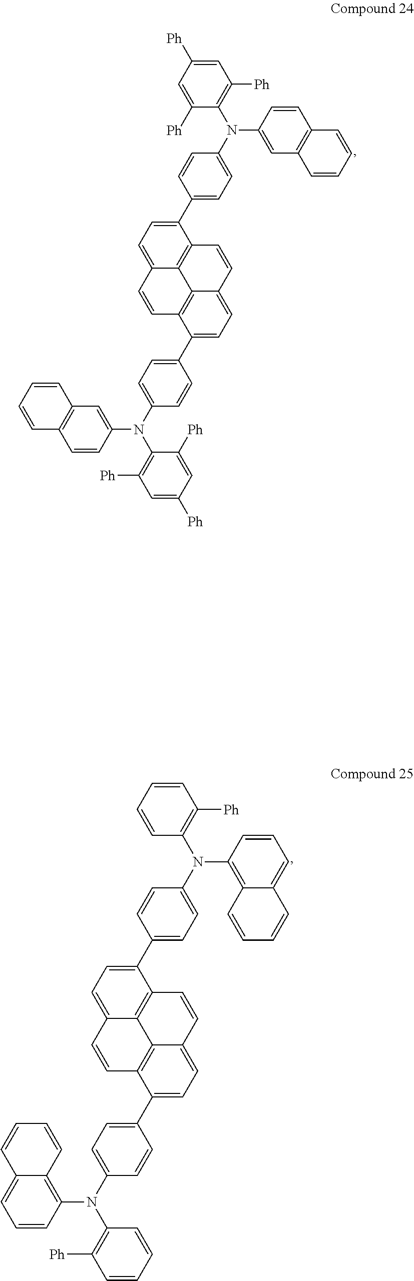 [SMILES: c1ccc(-c2cc(-c3ccccc3)c(N(c3ccc(-c4ccc5ccc6c(-c7ccc(N(c8ccc9ccccc9c8)c8c(-c9ccccc9)cc(-c9ccccc9)cc8-c8ccccc8)cc7)ccc7ccc4c5c76)cc3)c3ccc4ccccc4c3)c(-c3ccccc3)c2)cc1 ; c1ccc(-c2ccccc2N(c2ccc(-c3ccc4ccc5c(-c6ccc(N(c7ccccc7-c7ccccc7)c7cccc8ccccc78)cc6)ccc6ccc3c4c65)cc2)c2cccc3ccccc23)cc1]

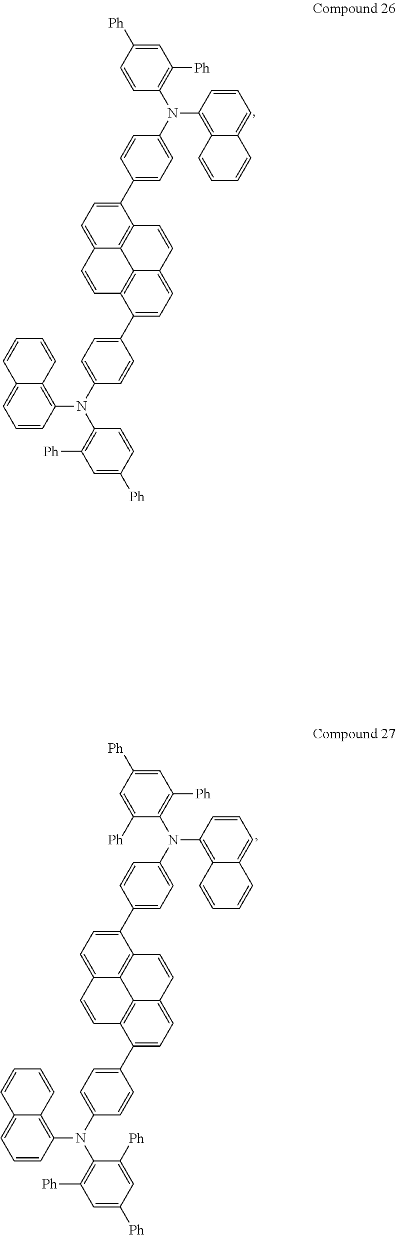 [SMILES: c1ccc(-c2ccc(N(c3ccc(-c4ccc5ccc6c(-c7ccc(N(c8ccc(-c9ccccc9)cc8-c8ccccc8)c8cccc9ccccc89)cc7)ccc7ccc4c5c76)cc3)c3cccc4ccccc34)c(-c3ccccc3)c2)cc1 ; c1ccc(-c2cc(-c3ccccc3)c(N(c3ccc(-c4ccc5ccc6c(-c7ccc(N(c8c(-c9ccccc9)cc(-c9ccccc9)cc8-c8ccccc8)c8cccc9ccccc89)cc7)ccc7ccc4c5c76)cc3)c3cccc4ccccc34)c(-c3ccccc3)c2)cc1]

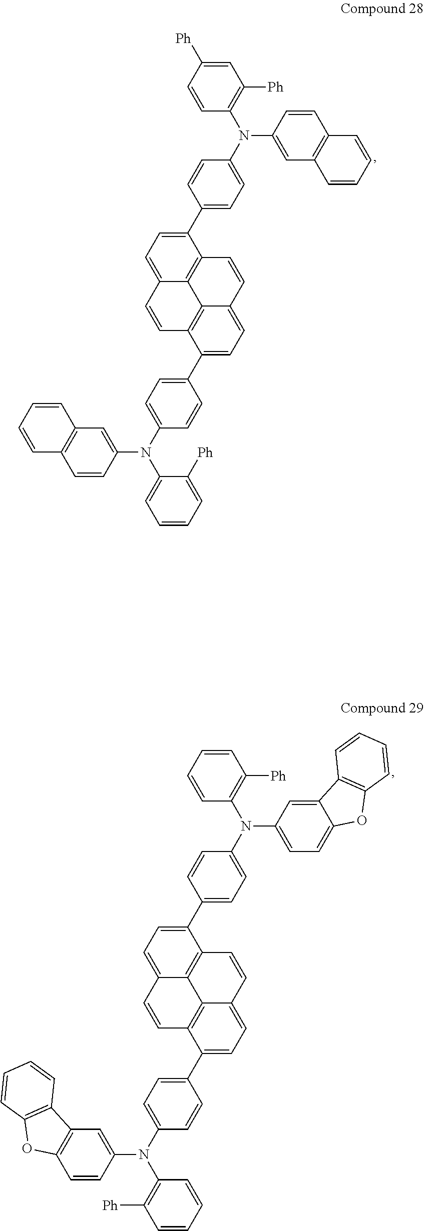 [SMILES: c1ccc(-c2ccc(N(c3ccc(-c4ccc5ccc6c(-c7ccc(N(c8ccc9ccccc9c8)c8ccccc8-c8ccccc8)cc7)ccc7ccc4c5c76)cc3)c3ccc4ccccc4c3)c(-c3ccccc3)c2)cc1 ; c1ccc(-c2ccccc2N(c2ccc(-c3ccc4ccc5c(-c6ccc(N(c7ccc8oc9ccccc9c8c7)c7ccccc7-c7ccccc7)cc6)ccc6ccc3c4c65)cc2)c2ccc3oc4ccccc4c3c2)cc1]

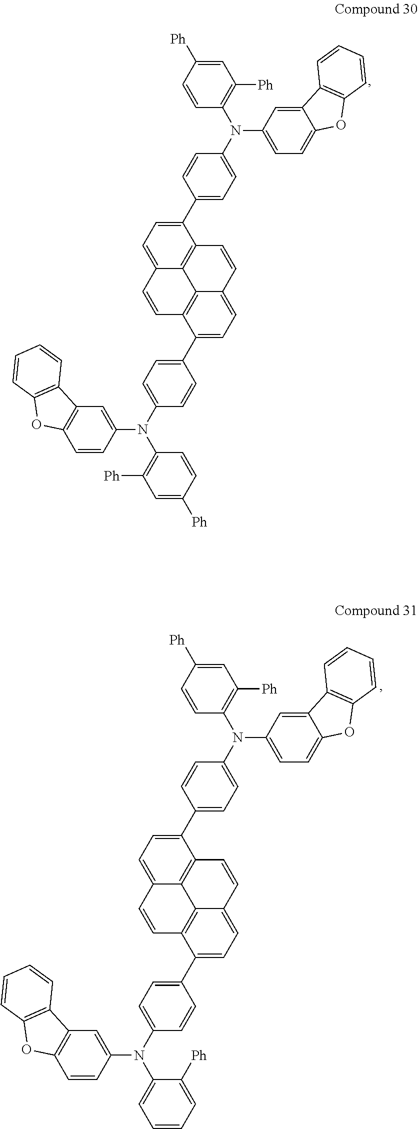 [SMILES: c1ccc(-c2ccc(N(c3ccc(-c4ccc5ccc6c(-c7ccc(N(c8ccc9oc%10ccccc%10c9c8)c8ccc(-c9ccccc9)cc8-c8ccccc8)cc7)ccc7ccc4c5c76)cc3)c3ccc4oc5ccccc5c4c3)c(-c3ccccc3)c2)cc1 ; c1ccc(-c2ccc(N(c3ccc(-c4ccc5ccc6c(-c7ccc(N(c8ccc9oc%10ccccc%10c9c8)c8ccccc8-c8ccccc8)cc7)ccc7ccc4c5c76)cc3)c3ccc4oc5ccccc5c4c3)c(-c3ccccc3)c2)cc1]

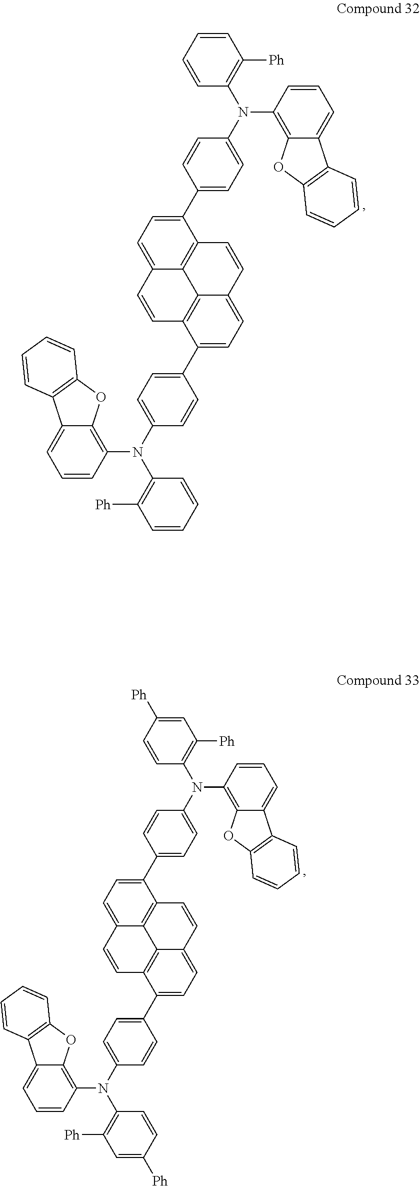 [SMILES: c1ccc(-c2ccccc2N(c2ccc(-c3ccc4ccc5c(-c6ccc(N(c7ccccc7-c7ccccc7)c7cccc8c7oc7ccccc78)cc6)ccc6ccc3c4c65)cc2)c2cccc3c2oc2ccccc23)cc1 ; c1ccc(-c2ccc(N(c3ccc(-c4ccc5ccc6c(-c7ccc(N(c8ccc(-c9ccccc9)cc8-c8ccccc8)c8cccc9c8oc8ccccc89)cc7)ccc7ccc4c5c76)cc3)c3cccc4c3oc3ccccc34)c(-c3ccccc3)c2)cc1]

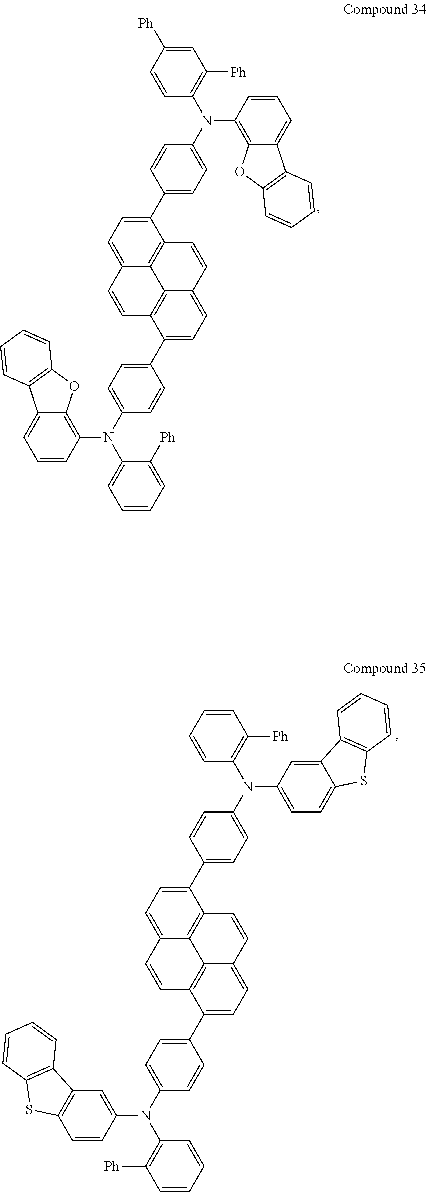 [SMILES: c1ccc(-c2ccc(N(c3ccc(-c4ccc5ccc6c(-c7ccc(N(c8ccccc8-c8ccccc8)c8cccc9c8oc8ccccc89)cc7)ccc7ccc4c5c76)cc3)c3cccc4c3oc3ccccc34)c(-c3ccccc3)c2)cc1 ; c1ccc(-c2ccccc2N(c2ccc(-c3ccc4ccc5c(-c6ccc(N(c7ccc8sc9ccccc9c8c7)c7ccccc7-c7ccccc7)cc6)ccc6ccc3c4c65)cc2)c2ccc3sc4ccccc4c3c2)cc1]

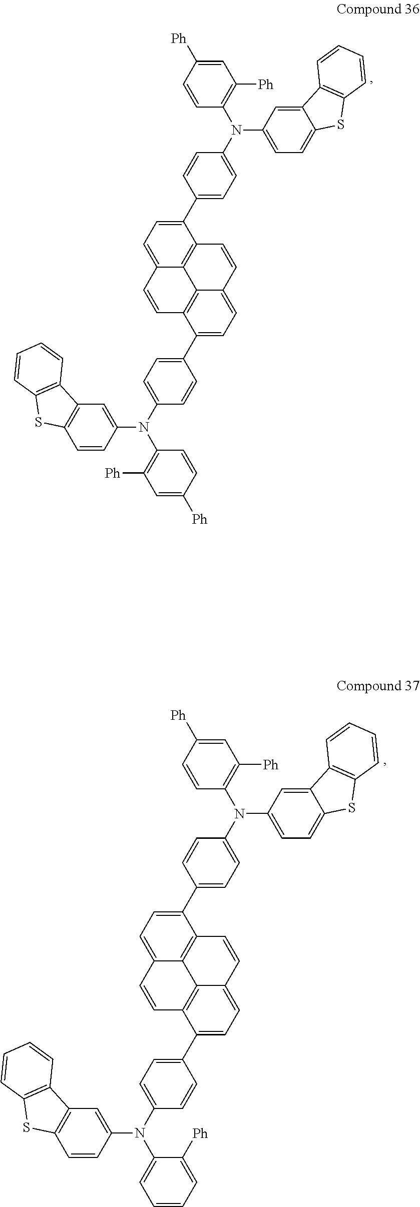 [SMILES: c1ccc(-c2ccc(N(c3ccc(-c4ccc5ccc6c(-c7ccc(N(c8ccc9sc%10ccccc%10c9c8)c8ccc(-c9ccccc9)cc8-c8ccccc8)cc7)ccc7ccc4c5c76)cc3)c3ccc4sc5ccccc5c4c3)c(-c3ccccc3)c2)cc1 ; c1ccc(-c2ccc(N(c3ccc(-c4ccc5ccc6c(-c7ccc(N(c8ccc9sc%10ccccc%10c9c8)c8ccccc8-c8ccccc8)cc7)ccc7ccc4c5c76)cc3)c3ccc4sc5ccccc5c4c3)c(-c3ccccc3)c2)cc1]

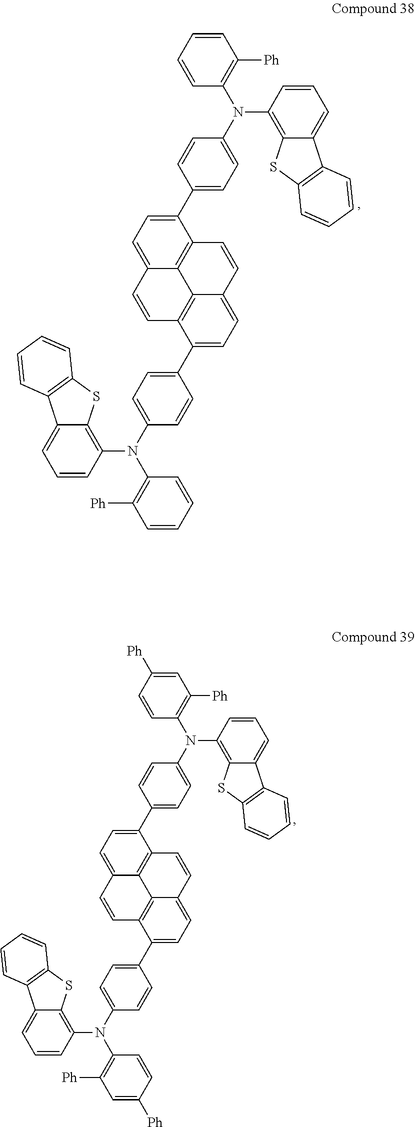 [SMILES: c1ccc(-c2ccccc2N(c2ccc(-c3ccc4ccc5c(-c6ccc(N(c7ccccc7-c7ccccc7)c7cccc8c7sc7ccccc78)cc6)ccc6ccc3c4c65)cc2)c2cccc3c2sc2ccccc23)cc1 ; c1ccc(-c2ccc(N(c3ccc(-c4ccc5ccc6c(-c7ccc(N(c8ccc(-c9ccccc9)cc8-c8ccccc8)c8cccc9c8sc8ccccc89)cc7)ccc7ccc4c5c76)cc3)c3cccc4c3sc3ccccc34)c(-c3ccccc3)c2)cc1]

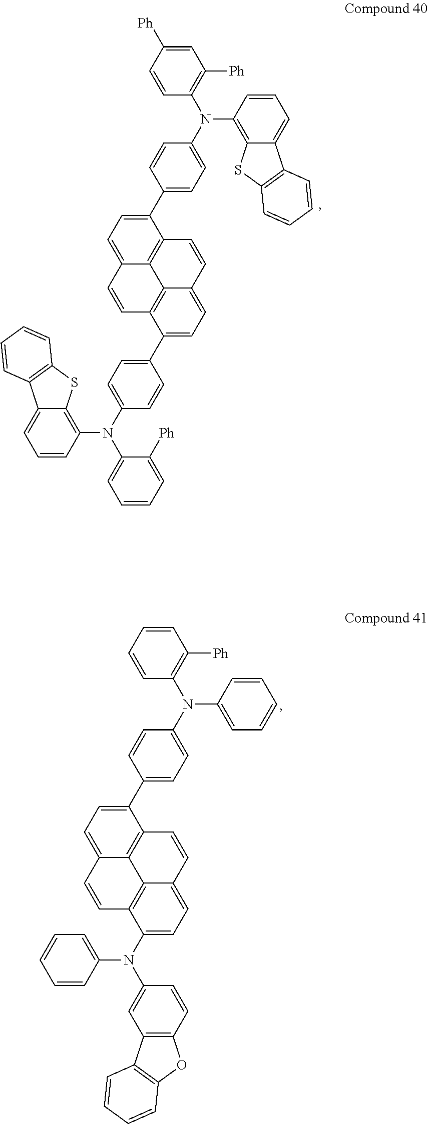 [SMILES: c1ccc(-c2ccc(N(c3ccc(-c4ccc5ccc6c(-c7ccc(N(c8ccccc8-c8ccccc8)c8cccc9c8sc8ccccc89)cc7)ccc7ccc4c5c76)cc3)c3cccc4c3sc3ccccc34)c(-c3ccccc3)c2)cc1 ; c1ccc(-c2ccccc2N(c2ccccc2)c2ccc(-c3ccc4ccc5c(N(c6ccccc6)c6ccc7oc8ccccc8c7c6)ccc6ccc3c4c65)cc2)cc1]

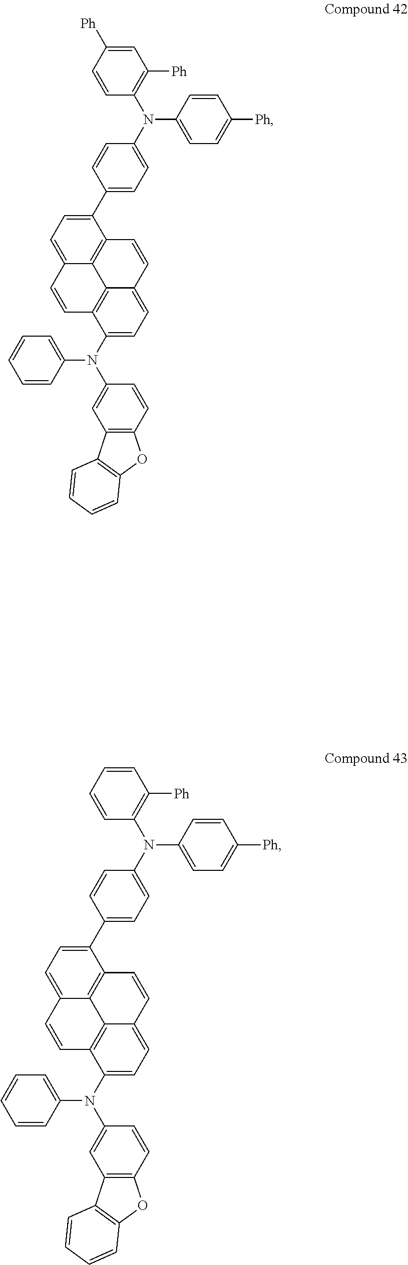 [SMILES: c1ccc(-c2ccc(N(c3ccc(-c4ccc5ccc6c(N(c7ccccc7)c7ccc8oc9ccccc9c8c7)ccc7ccc4c5c76)cc3)c3ccc(-c4ccccc4)cc3-c3ccccc3)cc2)cc1 ; c1ccc(-c2ccc(N(c3ccc(-c4ccc5ccc6c(N(c7ccccc7)c7ccc8oc9ccccc9c8c7)ccc7ccc4c5c76)cc3)c3ccccc3-c3ccccc3)cc2)cc1]

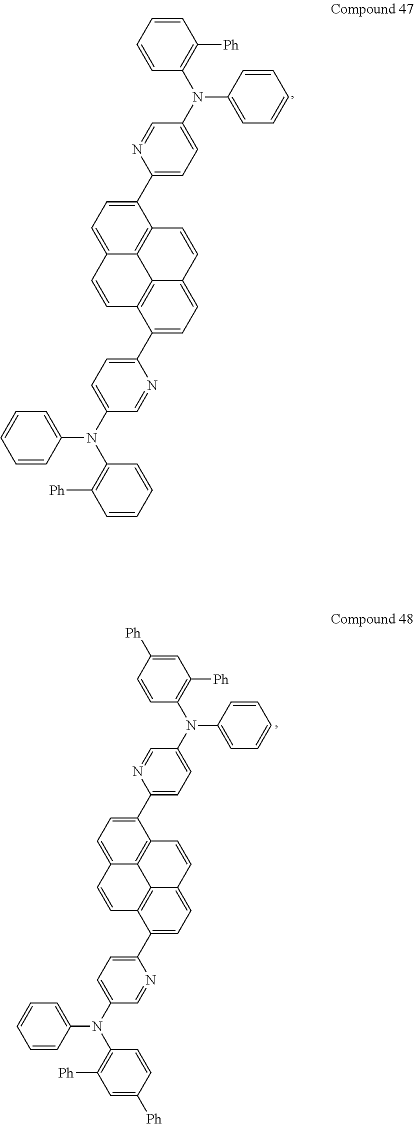 [SMILES: c1ccc(-c2ccccc2N(c2ccccc2)c2ccc(-c3ccc4ccc5c(-c6ccc(N(c7ccccc7)c7ccccc7-c7ccccc7)cn6)ccc6ccc3c4c65)nc2)cc1 ; c1ccc(-c2ccc(N(c3ccccc3)c3ccc(-c4ccc5ccc6c(-c7ccc(N(c8ccccc8)c8ccc(-c9ccccc9)cc8-c8ccccc8)cn7)ccc7ccc4c5c76)nc3)c(-c3ccccc3)c2)cc1]

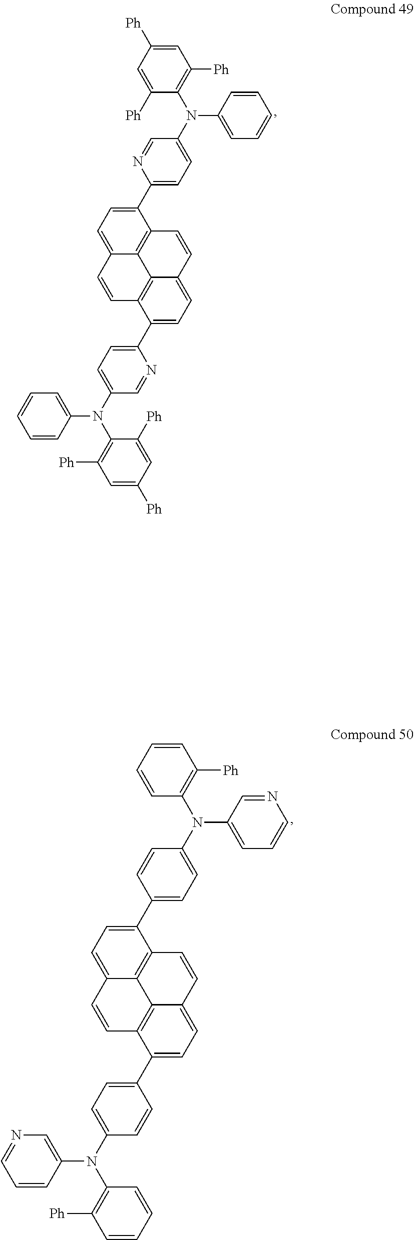 [SMILES: c1ccc(-c2cc(-c3ccccc3)c(N(c3ccccc3)c3ccc(-c4ccc5ccc6c(-c7ccc(N(c8ccccc8)c8c(-c9ccccc9)cc(-c9ccccc9)cc8-c8ccccc8)cn7)ccc7ccc4c5c76)nc3)c(-c3ccccc3)c2)cc1 ; c1ccc(-c2ccccc2N(c2ccc(-c3ccc4ccc5c(-c6ccc(N(c7cccnc7)c7ccccc7-c7ccccc7)cc6)ccc6ccc3c4c65)cc2)c2cccnc2)cc1]

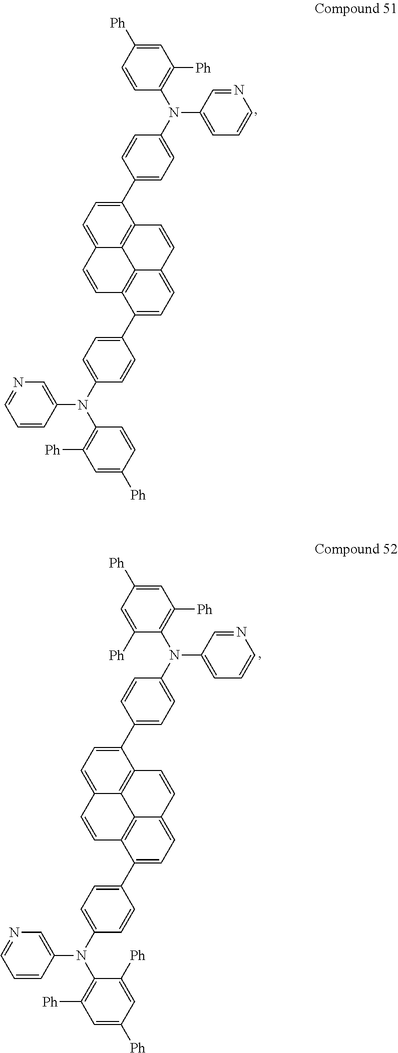 [SMILES: c1ccc(-c2ccc(N(c3ccc(-c4ccc5ccc6c(-c7ccc(N(c8cccnc8)c8ccc(-c9ccccc9)cc8-c8ccccc8)cc7)ccc7ccc4c5c76)cc3)c3cccnc3)c(-c3ccccc3)c2)cc1 ; c1ccc(-c2cc(-c3ccccc3)c(N(c3ccc(-c4ccc5ccc6c(-c7ccc(N(c8cccnc8)c8c(-c9ccccc9)cc(-c9ccccc9)cc8-c8ccccc8)cc7)ccc7ccc4c5c76)cc3)c3cccnc3)c(-c3ccccc3)c2)cc1]

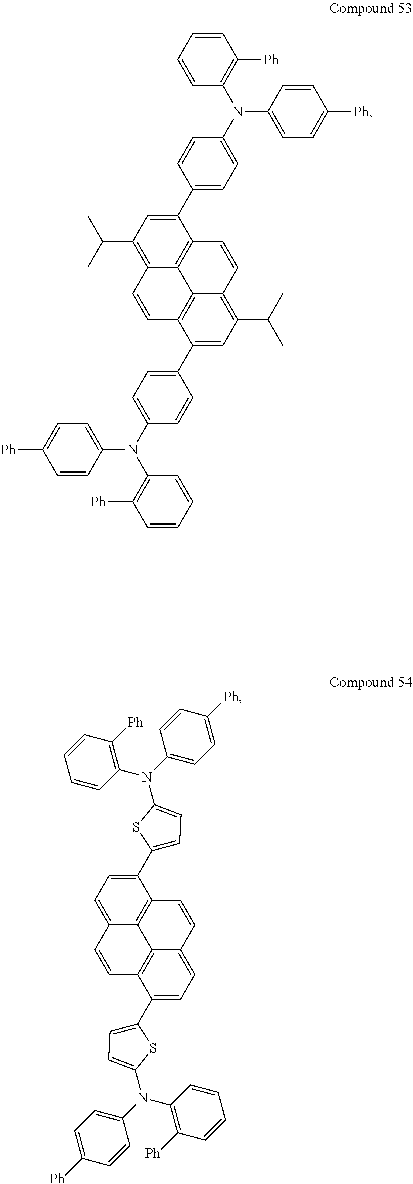 [SMILES: CC(C)c1cc(-c2ccc(N(c3ccc(-c4ccccc4)cc3)c3ccccc3-c3ccccc3)cc2)c2ccc3c(C(C)C)cc(-c4ccc(N(c5ccc(-c6ccccc6)cc5)c5ccccc5-c5ccccc5)cc4)c4ccc1c2c43 ; c1ccc(-c2ccc(N(c3ccc(-c4ccc5ccc6c(-c7ccc(N(c8ccc(-c9ccccc9)cc8)c8ccccc8-c8ccccc8)s7)ccc7ccc4c5c76)s3)c3ccccc3-c3ccccc3)cc2)cc1]

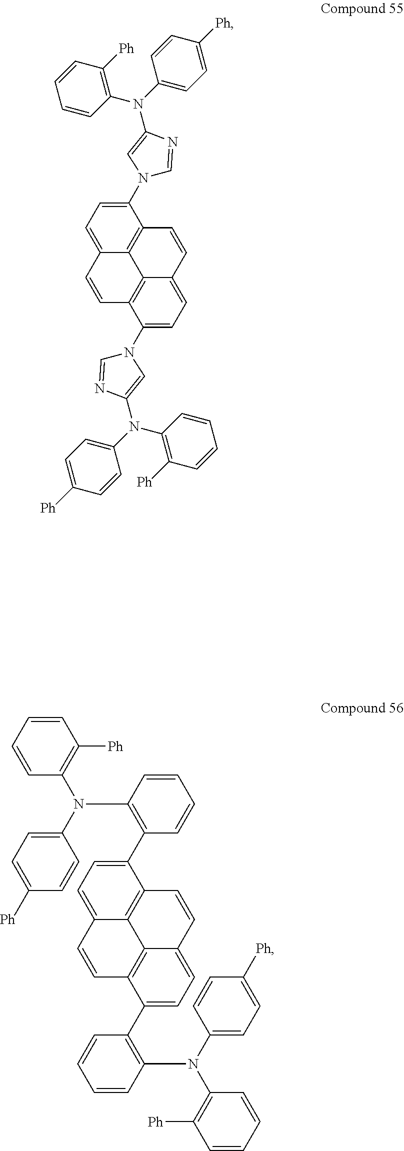 [SMILES: c1ccc(-c2ccc(N(c3cn(-c4ccc5ccc6c(-n7cnc(N(c8ccc(-c9ccccc9)cc8)c8ccccc8-c8ccccc8)c7)ccc7ccc4c5c76)cn3)c3ccccc3-c3ccccc3)cc2)cc1 ; c1ccc(-c2ccc(N(c3ccccc3-c3ccccc3)c3ccccc3-c3ccc4ccc5c(-c6ccccc6N(c6ccc(-c7ccccc7)cc6)c6ccccc6-c6ccccc6)ccc6ccc3c4c65)cc2)cc1]

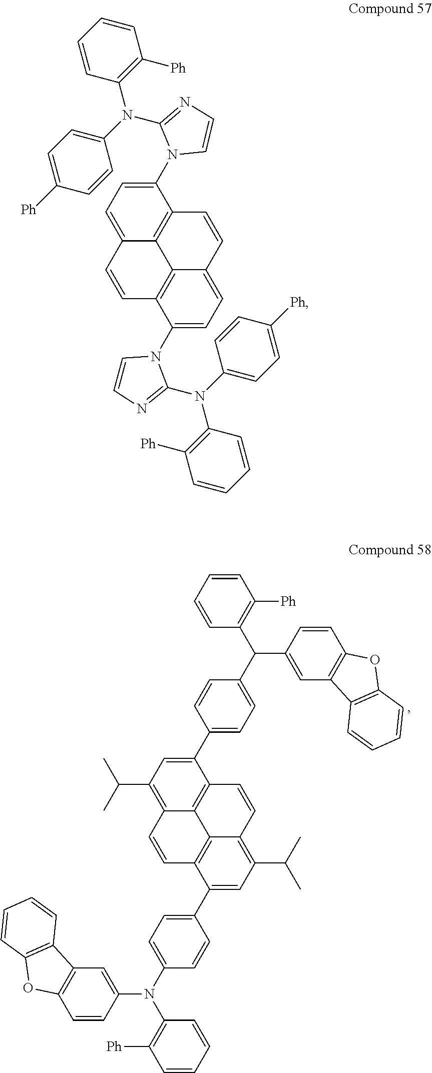 [SMILES: c1ccc(-c2ccc(N(c3ccccc3-c3ccccc3)c3nccn3-c3ccc4ccc5c(-n6ccnc6N(c6ccc(-c7ccccc7)cc6)c6ccccc6-c6ccccc6)ccc6ccc3c4c65)cc2)cc1 ; CC(C)c1cc(-c2ccc(C(c3ccc4oc5ccccc5c4c3)c3ccccc3-c3ccccc3)cc2)c2ccc3c(C(C)C)cc(-c4ccc(N(c5ccc6oc7ccccc7c6c5)c5ccccc5-c5ccccc5)cc4)c4ccc1c2c43]

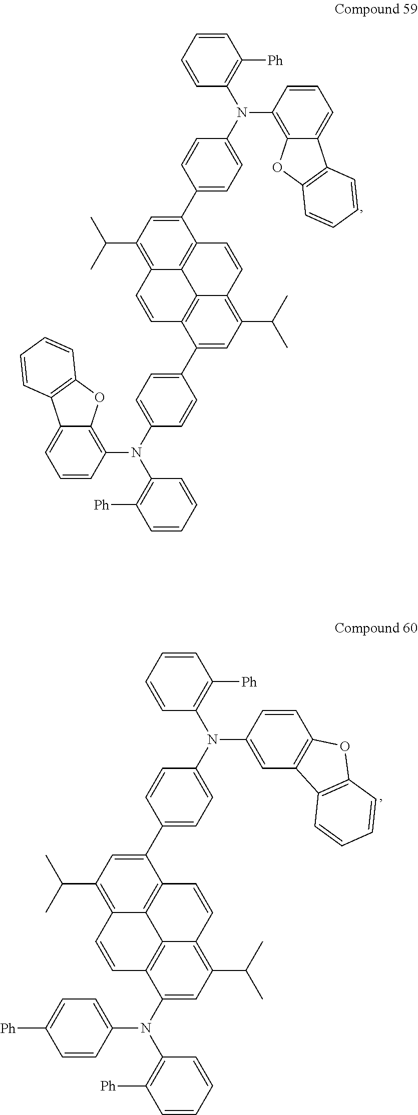 [SMILES: CC(C)c1cc(-c2ccc(N(c3ccccc3-c3ccccc3)c3cccc4c3oc3ccccc34)cc2)c2ccc3c(C(C)C)cc(-c4ccc(N(c5ccccc5-c5ccccc5)c5cccc6c5oc5ccccc56)cc4)c4ccc1c2c43 ; CC(C)c1cc(-c2ccc(N(c3ccc4oc5ccccc5c4c3)c3ccccc3-c3ccccc3)cc2)c2ccc3c(C(C)C)cc(N(c4ccc(-c5ccccc5)cc4)c4ccccc4-c4ccccc4)c4ccc1c2c34]

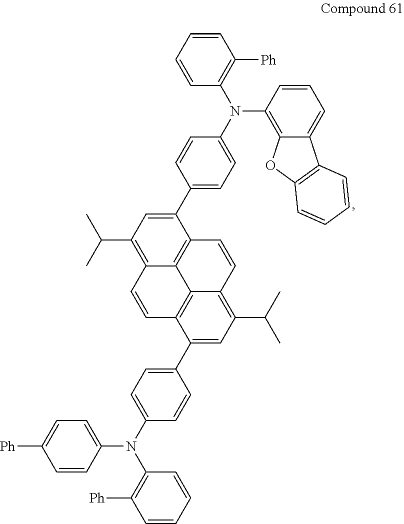 [SMILES: CC(C)c1cc(-c2ccc(N(c3ccc(-c4ccccc4)cc3)c3ccccc3-c3ccccc3)cc2)c2ccc3c(C(C)C)cc(-c4ccc(N(c5ccccc5-c5ccccc5)c5cccc6c5oc5ccccc56)cc4)c4ccc1c2c43]

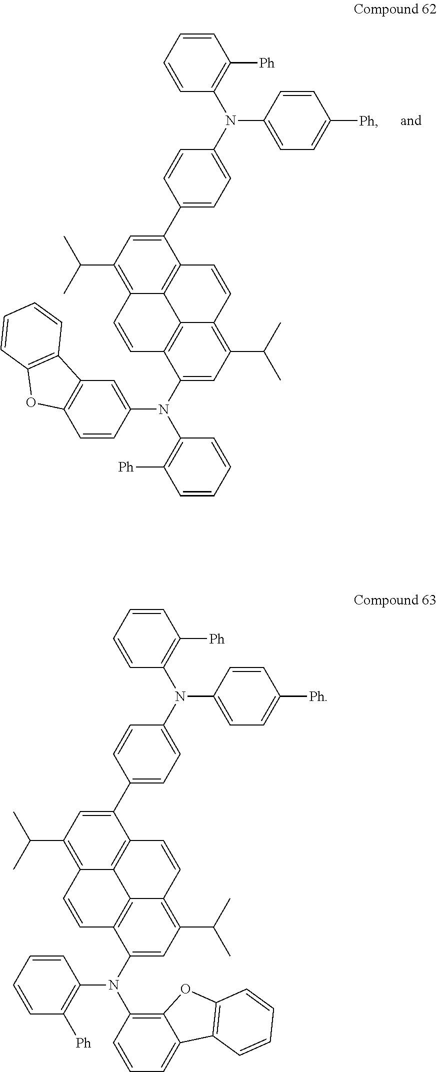 [SMILES: CC(C)c1cc(-c2ccc(N(c3ccc(-c4ccccc4)cc3)c3ccccc3-c3ccccc3)cc2)c2ccc3c(C(C)C)cc(N(c4ccc5oc6ccccc6c5c4)c4ccccc4-c4ccccc4)c4ccc1c2c34 ; CC(C)c1cc(-c2ccc(N(c3ccc(-c4ccccc4)cc3)c3ccccc3-c3ccccc3)cc2)c2ccc3c(C(C)C)cc(N(c4ccccc4-c4ccccc4)c4cccc5c4oc4ccccc45)c4ccc1c2c34]

10. The compound of claim 1, wherein R¹ has the formula 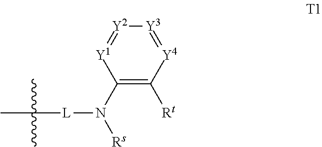
and R⁶ is amino.

11. The compound of claim 10, wherein the compound is selected from the group

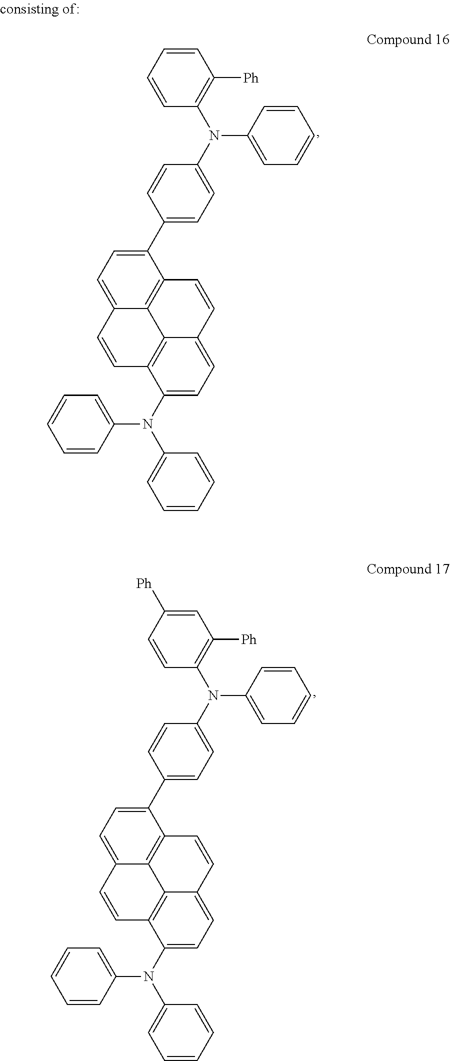 [SMILES: c1ccc(-c2ccccc2N(c2ccccc2)c2ccc(-c3ccc4ccc5c(N(c6ccccc6)c6ccccc6)ccc6ccc3c4c65)cc2)cc1 ; c1ccc(-c2ccc(N(c3ccccc3)c3ccc(-c4ccc5ccc6c(N(c7ccccc7)c7ccccc7)ccc7ccc4c5c76)cc3)c(-c3ccccc3)c2)cc1]

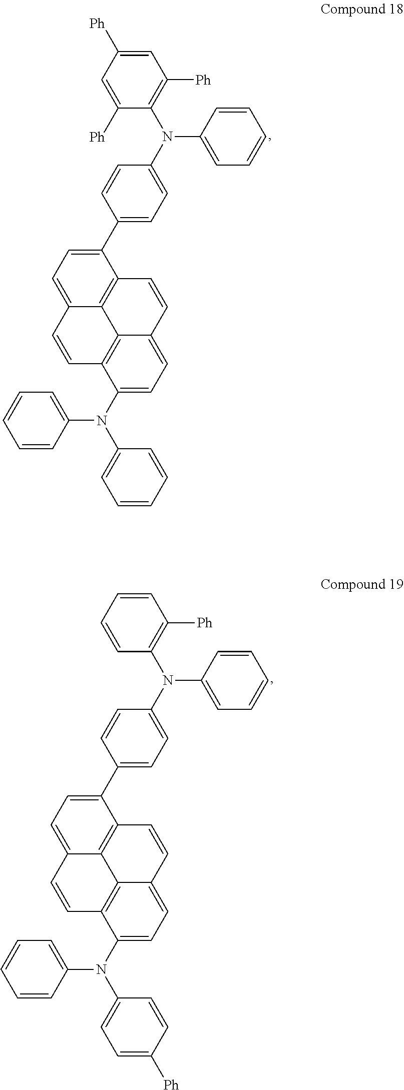 [SMILES: c1ccc(-c2cc(-c3ccccc3)c(N(c3ccccc3)c3ccc(-c4ccc5ccc6c(N(c7ccccc7)c7ccccc7)ccc7ccc4c5c76)cc3)c(-c3ccccc3)c2)cc1 ; c1ccc(-c2ccc(N(c3ccccc3)c3ccc4ccc5c(-c6ccc(N(c7ccccc7)c7ccccc7-c7ccccc7)cc6)ccc6ccc3c4c65)cc2)cc1]

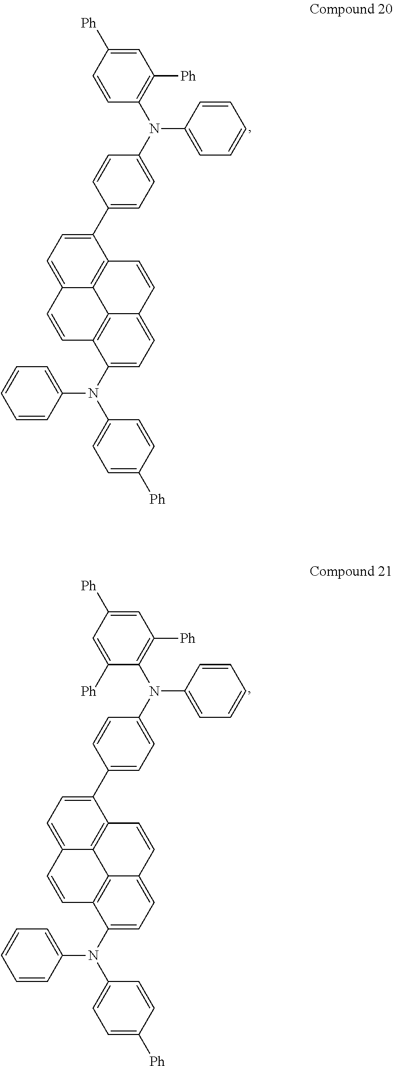 [SMILES: c1ccc(-c2ccc(N(c3ccccc3)c3ccc4ccc5c(-c6ccc(N(c7ccccc7)c7ccc(-c8ccccc8)cc7-c7ccccc7)cc6)ccc6ccc3c4c65)cc2)cc1 ; c1ccc(-c2ccc(N(c3ccccc3)c3ccc4ccc5c(-c6ccc(N(c7ccccc7)c7c(-c8ccccc8)cc(-c8ccccc8)cc7-c7ccccc7)cc6)ccc6ccc3c4c65)cc2)cc1]

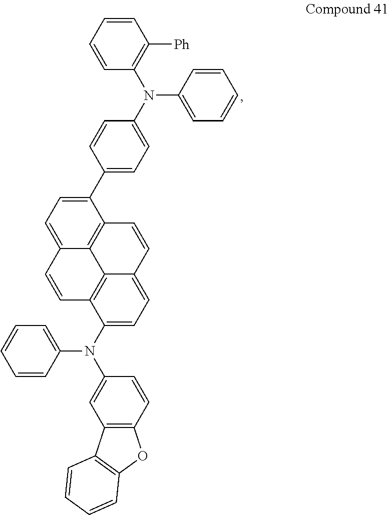 [SMILES: c1ccc(-c2ccccc2N(c2ccccc2)c2ccc(-c3ccc4ccc5c(N(c6ccccc6)c6ccc7oc8ccccc8c7c6)ccc6ccc3c4c65)cc2)cc1]

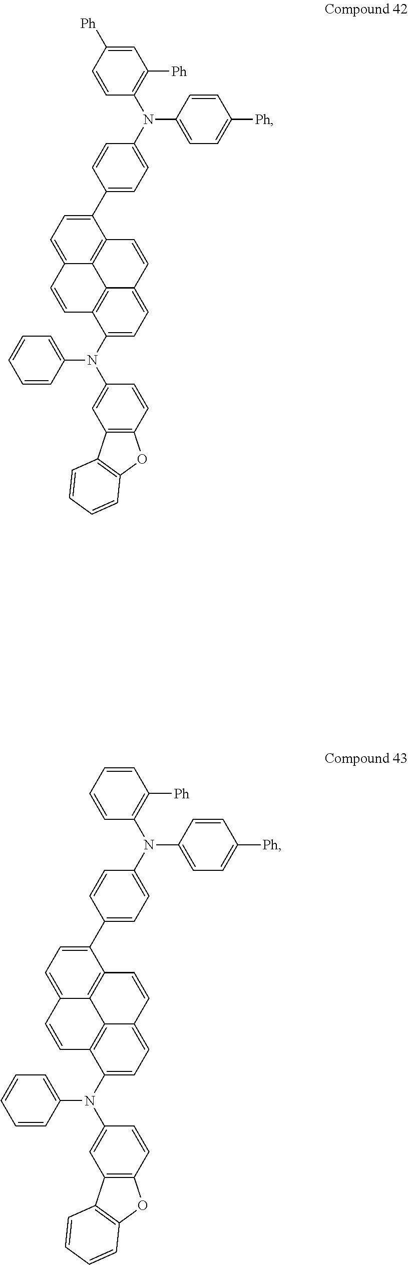 [SMILES: c1ccc(-c2ccc(N(c3ccc(-c4ccc5ccc6c(N(c7ccccc7)c7ccc8oc9ccccc9c8c7)ccc7ccc4c5c76)cc3)c3ccc(-c4ccccc4)cc3-c3ccccc3)cc2)cc1 ; c1ccc(-c2ccc(N(c3ccc(-c4ccc5ccc6c(N(c7ccccc7)c7ccc8oc9ccccc9c8c7)ccc7ccc4c5c76)cc3)c3ccccc3-c3ccccc3)cc2)cc1]

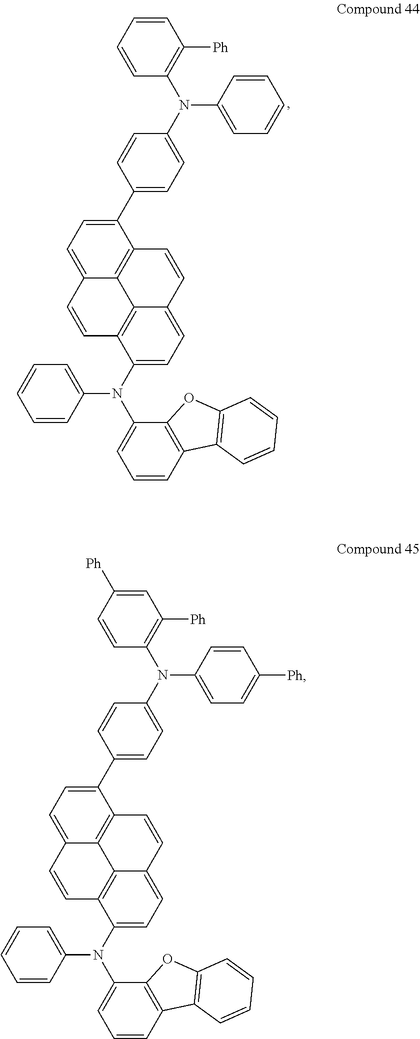 [SMILES: c1ccc(-c2ccccc2N(c2ccccc2)c2ccc(-c3ccc4ccc5c(N(c6ccccc6)c6cccc7c6oc6ccccc67)ccc6ccc3c4c65)cc2)cc1 ; c1ccc(-c2ccc(N(c3ccc(-c4ccc5ccc6c(N(c7ccccc7)c7cccc8c7oc7ccccc78)ccc7ccc4c5c76)cc3)c3ccc(-c4ccccc4)cc3-c3ccccc3)cc2)cc1]

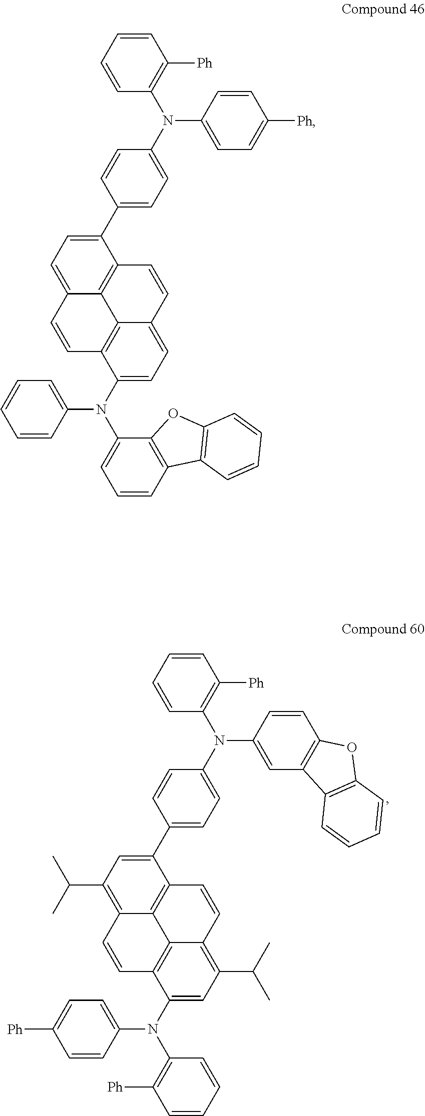 [SMILES: c1ccc(-c2ccc(N(c3ccc(-c4ccc5ccc6c(N(c7ccccc7)c7cccc8c7oc7ccccc78)ccc7ccc4c5c76)cc3)c3ccccc3-c3ccccc3)cc2)cc1 ; CC(C)c1cc(-c2ccc(N(c3ccc4oc5ccccc5c4c3)c3ccccc3-c3ccccc3)cc2)c2ccc3c(C(C)C)cc(N(c4ccc(-c5ccccc5)cc4)c4ccccc4-c4ccccc4)c4ccc1c2c34]

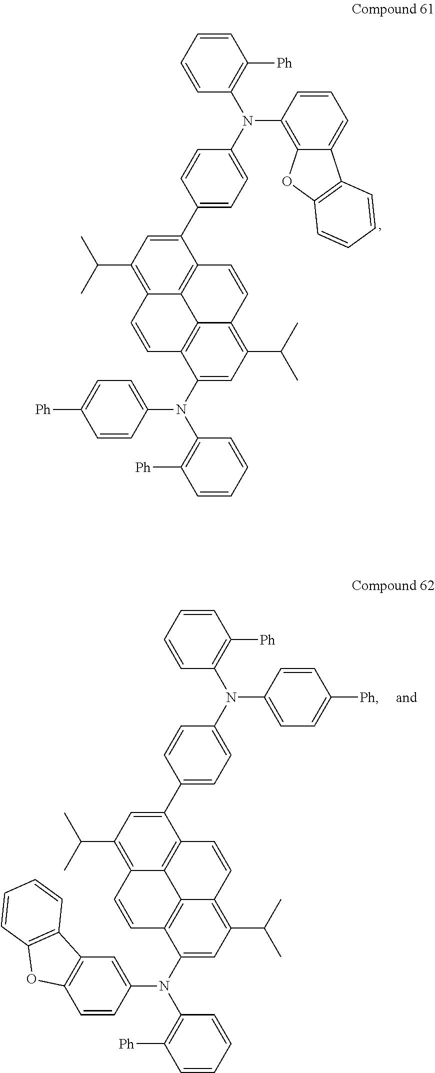 [SMILES: CC(C)c1cc(-c2ccc(N(c3ccccc3-c3ccccc3)c3cccc4c3oc3ccccc34)cc2)c2ccc3c(C(C)C)cc(N(c4ccc(-c5ccccc5)cc4)c4ccccc4-c4ccccc4)c4ccc1c2c34 ; CC(C)c1cc(-c2ccc(N(c3ccc(-c4ccccc4)cc3)c3ccccc3-c3ccccc3)cc2)c2ccc3c(C(C)C)cc(N(c4ccc5oc6ccccc6c5c4)c4ccccc4-c4ccccc4)c4ccc1c2c34]

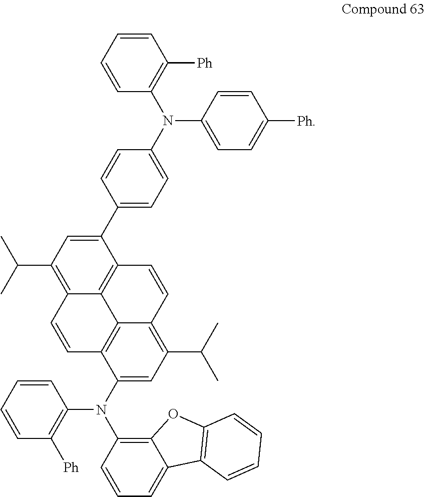 [SMILES: CC(C)c1cc(-c2ccc(N(c3ccc(-c4ccccc4)cc3)c3ccccc3-c3ccccc3)cc2)c2ccc3c(C(C)C)cc(N(c4ccccc4-c4ccccc4)c4cccc5c4oc4ccccc45)c4ccc1c2c34]

12. A first device comprising a first organic light emitting device, the first organic light emitting device comprising:
an anode;
a cathode; and
an organic layer, disposed between the anode and the cathode, comprising a compound having Formula 1: 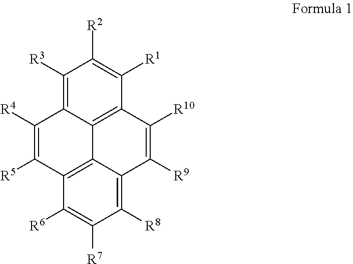
wherein R¹-R¹⁰ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof,
wherein at least two of R¹-R¹⁰ are not H,
wherein at least one R¹-R¹⁰ has the formula T1 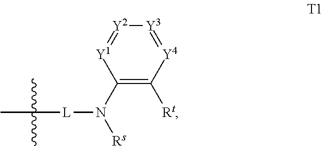
wherein L is an organic linker,
wherein Y¹ to Y⁴ are CR or N,
wherein R is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof,
wherein adjacent R moieties can form fused rings,
wherein R^{s} and R^{t} are independently aryl or heteroaryl, either of which may independently be further substituted, and
wherein R^{s} and R^{t} do not form fused rings with any part of the molecule.

13. The first device of claim 12, wherein R¹ has the formula T1

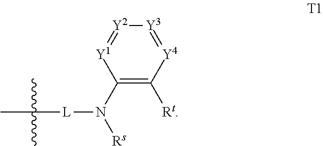

14. The first device of claim 12, wherein R¹ has the formula T1 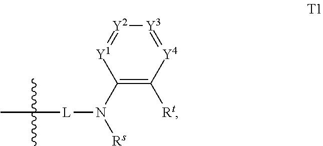
and R⁶ is alkyl, aryl or heteroaryl.

15. The first device of claim 12, wherein R¹ and R⁶ have the formula T1

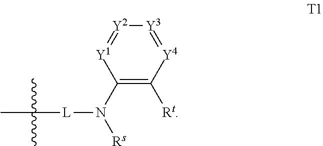

16. The first device of claim 12, wherein R¹ has the formula T1 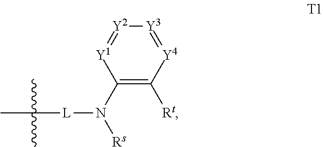
and R⁶ is amino.

17. The first device of claim 12, wherein the first device is a consumer product.

18. The first device of claim 12, wherein the first device is an organic light emitting device.

19. The first device of claim 12, wherein the first device comprises a light panel.

20. The first device of claim 12, wherein the organic layer is an emissive layer and the compound is an emissive dopant.

21. The first device of claim 12, wherein the organic layer is an emissive layer and the compound is a non-emissive dopant.

22. The first device of claim 12, wherein the organic layer further comprises a host material.

23. The first device of claim 22, wherein the host material contains aromatic groups selected from the group consisting of naphthalene, triphenylene, anthracene, chrysene, triazene, carbazole, dibenzofuran, dibenzothiophene and dibenzoselenophene.

24. A formulation comprising a compound of Formula 1, 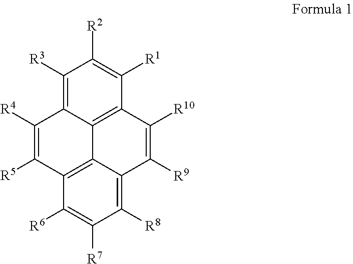
wherein R¹-R¹⁰ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof,
wherein at least two of R¹-R¹⁰ are not H,
wherein at least one R¹-R¹⁰ has the formula T1 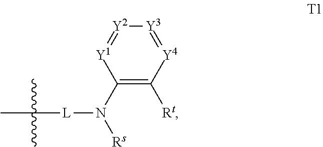
wherein L is an organic linker,
wherein Y¹ to Y⁴ are CR or N,
wherein R is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof,
wherein adjacent R moieties can form fused rings,
wherein R^{s} and R^{t} are independently aryl or heteroaryl, either of which may independently be further substituted, and
wherein R^{s} and R^{t} do not form fused rings with any part of the molecule.
